(19) United States
(12) Patent Application Publication
(10) Pub. No.: US 2021/0328154 A1
(43) Pub. Date: Oct. 21, 2021

(54) PLURALITY OF HOST MATERIALS AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Bitnari KIM, Gyeonggi-do (KR); Su-Hyun LEE, Gyeonggi-do (KR); Doo-Hyeon MOON, Gyeonggi-do (KR); Sang-Hee CHO, Gyeonggi-do (KR)

(21) Appl. No.: 17/264,742

(22) PCT Filed: Jul. 26, 2019
(86) PCT No.: PCT/KR2019/009337

§ 371 Date: Jan. 29, 2021

(30) Foreign Application Priority Data
Jul. 30, 2018 (KR) 10-2018-0088752
Jul. 23, 2019 (KR) 10-2019-0088860

(51) Int. Cl. H01L 51/00

(52) U.S. Cl. CPC H01L 51/0072; H01L 51/0073; H01L 51/0067; H01L 51/0074; H01L 51/0054; H01L 51/5012; H01L 51/0056; H01L 51/0057; H01L 51/0058; H01L 2251/5384; H01L 51/0055

(57) ABSTRACT

The present disclosure relates to a plurality of host materials comprising a first host material comprising a compound represented by formula 1, and a second host material comprising a compound represented by formula 2, and an organic electroluminescent device comprising the same. By comprising a specific combination of compounds of the present disclosure as host materials, it is possible to provide an organic electroluminescent device having higher luminous efficiency and/or longer lifetime properties as compared with a conventional organic electroluminescent device.

### TECHNICAL FIELD

The present disclosure relates to a plurality of host materials comprising a combination of specific compounds, and an organic electroluminescent device comprising the same.

### BACKGROUND ART

In 1987, Tang et al. of Eastman Kodak first developed a small molecule green organic electroluminescent device (OLED) of TPD/Alq3 bilayer consisting of a light-emitting layer and a charge transport layer. Since then, the research on an OLED has been rapidly carried out, and it has been commercialized.

At present, phosphorescent materials, which provide excellent luminous efficiency in realizing panels, are mainly used in organic electroluminescent devices. In many applications such as TVs and lightings, OLED lifetime is insufficient, and high efficiency of OLEDs is still required. Typically, the higher the luminance of an OLED, the shorter the lifetime of an OLED. Thus, a new luminescent material which shows high luminous efficiency and long lifetime is required for long time uses and high resolution of displays.

Korean Patent Appl. Laid-Open No. 2017-0022865 A discloses a phenanthro oxazole derivative compound. However, the development for improving performances of an OLED is still required.

### DISCLOSURE OF INVENTION

### Technical Problem

The objective of the present disclosure is to provide an improved host material capable of providing an organic electroluminescent device having higher luminous efficiency and/or longer lifetime properties.

### Solution to Problem

The present inventors have focused on how compounds having a phenanthroxazole core uniquely have a lower LUMO energy level compared to typical hole-type hosts, and have studied hole-type hosts capable of forming a proper energy gap with these compounds. As a result, it has been found that when a combination of a compound represented by the following formula 1 and a compound represented by the following formula 2 is used in a light-emitting layer, hole and electron properties are balanced by proper HOMO and LUMO energy levels, and it is possible to provide an OLED having higher luminous efficiency and/or longer lifetime properties as compared with conventional OLEDs. Specifically, the present inventors found that the above objective can be achieved by a plurality of host materials comprising a first host material and a second host material, wherein the first host material comprises a compound represented by the following formula 1, and the second host material comprises a compound represented by the following formula 2:

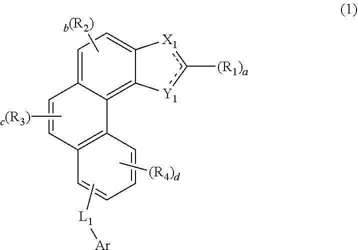

wherein,

X₁ and Y₁, each independently, represent —N═, —NR₅—, —O— or —S—, with a proviso that any one of X₁ and Y₁ represents —N═, and the other one represents —NR₅—, —O— or —S—;

L₁ represents a single bond, or a substituted or unsubstituted (C6-C30)arylene;

Ar represents a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino;

R₁ represents a substituted or unsubstituted (C6-C30)aryl, or a substituted or unsubstituted (3- to 30-membered)heteroaryl;

R₂ to R₅, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or adjacent ones of R₂ to R₅ may be linked to each other to form a ring(s);

a represents an integer of 1; b and c, each independently, represent an integer of 1 or 2; d represents an integer of 1 to 3; where if b to d, each independently, are an integer of 2 or more, each of R₂ to R₄ may be the same or different; and

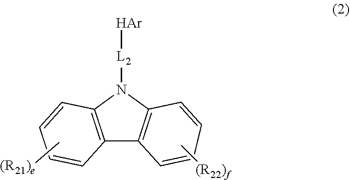

wherein,

HAr represents a substituted or unsubstituted (3- to 30-membered)heteroaryl;

L₂ represents a single bond, a substituted or unsubstituted (C6-C30)arylene, or a substituted or unsubstituted (3- to 30-membered)heteroarylene;

R₂₁ and R₂₂, each independently, represent hydrogen, deuterium, a halogen, a cyano, a substituted or unsubstituted (C1-C30)alkyl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C6-C30)aryl, a substituted or unsubstituted (3- to 30-membered)heteroaryl, —NR₁₁R₁₂, or —SiR₁₃R₁₄R₁₅; or adjacent R₂₁'s or adjacent R₂₂'s, each independently, may be linked to each other to form a ring(s), with a proviso that at least one ring is formed;

R₁₁ to R₁₅, each independently, represent a substituted or unsubstituted (C1-C30)alkyl, a substituted or unsubstituted (C6-C30)aryl, or a substituted or unsubstituted (3- to 30-membered)heteroaryl; and

e and f, each independently, represent an integer of 1 to 4; where if e and f, each independently, are an integer of 2 or more, each of R₂₁ and each of R₂₂ may be the same or different.

### Advantageous Effects of Invention

By comprising a specific combination of compounds of the present disclosure as host materials, it is possible to provide an organic electroluminescent device having higher luminous efficiency and/or longer lifetime properties as compared with the conventional organic electroluminescent device, and manufacture a display system or a light system using the same.

### MODE FOR THE INVENTION

Hereinafter, the present disclosure will be described in detail. However, the following description is intended to explain the disclosure, and is not meant in any way to restrict the scope of the disclosure.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (containing host and dopant materials), an electron buffer material, a hole blocking material, an electron transport material, an electron injection material, etc.

The term “a plurality of organic electroluminescent materials” in the present disclosure means an organic electroluminescent material(s) comprising a combination of at least two compounds, which may be comprised in any organic layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of at least two compounds which may be comprised in at least one of a hole injection layer, a hole transport layer, a hole auxiliary layer, a light-emitting auxiliary layer, an electron blocking layer, a light-emitting layer, an electron buffer layer, a hole blocking layer, an electron transport layer, and an electron injection layer. At least two compounds may be comprised in the same layer or different layers by means of the methods used in the art, for example, they may be mixture-evaporated or co-evaporated, or may be individually deposited.

The term “a plurality of host materials” in the present disclosure means a host material(s) comprising a combination of at least two compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure may be a combination of two or more host materials, and may optionally further include a conventional material comprised in organic electroluminescent materials. The two or more compounds comprised in the plurality of host materials of the present disclosure may be included in one light-emitting layer or may be respectively included in different light-emitting layers. For example, the two or more host materials may be mixture-evaporated or co-evaporated, or individually deposited.

Herein, the term “(C1-C30)alkyl” is meant to be a linear or branched alkyl having 1 to 30 carbon atoms constituting the chain, in which the number of carbon atoms is preferably 1 to 10, and more preferably 1 to 6. The above alkyl may include methyl, ethyl, n-propyl, isopropyl, n-butyl, isobutyl, tert-butyl, etc. The term “(C3-C30)cycloalkyl” or “(C3-C30)cycloalkylene” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, etc. The term “(3- to 7-membered)heterocycloalkyl” is meant to be a cycloalkyl having 3 to 7 ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolan, tetrahydropyran, etc. The term “(C6-C30)aryl” or “(C6-C30)arylene” is meant to be a monocyclic or fused ring radical derived from an aromatic hydrocarbon having 6 to 30 ring backbone carbon atoms. The above aryl or arylene may be partially saturated, and may comprise a spiro structure. The above aryl may include phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluorene]yl, etc. More specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzofluorenyl, dibenzofluorenyl, 2-biphenylyl, 3-biphenylyl, 4-biphenylyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenylyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, etc.

The term “(3- to 30-membered)heteroaryl” or “(3- to 30-membered)heteroarylene” is an aryl or an arylene having 3 to 30 ring backbone atoms, in which the number of ring backbone atoms is preferably 5 to 30, and including at least one, preferably 1 to 4 heteroatoms selected from the group consisting of B, N, O, S, Si, and P. The above heteroaryl(ene) may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzonaphthothiophenyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, benzocarbazolyl, dibenzocarbazolyl, phenoxazinyl, phenanthridinyl, benzodioxolyl, etc. More specifically, the heteroaryl may include 1-pyrrolyl, 2-pyrrolyl, 3-pyrrolyl, pyrazinyl, 2-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridinyl, 3-imidazopyridinyl, 5-imidazopyridinyl, 6-imidazopyridinyl, 7-imidazopyridinyl, 8-imidazopyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthrdinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, etc. “Halogen” includes F, Cl, Br, and I.

In addition, “ortho (o-).” “meta (m-),” and “para (p-)” are prefixes, which represent the relative positions of substituents, respectively. Ortho indicates that two substituents are adjacent to each other, and for example, when two substituents in a benzene derivative occupy positions 1 and 2, it is called an ortho position. Meta indicates that two substituents are at positions 1 and 3, and for example, when two substituents in a benzene derivative occupy positions 1 and 3, it is called a meta position. Para indicates that two substituents are at positions 1 and 4, and for example, when two substituents in a benzene derivative occupy positions 1 and 4, it is called a para position.

Herein, “substituted” in the expression “substituted or unsubstituted” means that a hydrogen atom in a certain functional group is replaced with another atom or another functional group, i.e., a substituent. In the present disclosure, the substituents of the substituted alkyl, the substituted aryl, the substituted arylene, the substituted heteroaryl, the substituted heteroarylene, the substituted cycloalkyl, the substituted cycloalkenyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di-alkylamino, the substituted mono- or di-arylamino, and the substituted alkylarylamino, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with a (C6-C30)aryl(s); a (C6-C30)aryl unsubstituted or substituted with a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsiyl; an amino; a mono- or di-(C1-C30)alkylamino; a mono- or di-(C6-C30)arylamino unsubstituted or substituted with a (C1-C30)alkyl(s); a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituents, each independently, are at least one selected from the group consisting of a (C1-C20)alkyl; a (C6-C25)aryl; and a (5- to 25-membered)heteroaryl. According to another embodiment of the present disclosure, the substituents, each independently, are at least one selected from the group consisting of a (C1-C10)alkyl and a (C6-C18)aryl. For example, the substituents, each independently, may be at least one selected from the group consisting of a methyl, a phenyl, a naphthyl, a biphenyl, a naphthylphenyl, a phenylnaphthyl, a dibenzofuranyl, a dibenzothiophenyl, a benzonaphthofuranyl, and a benzonaphthothiophenyl.

In the formulas of the present disclosure, a ring formed by a linkage of adjacent substituents means that at least two adjacent substituents are linked to or fused with each other to form a substituted or unsubstituted mono- or polycyclic (3- to 30-membered) alicyclic or aromatic ring, or the combination thereof; preferably, a substituted or unsubstituted mono- or polycyclic (3- to 25-membered) alicyclic or aromatic ring, or the combination thereof; more preferably, a mono- or polycyclic (5- to 20-membered) aromatic ring unsubstituted or substituted with an alkyl(s). Also, the ring may contain at least one heteroatom selected from B, N, O, S, Si, and P, preferably at least one heteroatom selected from N, O, and S. For example, the ring may be a benzene ring, a benzothiophene ring, a benzofuran ring, an indene ring substituted with a phenyl(s), or a benzoindene ring substituted with at least one of a phenyl(s) and a biphenyl(s).

Herein, the heteroaryl, the heteroarylene, and the heterocycloalkyl, each independently, may contain at least one heteroatom selected from B, N, O, S, Si, and P. Also, the heteroatom may be bonded to at least one selected from the group consisting of hydrogen, deuterium, a halogen, a cyano, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsiyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, and a substituted or unsubstituted (C1-C30)alkyl(C6-C30)arylamino.

In formula 1, X₁ and Y₁, each independently, represent —N═, —NR₅—, —O— or —S—, with a proviso that any one of X₁ and Y₁ represents —N═, and the other one represents —NR₅—, —O— or —S—.

In formula 1, L₁ represents a single bond, or a substituted or unsubstituted (C6-C30)arylene. According to one embodiment of the present disclosure, L₁ represents a single bond, or a substituted or unsubstituted (C6-C25)arylene. According to another embodiment of the present disclosure, L₁ represents a single bond, or a substituted or unsubstituted (C6-C18)arylene. For example, L₁ may represent a single bond, a phenylene, a naphthylene, or a biphenylene.

In formula 1, Ar represents a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino. According to one embodiment of the present disclosure, Ar represents a substituted or unsubstituted (C6-C30)aryl, a substituted or unsubstituted (5- to 25-membered)heteroaryl, a substituted or unsubstituted mono- or di-(C6-C25)arylamino, or a substituted or unsubstituted (C6-C25)aryl(5- to 25-membered)heteroarylamino. According to another embodiment of the present disclosure, Ar represents a (C6-C30)aryl unsubstituted or substituted with at least one of a (C1-C10)alkyl(s) and a (C6-C18)aryl(s); an unsubstituted (5- to 25-membered)heteroaryl; a mono- or di-(C6-C25)arylamino unsubstituted or substituted with at least one of a (C1-C10)alkyl(s), a (C6-C18)aryl(s), and a (C1-C10)alkyl(C6-C18)aryl(s); or a (C6-C18)aryl(5- to 20-membered)heteroarylamino unsubstituted or substituted with a (C6-C18)aryl(s). Specifically, Ar may represent a substituted or unsubstituted phenyl, a substituted or unsubstituted naphthyl, a substituted or unsubstituted biphenyl, a substituted or unsubstituted naphthylphenyl, a substituted or unsubstituted phenylnaphthyl, a substituted or unsubstituted terphenyl, a substituted or unsubstituted phenanthrenyl, a substituted or unsubstituted benzophenanthrenyl, a substituted or unsubstituted fluoranthenyl, a substituted or unsubstituted fluorenyl, a substituted or unsubstituted benzofluorenyl, a substituted or unsubstituted triphenylenyl, a substituted or unsubstituted nitrogen-containing 23-membered heteroaryl, a substituted or unsubstituted spirobifluorenyl, a substituted or unsubstituted spiro[cyclopentane-fluorene]yl, a substituted or unsubstituted spiro[indan-fluorene]yl, a substituted or unsubstituted spiro[fluorene-benzofluorene]yl, a substituted or unsubstituted diphenylamino, a substituted or unsubstituted phenylbiphenylamino, a substituted or unsubstituted phenylnaphthylamino, a substituted or unsubstituted phenylterphenylamino, a substituted or unsubstituted phenylfluorenylamino, a substituted or unsubstituted naphthylbiphenylamino, a substituted or unsubstituted naphthylterphenylamino, a substituted or unsubstituted naphthylphenanthrenylamino, a substituted or unsubstituted dinaphthylamino, a substituted or unsubstituted dibiphenylamino, a substituted or unsubstituted biphenylfluorenylamino, a substituted or unsubstituted difluorenylamino, a substituted or unsubstituted biphenyldibenzofuranylamino, a substituted or unsubstituted biphenyidibenzothiophenylamino, or a substituted or unsubstituted phenylcarbazolylamino. For example, Ar may represent a phenyl, a naphthyl, a biphenyl, a dimethylfluorenyl, a diphenylfluorenyl, a phenanthrenyl, a fluoranthenyl, a dimethylbenzofluorenyl, a diphenylbenzofluorenyl, a terphenyl, a triphenylenyl, a benzophenanthrenyl, a spirobifluorenyl, a spiro[cyclopentane-fluorene]yl, a spiro[indan-fluorene]yl, a nitrogen-containing 23-membered heteroaryl, a diphenylamino, a phenylbiphenylamino, a phenylnaphthylamino, a phenylterphenylamino, a naphthylphenylphenylamino, a dimethylfluorenylphenylamino, a naphthylterphenylamino, a dinaphthylamino, a naphthylphenanthrenylamino, a dibiphenylamino, a biphenylnaphthylamino, a dimethylfluorenylbiphenylamino, a diphenylfluorenylbiphenylamino, a dimethylfluorenyldimethylfluorenylamino, a biphenyldibenzofuranylamino, a biphenyidibenzothiophenylamino, or a phenylcarbazolylphenylamino.

In formula 1. R₁ represents a substituted or unsubstituted (C6-C30)aryl, or a substituted or unsubstituted (3- to 30-membered)heteroaryl. According to one embodiment of the present disclosure, R₁ represents a substituted or unsubstituted (C6-C25)aryl, or a substituted or unsubstituted (5- to 25-membered)heteroaryl. According to another embodiment of the present disclosure, R₁ represents an unsubstituted (C6-C18)aryl, or an unsubstituted (5- to 20-membered)heteroaryl. For example, R₁ may represent a phenyl, a biphenyl, a pyridyl, a quinolyl, or an isoquinolyl.

In formula 1, R₂ to R₅, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or adjacent ones of R₂ to R₅ may be linked to each other to form a ring(s). According to one embodiment of the present disclosure, R₂ to R₄ may represent hydrogen; and R₅ may present a substituted or unsubstituted (C1-C20)alkyl, a substituted or unsubstituted (C6-C25)aryl, or a substituted or unsubstituted (3- to 30-membered)heteroaryl.

In formula 1, a represents an integer of 1; b and c, each independently, represent an integer of 1 or 2; d represents an integer of 1 to 3; where if b to d, each independently, are an integer of 2 or more, each of R₂ to each of R₄ may be the same or different. According to one embodiment of the present disclosure, a to d, each independently, represent an integer of 1.

According to one embodiment of the present disclosure, the compound represented by formula 1 may be represented by at least one of the following formulas 1-1 and 1-2.

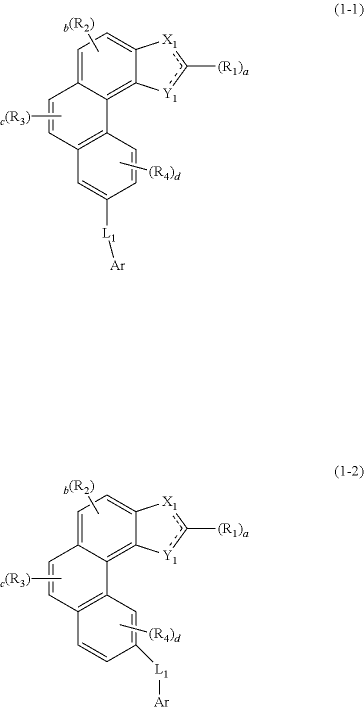

In formulas 1-1 and 1-2, X₁, Y₁, Ar, L₁, R₁ to R₄, and a to d are as defined in formula 1.

In formula 2, HAr represents a substituted or unsubstituted (3- to 30-membered)heteroaryl. According to one embodiment of the present disclosure, HAr represents a substituted or unsubstituted (5- to 25-membered)heteroaryl. According to another embodiment of the present disclosure, HAr represents a (5- to 20-membered)heteroaryl unsubstituted or substituted with a (C6-C30)aryl(s). Specifically, HAr may represent a substituted or unsubstituted triazinyl, a substituted or unsubstituted pyridyl, a substituted or unsubstituted pyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted naphthyridinyl, or a substituted or unsubstituted benzothienopyrimidinyl. For example, HAr may represent a substituted triazinyl, a substituted pyridyl, a substituted pyrimidinyl, a substituted quinazolinyl, or a substituted quinoxalinyl, in which the substituent of the substituted triazinyl, the substituted pyridyl, the substituted pyrimidinyl, the substituted quinazolinyl, and the substituted quinoxalinyl may be at least one of a phenyl(s), a biphenyl(s), a naphthyl(s), a naphthylphenyl(s), a dibenzofuranyl(s), a dibenzothiophenyl(s), a benzonaphthofuranyl(s), and a benzonaphthothiophenyl(s).

In formula 2, L₂ represents a single bond, a substituted or unsubstituted (C6-C30)arylene, or a substituted or unsubstituted (3- to 30-membered)heteroarylene. According to one embodiment of the present disclosure, L₂ represents a single bond, or a substituted or unsubstituted (C6-C25)arylene. According to another embodiment of the present disclosure, L₂ represents a single bond, or a (C6-C18)arylene unsubstituted or substituted with a (C1-C10)alkyl(s). For example, L₂ may represent a single bond, a phenylene, a naphthylene, a biphenylene, a fluorenylene substituted with a methyl(s), or a benzofluorenylene substituted with a methyl(s).

In formula 2, R₂₁ and R₂₂, each independently, represent hydrogen, deuterium, a halogen, a cyano, a substituted or unsubstituted (C1-C30)alkyl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C6-C30)aryl, a substituted or unsubstituted (3- to 30-membered)heteroaryl, —NR₁₁R₁₂, or —SiR₁₃R₁₄R₁₅; or adjacent R₂₁'s or adjacent R₂₂'s, each independently, may be linked to each other to form a ring(s), with a proviso that at least one ring must be formed. R₁₁ to R₁₅, each independently, represent a substituted or unsubstituted (C1-C30)alkyl, a substituted or unsubstituted (C6-C30)aryl, or a substituted or unsubstituted (3- to 30-membered)heteroaryl. According to one embodiment of the present disclosure, R₂₁ and R₂₂, each independently, represent hydrogen, or a substituted or unsubstituted (C6-C25)aryl; or adjacent R₂₁'s or adjacent R₂₂'s, each independently, may be linked to each other to form a ring(s). According to another embodiment of the present disclosure, R₂₁ and R₂₂, each independently, represent hydrogen, or an unsubstituted (C6-C18)aryl; or adjacent R₂₁'s or adjacent R₂₂'s, each independently, may be linked to each other to form a ring(s). For example, R₂₁ and R₂₂, each independently, represent hydrogen or a phenyl; or adjacent R₂₁'s or adjacent R₂₂'s, each independently, may be linked to each other to form a ring(s). At least one of two adjacent R₂₁'s and two adjacent R₂₂'s must be linked to each other to form a ring(s). According to one embodiment of the present disclosure, when adjacent R₂₁'s or adjacent R₂₂'s are linked to each other to form a ring(s), the ring may be at least one of an unsubstituted benzene ring, an indene ring substituted with a phenyl(s), a benzofuran ring, a benzothiophene ring, and a benzoindene ring substituted with at least one of a phenyl(s) and a biphenyl(s).

In formula 2, e and f, each independently, represent an integer of 1 to 4; where if e and f, each independently, are an integer of 2 or more, each of R₂₁ and each of R₂₂ may be the same or different.

According to one embodiment of the present disclosure, the compound represented by formula 2 may be represented by at least one of the following formulas 2-1 to 2-7.

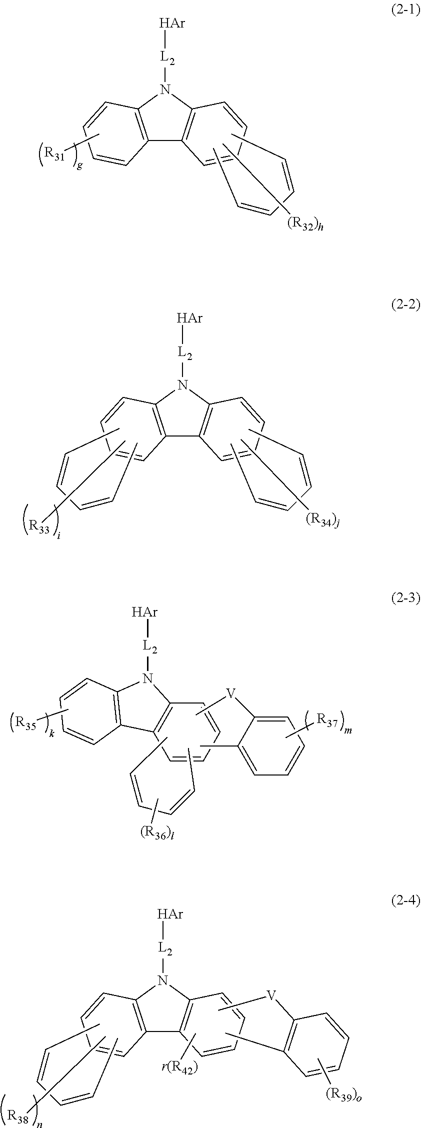

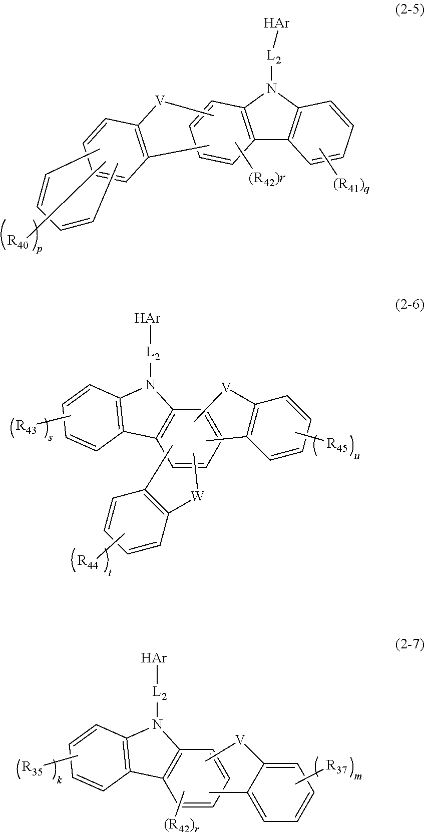

In formulas 2-1 to 2-7, HAr and L₂ are as defined in formula 2.

In formulas 2-1 to 2-7, V and W, each independently, represent NR₁₆, O or S.

R₁₆ represents a substituted or unsubstituted (C6-C30)aryl, or a substituted or unsubstituted (3- to 30-membered)heteroaryl. According to one embodiment of the present disclosure, R₁₆ represents a substituted or unsubstituted (C6-C25)aryl, or a substituted or unsubstituted (5- to 25-membered)heteroaryl. According to another embodiment of the present disclosure, R₁₆ represents an unsubstituted (C6-C18)aryl. For example, R₁₆ may represent a phenyl or a biphenyl.

In formulas 2-1 to 2-7, R₃₁ to R₄₅, each independently, represent hydrogen, deuterium, a halogen, a cyano, a substituted or unsubstituted (C1-C30)alkyl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C6-C30)aryl, a substituted or unsubstituted (3- to 30-membered)heteroaryl, —NR₆R₇, or —SiR₈R₉R₁₀. According to one embodiment of the present disclosure, R₃₁ to R₄₅, each independently, represent hydrogen, deuterium, or a substituted or unsubstituted (C6-C25)aryl. According to another embodiment of the present disclosure, R₃₁ to R₄₅, each independently, represent hydrogen, or an unsubstituted (C6-C18)aryl. For example, R₃₁ to R₄₅, each independently, may represent hydrogen, or a phenyl.

R₆ to R₁₀, each independently, represent a substituted or unsubstituted (C1-C30)alkyl, a substituted or unsubstituted (C6-C30)aryl, or a substituted or unsubstituted (3- to 30-membered)heteroaryl.

In formulas 2-1 to 2-7, g, k, l, m, o, q, s, t and u, each independently, represent an integer of 1 to 4; h, i, j, n and p, each independently, represent an integer of 1 to 6; r represents an integer of 1 or 2; where if g to u, each independently, are an integer of 2 or more, each of R₃₁ to each of R₄₅ may be the same or different.

According to one embodiment of the present disclosure, the compound represented by formula 2 may be represented by at least one of the following formulas 2-11 to 2-38.

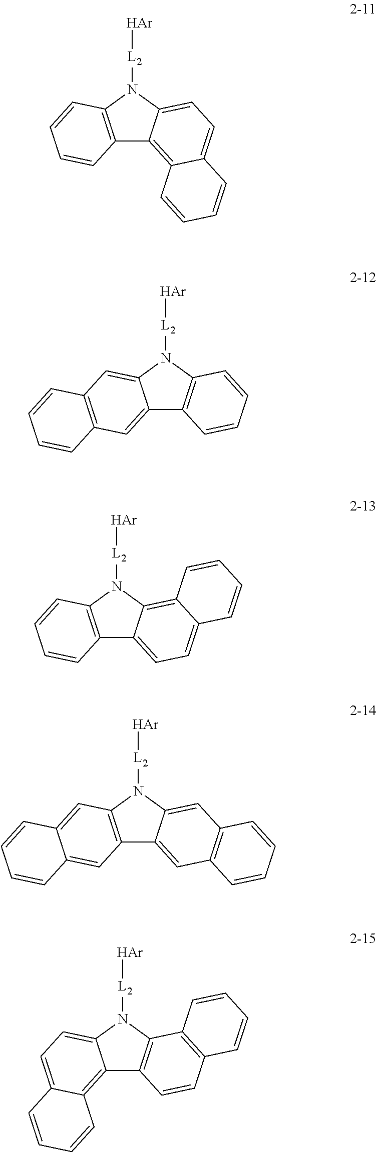

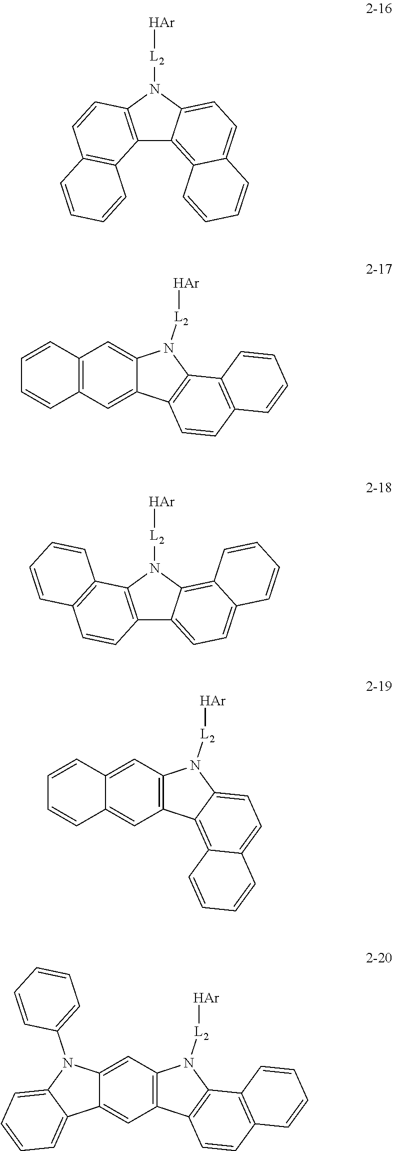

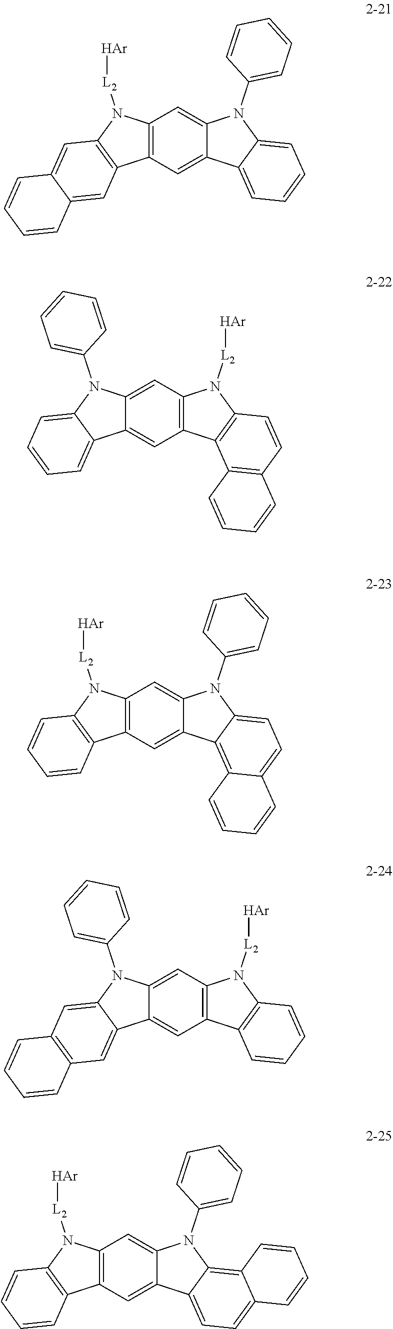

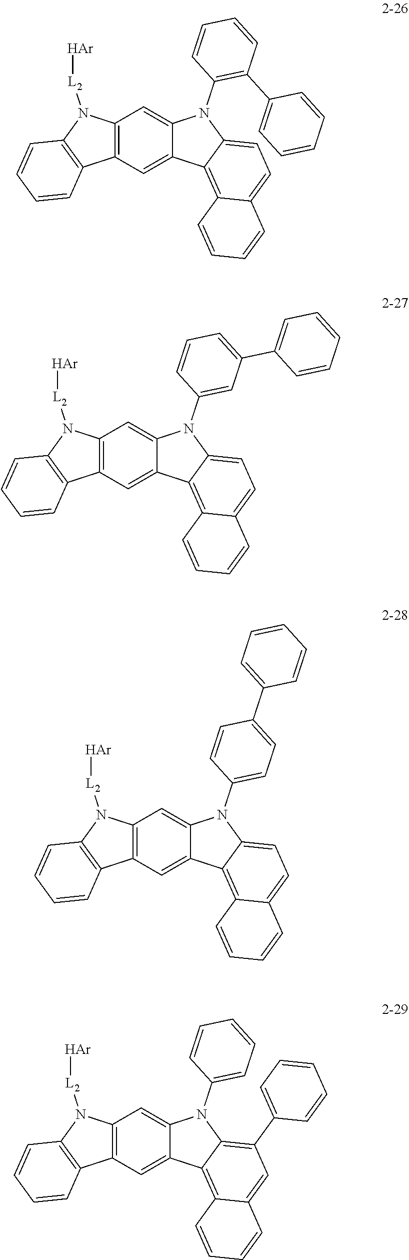

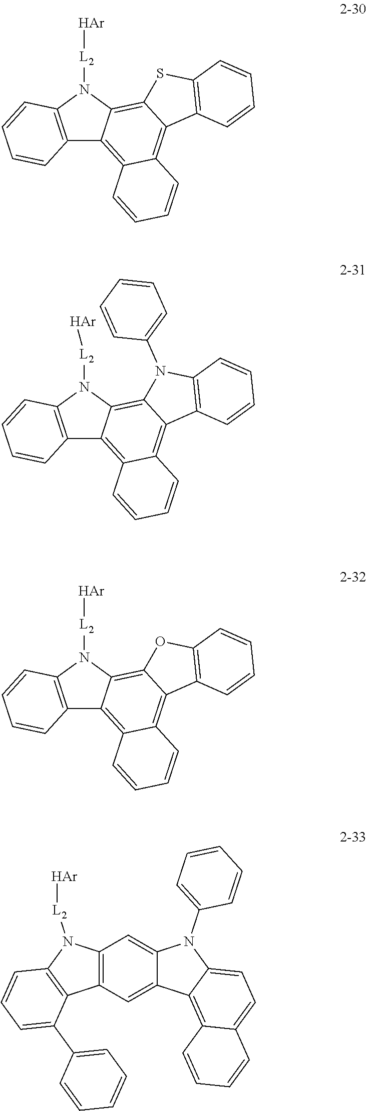

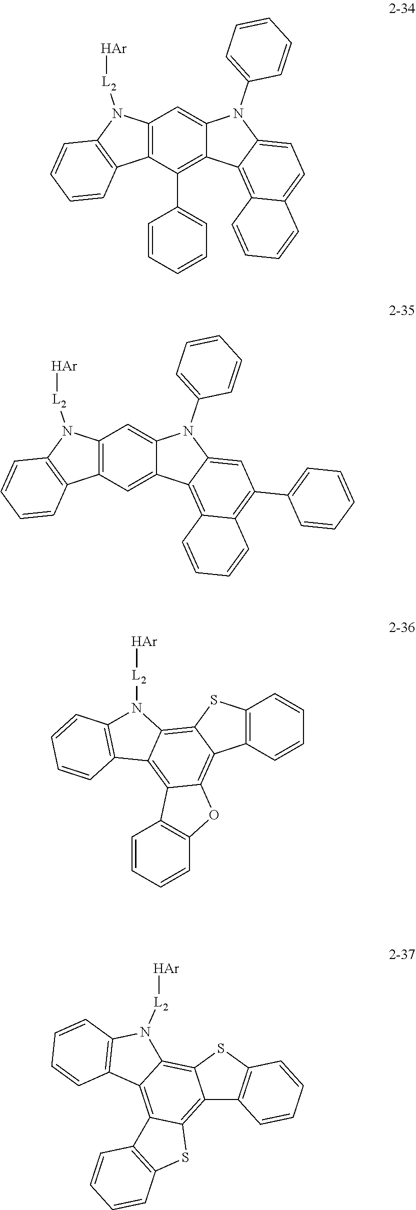

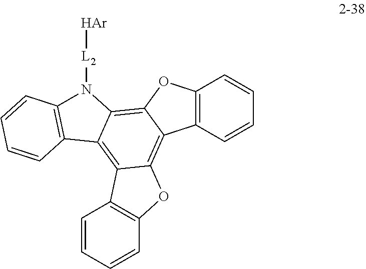

In formulas 2, 2-1 to 2-7, and 2-11 to 2-38, HAr may represent any one selected from the group consisting of the following structures 4-1 to 4-28.

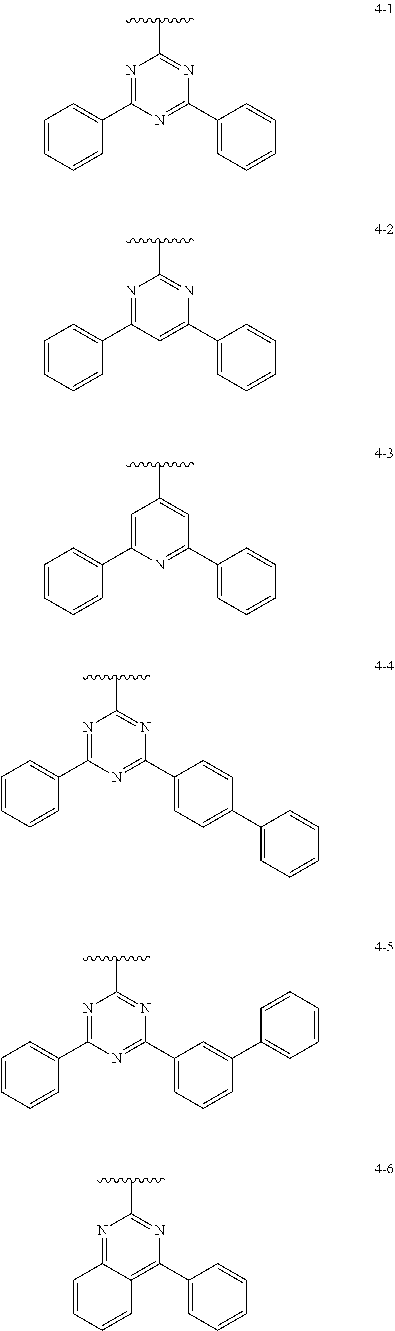 [SMILES: *c1nc(-c2ccccc2)nc(-c2ccccc2)n1 ; *c1nc(-c2ccccc2)cc(-c2ccccc2)n1 ; *c1cc(-c2ccccc2)nc(-c2ccccc2)c1 ; *c1nc(-c2ccccc2)nc(-c2ccc(-c3ccccc3)cc2)n1 ; *c1nc(-c2ccccc2)nc(-c2cccc(-c3ccccc3)c2)n1 ; *c1nc(-c2ccccc2)c2ccccc2n1]

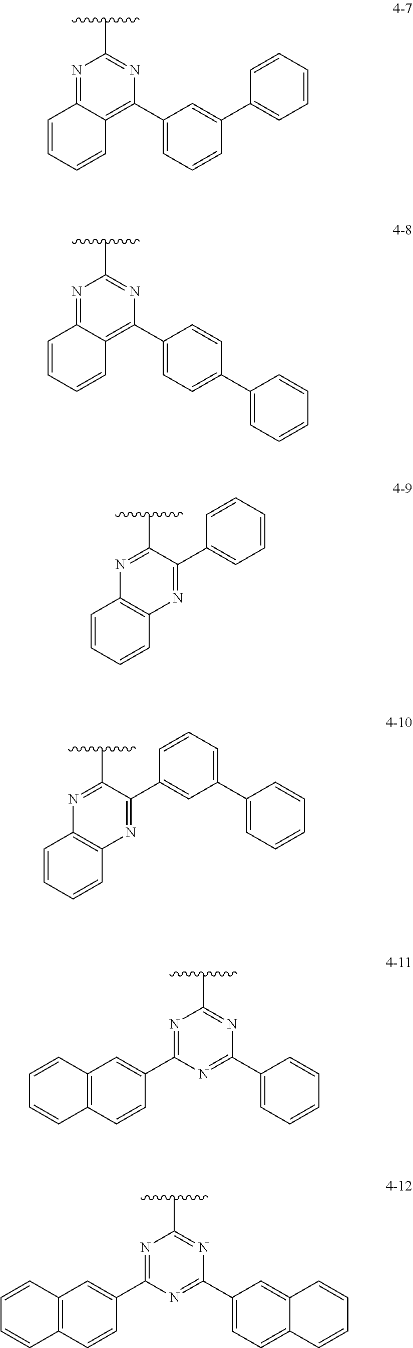 [SMILES: *c1nc(-c2cccc(-c3ccccc3)c2)c2ccccc2n1 ; *c1nc(-c2ccc(-c3ccccc3)cc2)c2ccccc2n1 ; *c1nc2ccccc2nc1-c1ccccc1 ; *c1nc2ccccc2nc1-c1cccc(-c2ccccc2)c1 ; *c1nc(-c2ccccc2)nc(-c2ccc3ccccc3c2)n1 ; *c1nc(-c2ccc3ccccc3c2)nc(-c2ccc3ccccc3c2)n1]

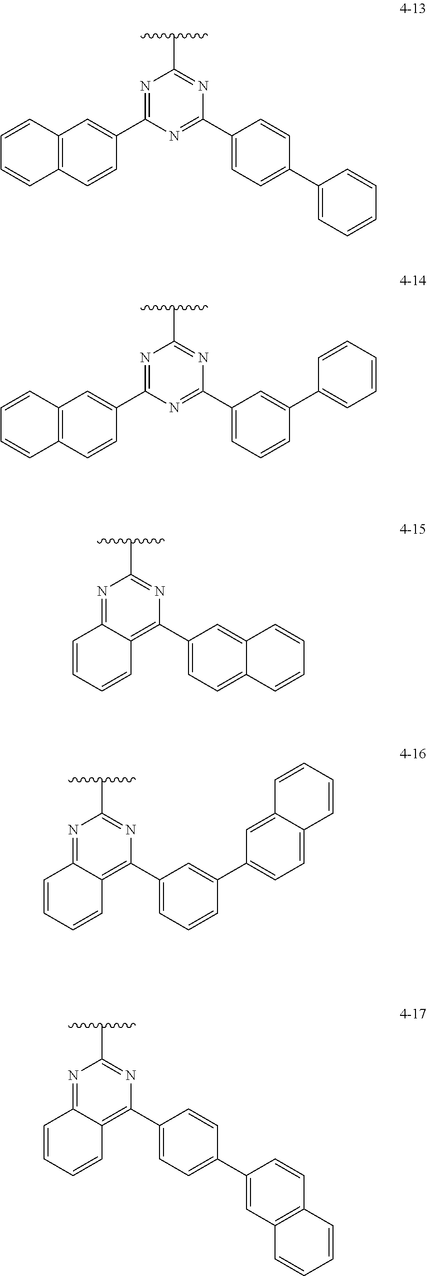 [SMILES: *c1nc(-c2ccc(-c3ccccc3)cc2)nc(-c2ccc3ccccc3c2)n1 ; *c1nc(-c2cccc(-c3ccccc3)c2)nc(-c2ccc3ccccc3c2)n1 ; *c1nc(-c2ccc3ccccc3c2)c2ccccc2n1 ; *c1nc(-c2cccc(-c3ccc4ccccc4c3)c2)c2ccccc2n1 ; *c1nc(-c2ccc(-c3ccc4ccccc4c3)cc2)c2ccccc2n1]

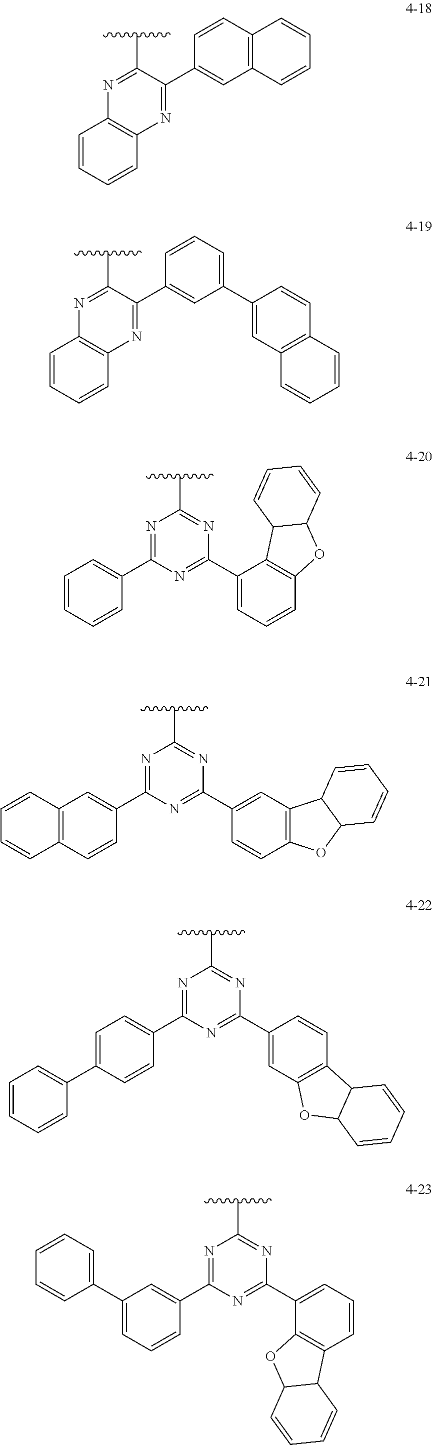 [SMILES: *c1nc2ccccc2nc1-c1ccc2ccccc2c1 ; *c1nc2ccccc2nc1-c1cccc(-c2ccc3ccccc3c2)c1 ; *c1nc(-c2ccccc2)nc(-c2cccc3c2C2C=CC=CC2O3)n1 ; *c1nc(-c2ccc3c(c2)C2C=CC=CC2O3)nc(-c2ccc3ccccc3c2)n1 ; *c1nc(-c2ccc(-c3ccccc3)cc2)nc(-c2ccc3c(c2)OC2C=CC=CC32)n1 ; *c1nc(-c2cccc(-c3ccccc3)c2)nc(-c2cccc3c2OC2C=CC=CC32)n1]

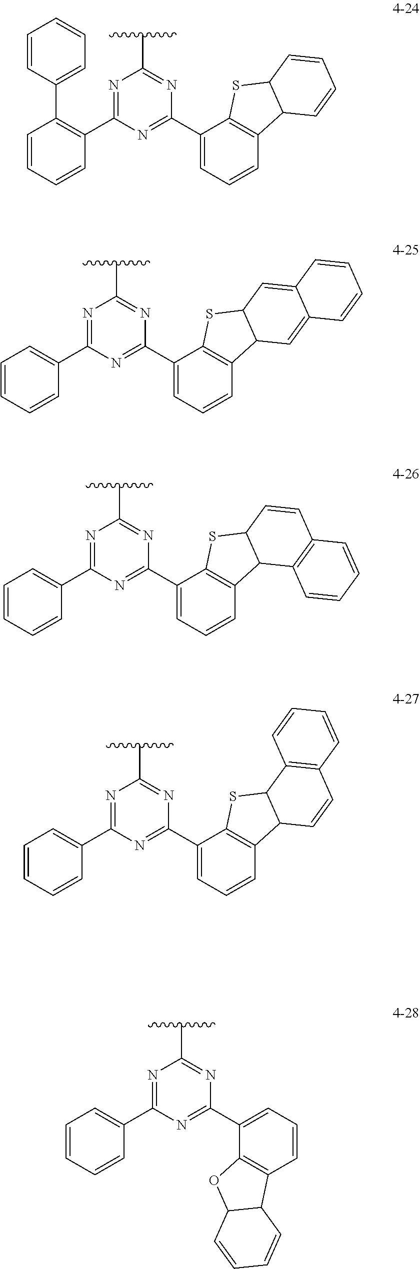 [SMILES: *c1nc(-c2ccccc2-c2ccccc2)nc(-c2cccc3c2SC2C=CC=CC32)n1 ; *c1nc(-c2ccccc2)nc(-c2cccc3c2SC2C=c4ccccc4=CC32)n1 ; *c1nc(-c2ccccc2)nc(-c2cccc3c2SC2C=Cc4ccccc4C32)n1 ; *c1nc(-c2ccccc2)nc(-c2cccc3c2SC2c4ccccc4C=CC32)n1 ; *c1nc(-c2ccccc2)nc(-c2cccc3c2OC2C=CC=CC32)n1]

In formulas 2, 2-1 to 2-7, and 2-11 to 2-38, L₂ may represent a single bond, or any one selected from the group consisting of the following structures 3-1 to 3-40.

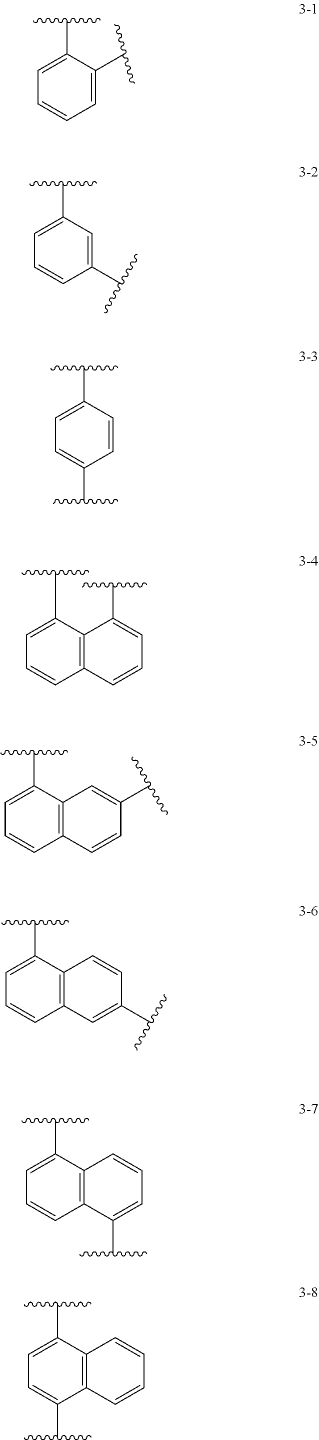

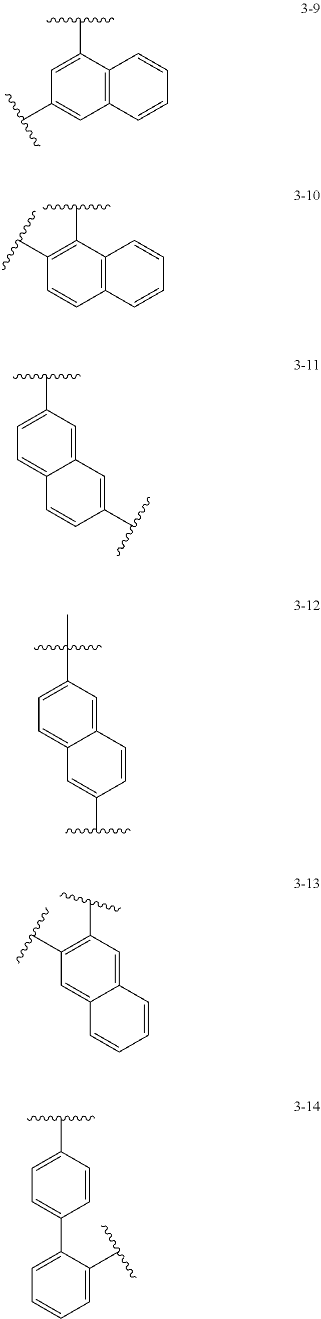 [SMILES: *c1cc(*)c2ccccc2c1 ; *c1ccc2ccccc2c1* ; *c1ccc2ccc(*)cc2c1 ; *c1ccc2cc(*)ccc2c1 ; *c1cc2ccccc2cc1* ; *c1ccc(-c2ccccc2*)cc1]

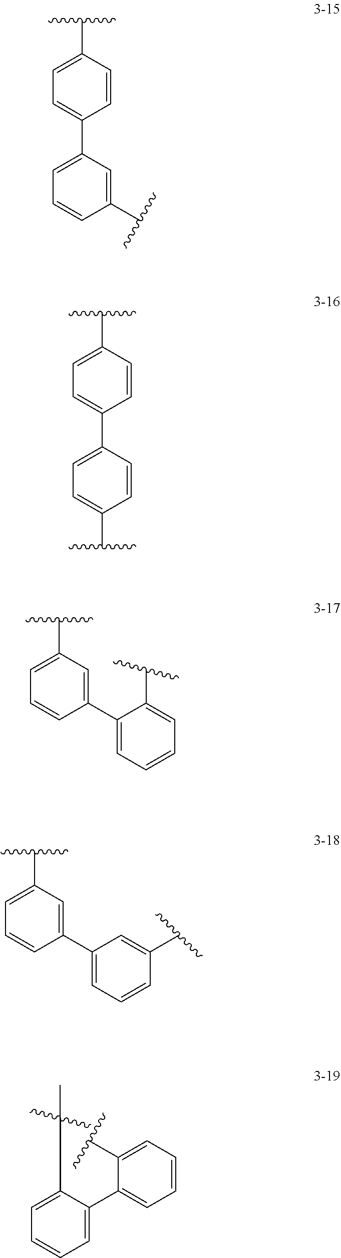 [SMILES: *c1ccc(-c2cccc(*)c2)cc1 ; *c1ccc(-c2ccc(*)cc2)cc1 ; *c1cccc(-c2ccccc2*)c1 ; *c1cccc(-c2cccc(*)c2)c1 ; *c1ccccc1-c1ccccc1*]

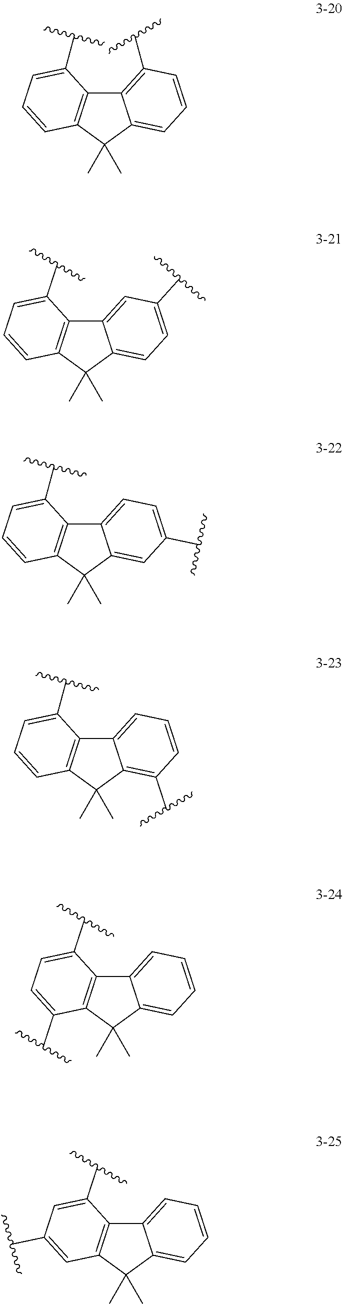 [SMILES: *c1cccc2c1-c1c(*)cccc1C2(C)C ; *c1ccc2c(c1)-c1c(*)cccc1C2(C)C ; *c1ccc2c(c1)C(C)(C)c1cccc(*)c1-2 ; *c1cccc2c1-c1cccc(*)c1C2(C)C ; *c1ccc(*)c2c1-c1ccccc1C2(C)C ; *c1cc(*)c2c(c1)C(C)(C)c1ccccc1-2]

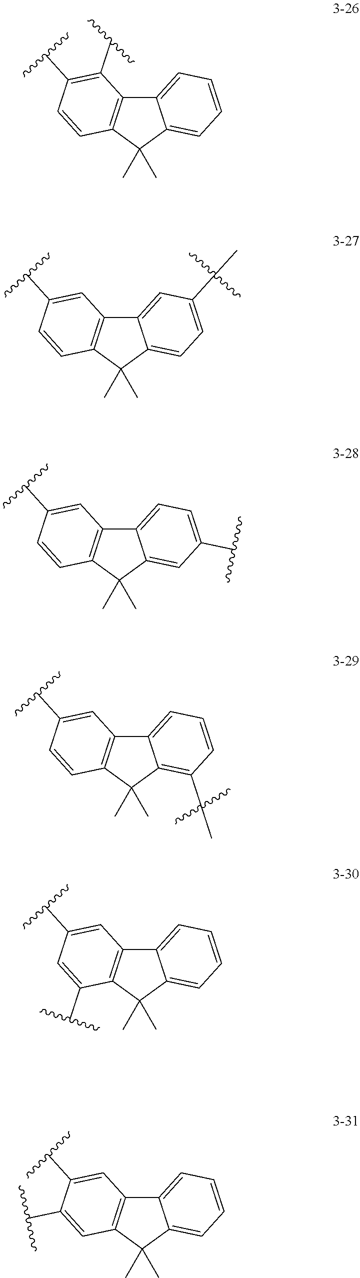 [SMILES: *c1ccc2c(c1*)-c1ccccc1C2(C)C ; *c1ccc2c(c1)-c1cc(*)ccc1C2(C)C ; *c1ccc2c(c1)-c1ccc(*)cc1C2(C)C ; *c1ccc2c(c1)-c1cccc(*)c1C2(C)C ; *c1cc(*)c2c(c1)-c1ccccc1C2(C)C ; *c1cc2c(cc1*)C(C)(C)c1ccccc1-2]

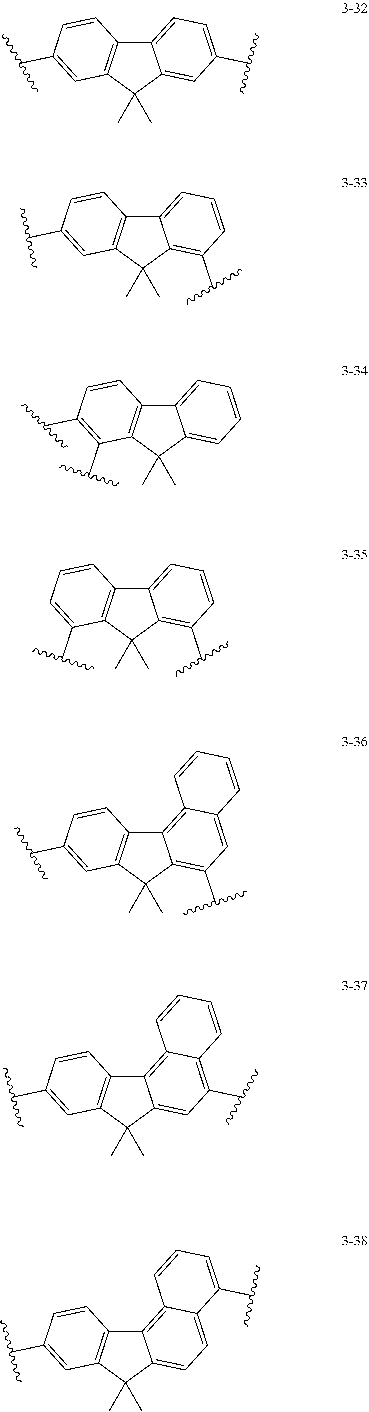

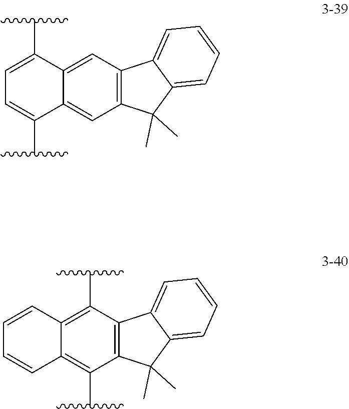 [SMILES: *c1ccc(*)c2cc3c(cc12)-c1ccccc1C3(C)C ; *c1c2c(c(*)c3ccccc13)C(C)(C)c1ccccc1-2]

The compound represented by formula 1 may be specifically exemplified by the following compounds but is not limited thereto.

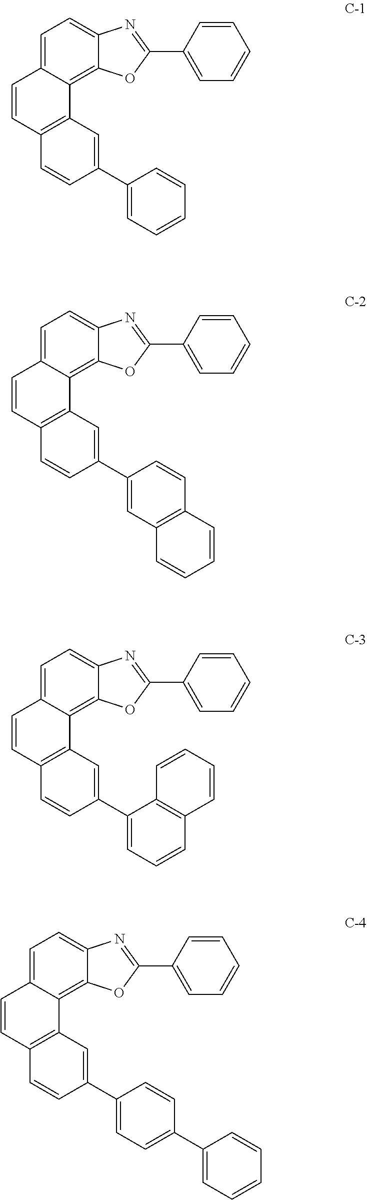 [SMILES: c1ccc(-c2ccc3ccc4ccc5nc(-c6ccccc6)oc5c4c3c2)cc1 ; c1ccc(-c2nc3ccc4ccc5ccc(-c6ccc7ccccc7c6)cc5c4c3o2)cc1 ; c1ccc(-c2nc3ccc4ccc5ccc(-c6cccc7ccccc67)cc5c4c3o2)cc1 ; c1ccc(-c2ccc(-c3ccc4ccc5ccc6nc(-c7ccccc7)oc6c5c4c3)cc2)cc1]

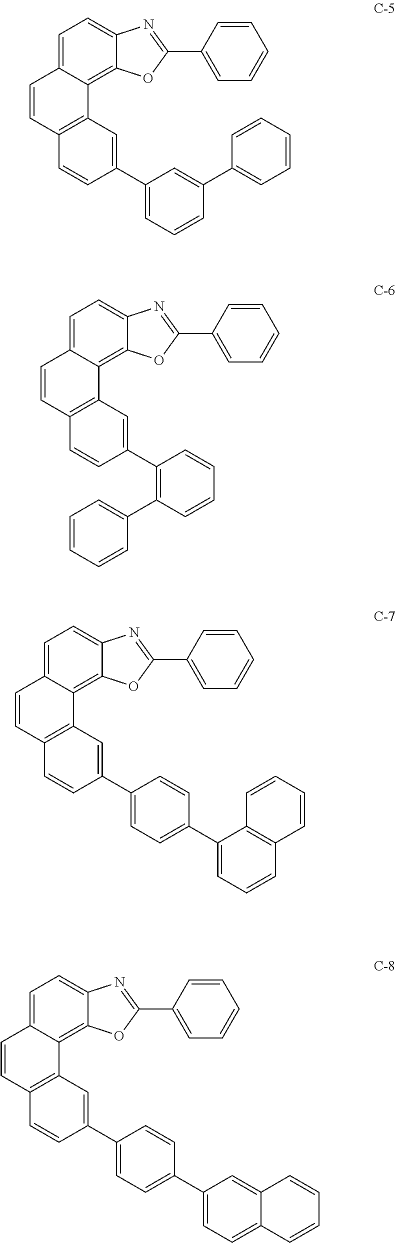 [SMILES: c1ccc(-c2cccc(-c3ccc4ccc5ccc6nc(-c7ccccc7)oc6c5c4c3)c2)cc1 ; c1ccc(-c2nc3ccc4ccc5ccc(-c6ccccc6-c6ccccc6)cc5c4c3o2)cc1 ; c1ccc(-c2nc3ccc4ccc5ccc(-c6ccc(-c7cccc8ccccc78)cc6)cc5c4c3o2)cc1 ; c1ccc(-c2nc3ccc4ccc5ccc(-c6ccc(-c7ccc8ccccc8c7)cc6)cc5c4c3o2)cc1]

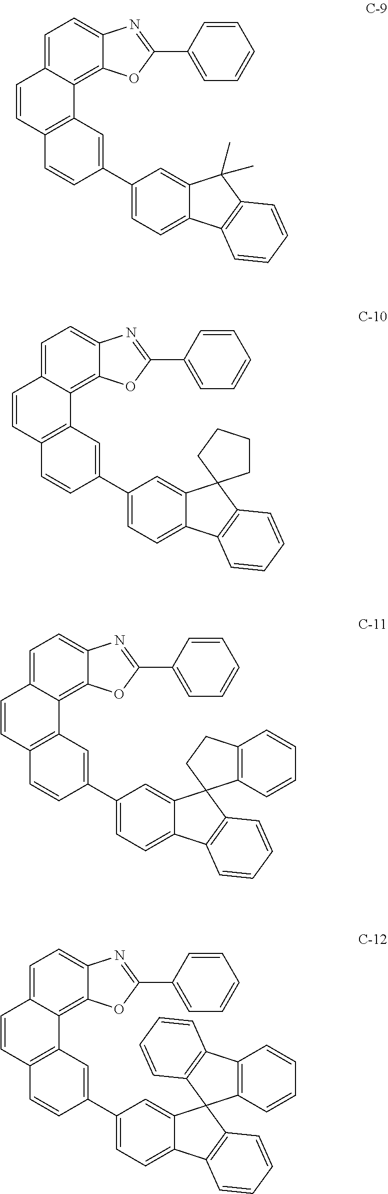 [SMILES: CC1(C)c2ccccc2-c2ccc(-c3ccc4ccc5ccc6nc(-c7ccccc7)oc6c5c4c3)cc21 ; c1ccc(-c2nc3ccc4ccc5ccc(-c6ccc7c(c6)C6(CCCC6)c6ccccc6-7)cc5c4c3o2)cc1 ; c1ccc(-c2nc3ccc4ccc5ccc(-c6ccc7c(c6)C6(CCc8ccccc86)c6ccccc6-7)cc5c4c3o2)cc1 ; c1ccc(-c2nc3ccc4ccc5ccc(-c6ccc7c(c6)C6(c8ccccc8-c8ccccc86)c6ccccc6-7)cc5c4c3o2)cc1]

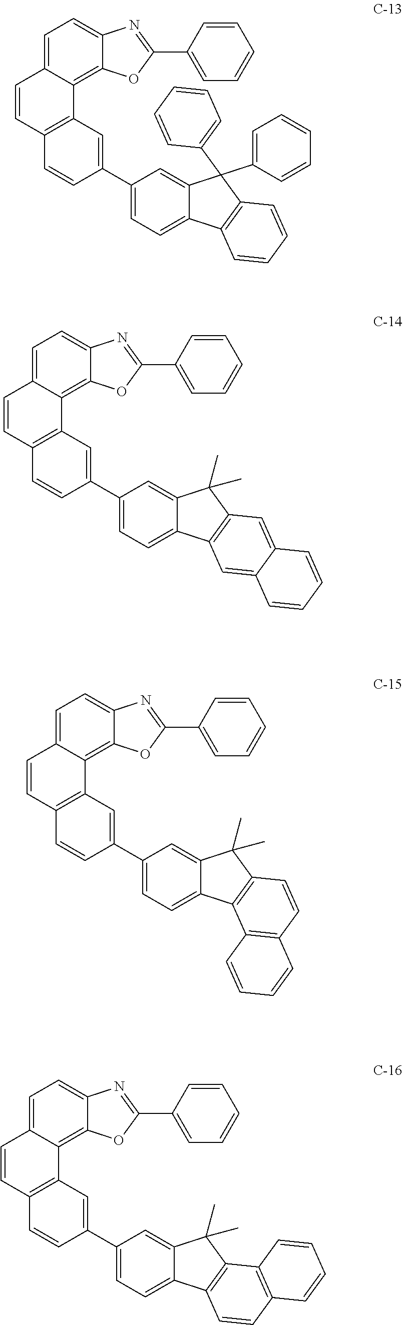 [SMILES: c1ccc(-c2nc3ccc4ccc5ccc(-c6ccc7c(c6)C(c6ccccc6)(c6ccccc6)c6ccccc6-7)cc5c4c3o2)cc1 ; CC1(C)c2cc(-c3ccc4ccc5ccc6nc(-c7ccccc7)oc6c5c4c3)ccc2-c2cc3ccccc3cc21 ; CC1(C)c2cc(-c3ccc4ccc5ccc6nc(-c7ccccc7)oc6c5c4c3)ccc2-c2c1ccc1ccccc21 ; CC1(C)c2cc(-c3ccc4ccc5ccc6nc(-c7ccccc7)oc6c5c4c3)ccc2-c2ccc3ccccc3c21]

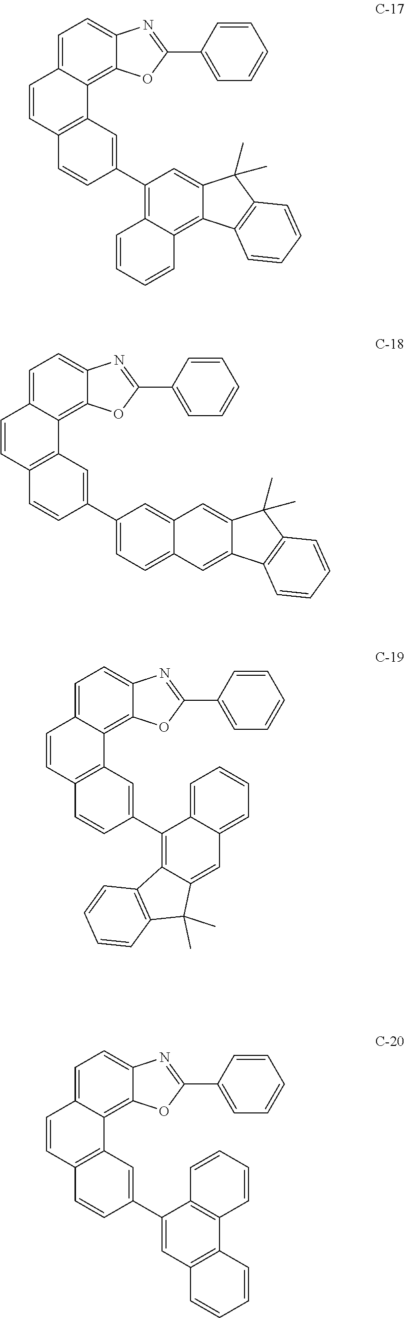 [SMILES: CC1(C)c2ccccc2-c2c1cc(-c1ccc3ccc4ccc5nc(-c6ccccc6)oc5c4c3c1)c1ccccc21 ; CC1(C)c2ccccc2-c2cc3ccc(-c4ccc5ccc6ccc7nc(-c8ccccc8)oc7c6c5c4)cc3cc21 ; CC1(C)c2ccccc2-c2c1cc1ccccc1c2-c1ccc2ccc3ccc4nc(-c5ccccc5)oc4c3c2c1 ; c1ccc(-c2nc3ccc4ccc5ccc(-c6cc7ccccc7c7ccccc67)cc5c4c3o2)cc1]

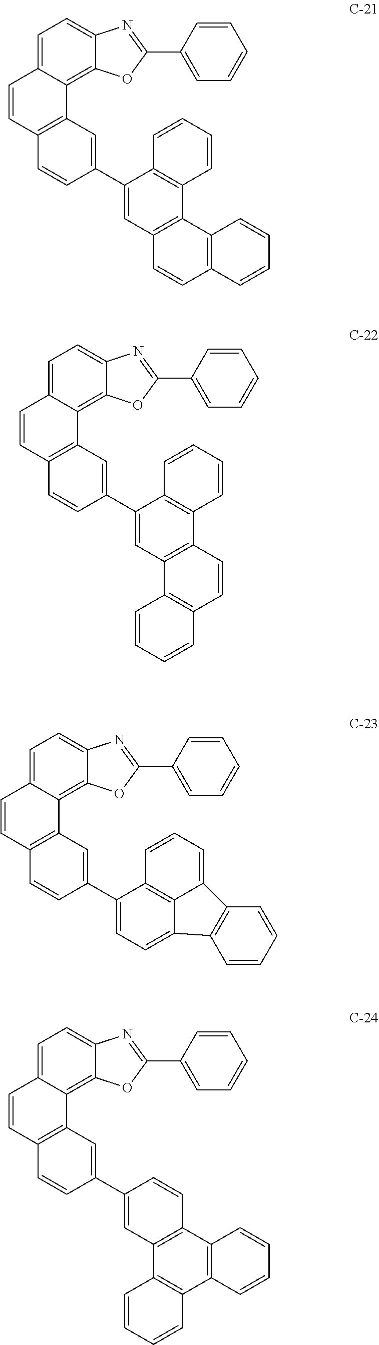 [SMILES: c1ccc(-c2nc3ccc4ccc5ccc(-c6cc7ccc8ccccc8c7c7ccccc67)cc5c4c3o2)cc1 ; c1ccc(-c2nc3ccc4ccc5ccc(-c6cc7c8ccccc8ccc7c7ccccc67)cc5c4c3o2)cc1 ; c1ccc(-c2nc3ccc4ccc5ccc(-c6ccc7c8c(cccc68)-c6ccccc6-7)cc5c4c3o2)cc1 ; c1ccc(-c2nc3ccc4ccc5ccc(-c6ccc7c8ccccc8c8ccccc8c7c6)cc5c4c3o2)cc1]

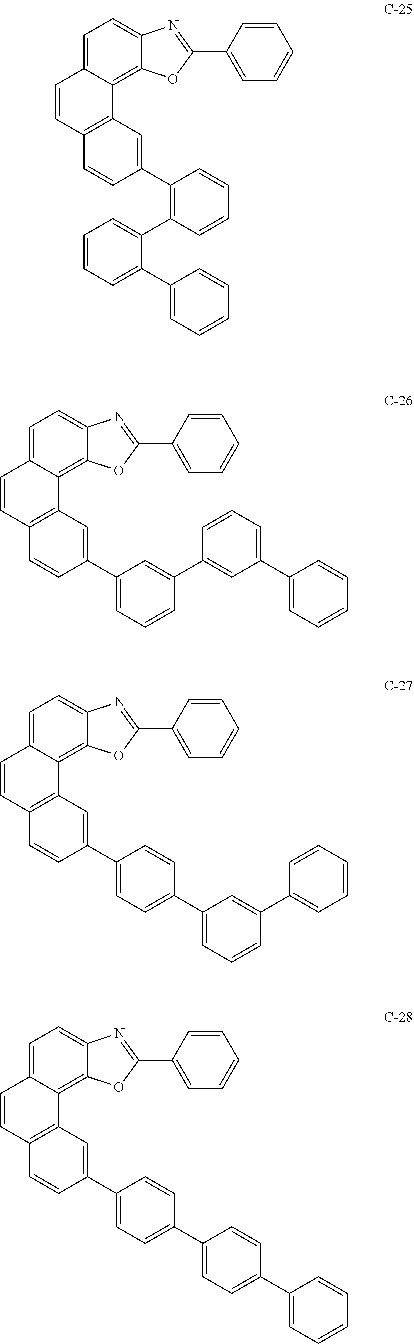 [SMILES: c1ccc(-c2nc3ccc4ccc5ccc(-c6ccccc6-c6ccccc6-c6ccccc6)cc5c4c3o2)cc1 ; c1ccc(-c2cccc(-c3cccc(-c4ccc5ccc6ccc7nc(-c8ccccc8)oc7c6c5c4)c3)c2)cc1 ; c1ccc(-c2cccc(-c3ccc(-c4ccc5ccc6ccc7nc(-c8ccccc8)oc7c6c5c4)cc3)c2)cc1 ; c1ccc(-c2ccc(-c3ccc(-c4ccc5ccc6ccc7nc(-c8ccccc8)oc7c6c5c4)cc3)cc2)cc1]

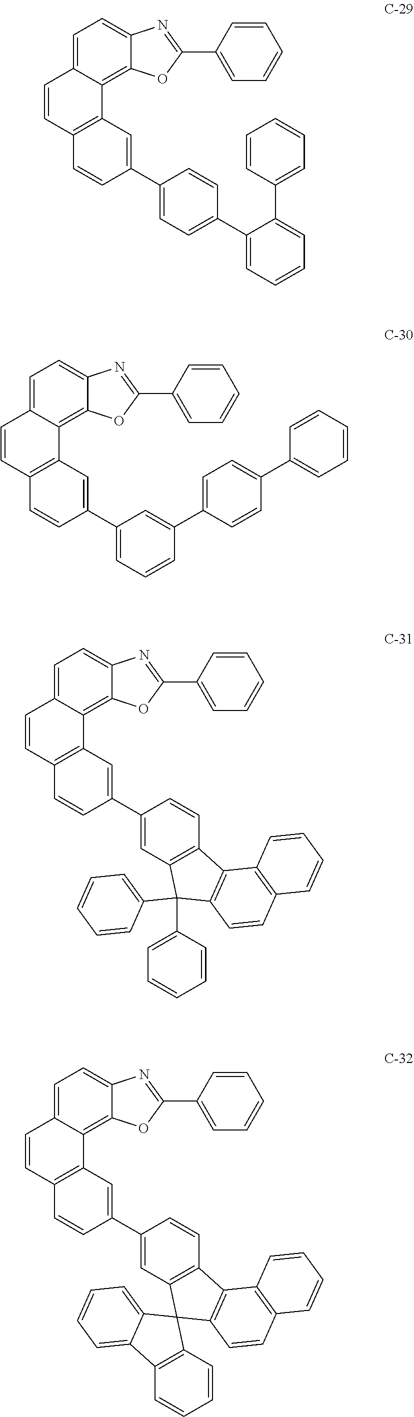 [SMILES: c1ccc(-c2nc3ccc4ccc5ccc(-c6ccc(-c7ccccc7-c7ccccc7)cc6)cc5c4c3o2)cc1 ; c1ccc(-c2ccc(-c3cccc(-c4ccc5ccc6ccc7nc(-c8ccccc8)oc7c6c5c4)c3)cc2)cc1 ; c1ccc(-c2nc3ccc4ccc5ccc(-c6ccc7c(c6)C(c6ccccc6)(c6ccccc6)c6ccc8ccccc8c6-7)cc5c4c3o2)cc1 ; c1ccc(-c2nc3ccc4ccc5ccc(-c6ccc7c(c6)C6(c8ccccc8-c8ccccc86)c6ccc8ccccc8c6-7)cc5c4c3o2)cc1]

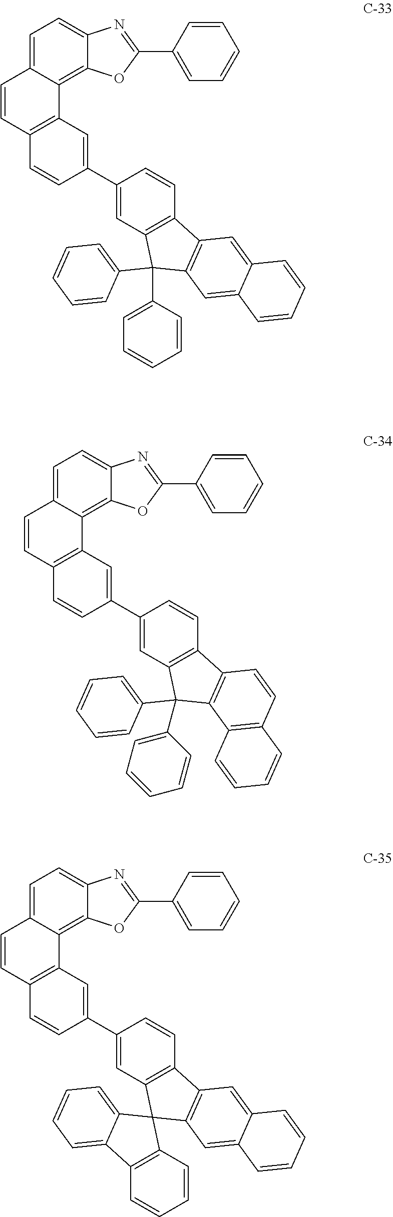 [SMILES: c1ccc(-c2nc3ccc4ccc5ccc(-c6ccc7c(c6)C(c6ccccc6)(c6ccccc6)c6cc8ccccc8cc6-7)cc5c4c3o2)cc1 ; c1ccc(-c2nc3ccc4ccc5ccc(-c6ccc7c(c6)C(c6ccccc6)(c6ccccc6)c6c-7ccc7ccccc67)cc5c4c3o2)cc1 ; c1ccc(-c2nc3ccc4ccc5ccc(-c6ccc7c(c6)C6(c8ccccc8-c8ccccc86)c6cc8ccccc8cc6-7)cc5c4c3o2)cc1]

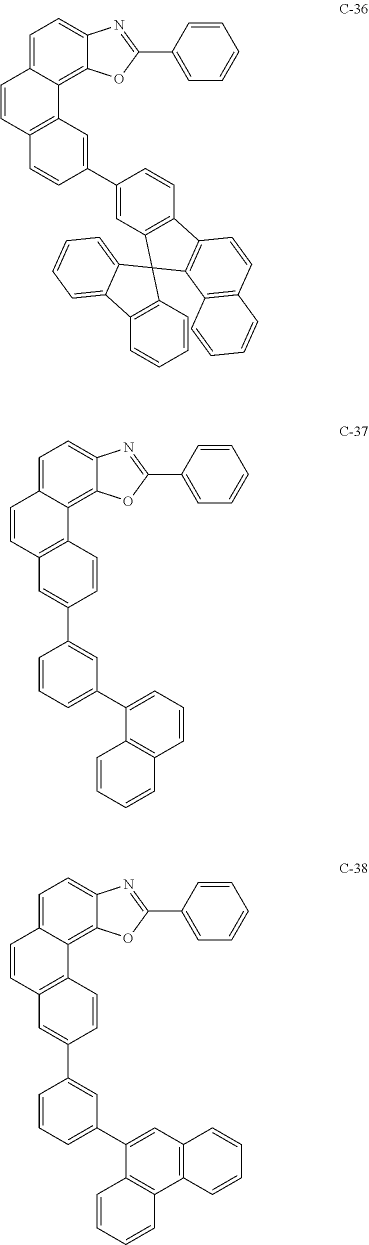 [SMILES: c1ccc(-c2nc3ccc4ccc5ccc(-c6ccc7c(c6)C6(c8ccccc8-c8ccccc86)c6c-7ccc7ccccc67)cc5c4c3o2)cc1 ; c1ccc(-c2nc3ccc4ccc5cc(-c6cccc(-c7cccc8ccccc78)c6)ccc5c4c3o2)cc1 ; c1ccc(-c2nc3ccc4ccc5cc(-c6cccc(-c7cc8ccccc8c8ccccc78)c6)ccc5c4c3o2)cc1]

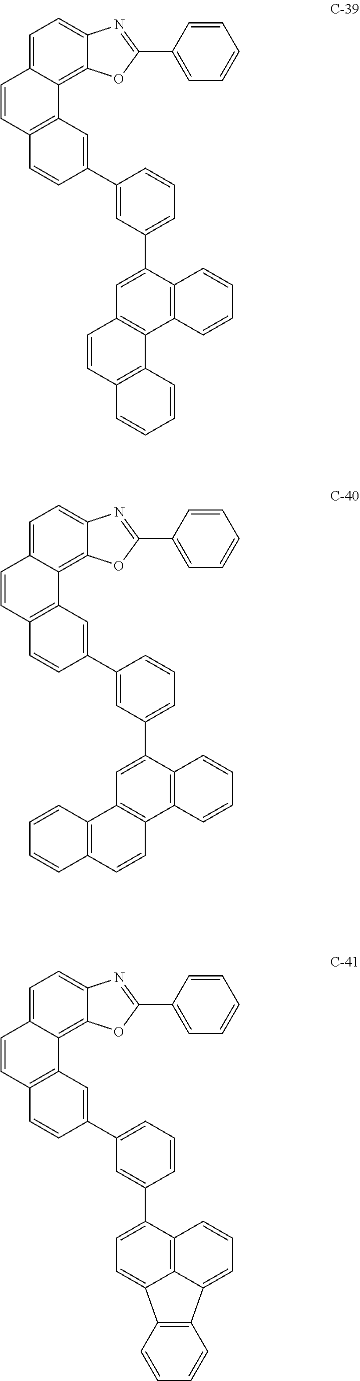 [SMILES: c1ccc(-c2nc3ccc4ccc5ccc(-c6cccc(-c7cc8ccc9ccccc9c8c8ccccc78)c6)cc5c4c3o2)cc1 ; c1ccc(-c2nc3ccc4ccc5ccc(-c6cccc(-c7cc8c9ccccc9ccc8c8ccccc78)c6)cc5c4c3o2)cc1 ; c1ccc(-c2nc3ccc4ccc5ccc(-c6cccc(-c7ccc8c9c(cccc79)-c7ccccc7-8)c6)cc5c4c3o2)cc1]

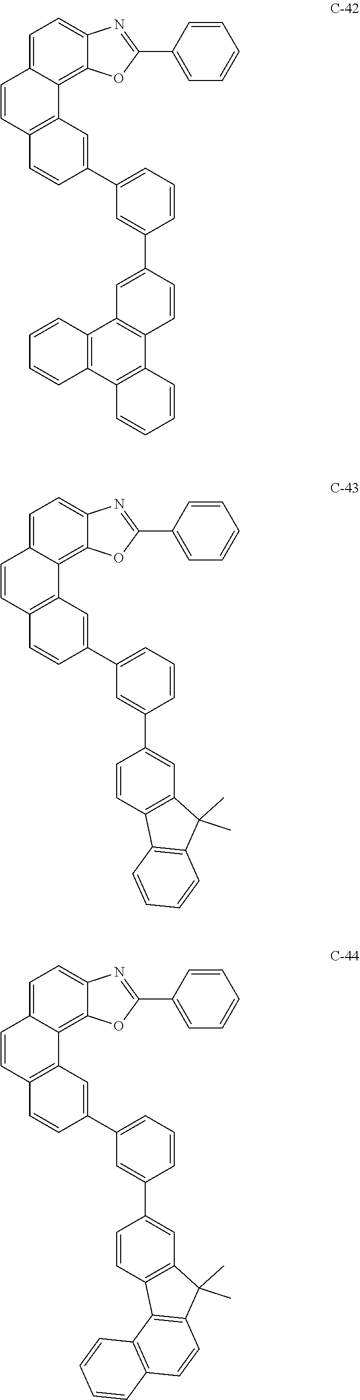 [SMILES: c1ccc(-c2nc3ccc4ccc5ccc(-c6cccc(-c7ccc8c9ccccc9c9ccccc9c8c7)c6)cc5c4c3o2)cc1 ; CC1(C)c2ccccc2-c2ccc(-c3cccc(-c4ccc5ccc6ccc7nc(-c8ccccc8)oc7c6c5c4)c3)cc21 ; CC1(C)c2cc(-c3cccc(-c4ccc5ccc6ccc7nc(-c8ccccc8)oc7c6c5c4)c3)ccc2-c2c1ccc1ccccc21]

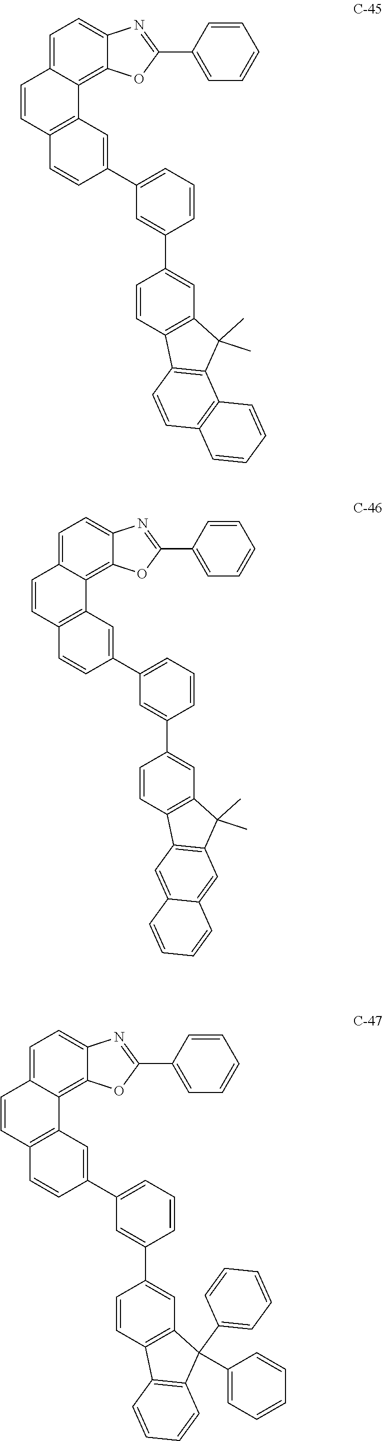 [SMILES: CC1(C)c2cc(-c3cccc(-c4ccc5ccc6ccc7nc(-c8ccccc8)oc7c6c5c4)c3)ccc2-c2ccc3ccccc3c21 ; CC1(C)c2cc(-c3cccc(-c4ccc5ccc6ccc7nc(-c8ccccc8)oc7c6c5c4)c3)ccc2-c2cc3ccccc3cc21 ; c1ccc(-c2nc3ccc4ccc5ccc(-c6cccc(-c7ccc8c(c7)C(c7ccccc7)(c7ccccc7)c7ccccc7-8)c6)cc5c4c3o2)cc1]

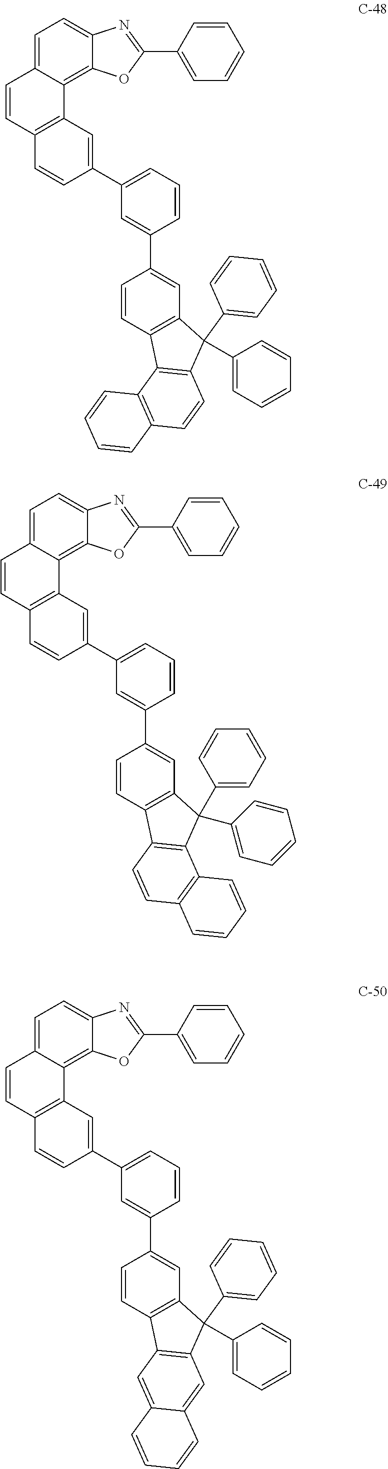 [SMILES: c1ccc(-c2nc3ccc4ccc5ccc(-c6cccc(-c7ccc8c(c7)C(c7ccccc7)(c7ccccc7)c7ccc9ccccc9c7-8)c6)cc5c4c3o2)cc1 ; c1ccc(-c2nc3ccc4ccc5ccc(-c6cccc(-c7ccc8c(c7)C(c7ccccc7)(c7ccccc7)c7c-8ccc8ccccc78)c6)cc5c4c3o2)cc1 ; c1ccc(-c2nc3ccc4ccc5ccc(-c6cccc(-c7ccc8c(c7)C(c7ccccc7)(c7ccccc7)c7cc9ccccc9cc7-8)c6)cc5c4c3o2)cc1]

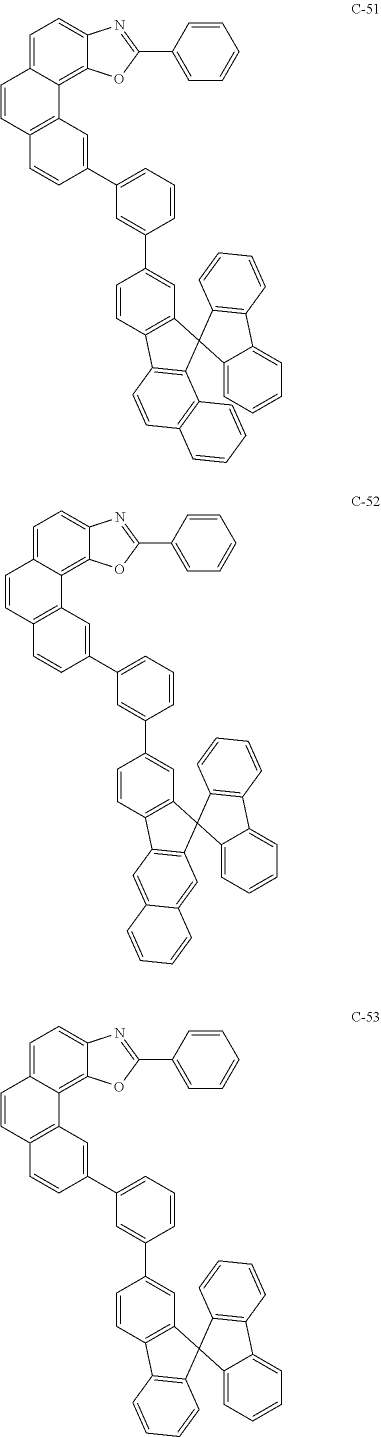 [SMILES: c1ccc(-c2nc3ccc4ccc5ccc(-c6cccc(-c7ccc8c(c7)C7(c9ccccc9-c9ccccc97)c7c-8ccc8ccccc78)c6)cc5c4c3o2)cc1 ; c1ccc(-c2nc3ccc4ccc5ccc(-c6cccc(-c7ccc8c(c7)C7(c9ccccc9-c9ccccc97)c7cc9ccccc9cc7-8)c6)cc5c4c3o2)cc1 ; c1ccc(-c2nc3ccc4ccc5ccc(-c6cccc(-c7ccc8c(c7)C7(c9ccccc9-c9ccccc97)c7ccccc7-8)c6)cc5c4c3o2)cc1]

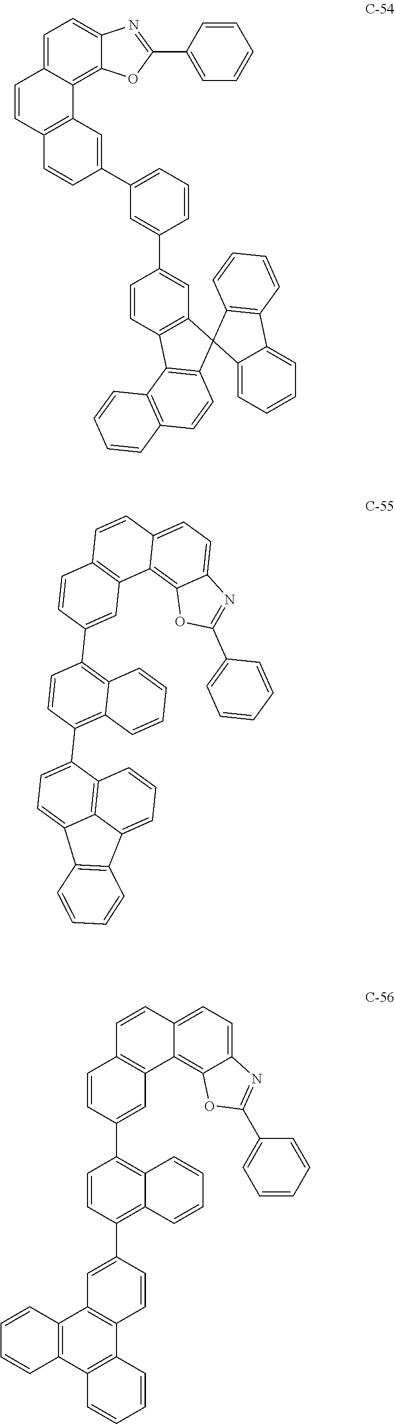 [SMILES: c1ccc(-c2nc3ccc4ccc5ccc(-c6cccc(-c7ccc8c(c7)C7(c9ccccc9-c9ccccc97)c7ccc9ccccc9c7-8)c6)cc5c4c3o2)cc1 ; c1ccc(-c2nc3ccc4ccc5ccc(-c6ccc(-c7ccc8c9c(cccc79)-c7ccccc7-8)c7ccccc67)cc5c4c3o2)cc1 ; c1ccc(-c2nc3ccc4ccc5ccc(-c6ccc(-c7ccc8c9ccccc9c9ccccc9c8c7)c7ccccc67)cc5c4c3o2)cc1]

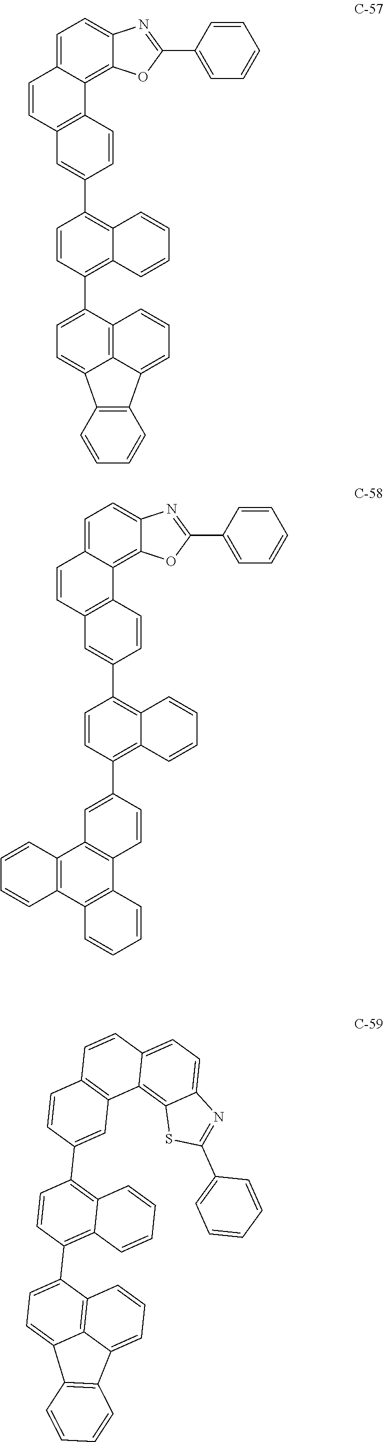

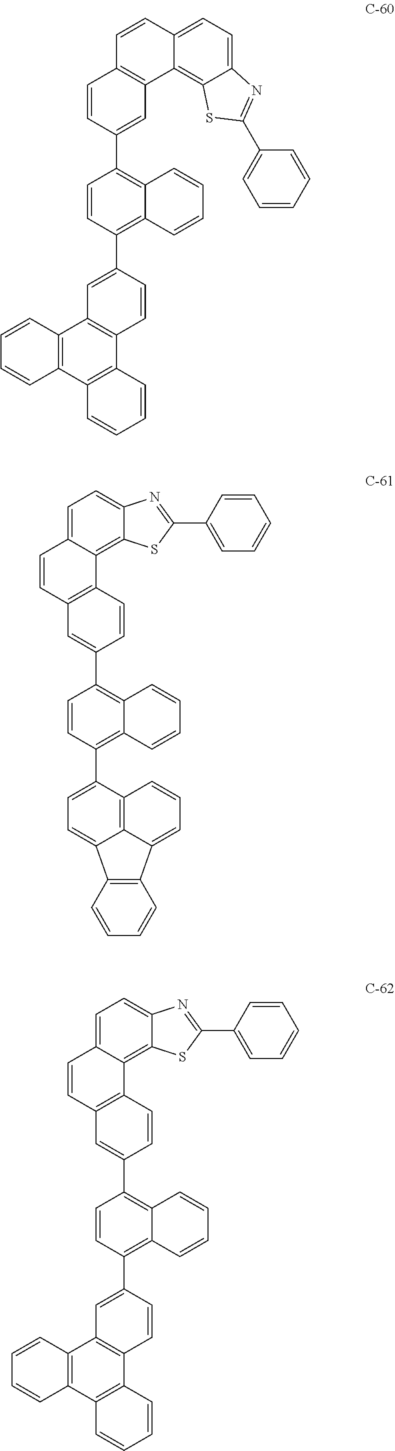 [SMILES: c1ccc(-c2nc3ccc4ccc5ccc(-c6ccc(-c7ccc8c9ccccc9c9ccccc9c8c7)c7ccccc67)cc5c4c3s2)cc1 ; c1ccc(-c2nc3ccc4ccc5cc(-c6ccc(-c7ccc8c9c(cccc79)-c7ccccc7-8)c7ccccc67)ccc5c4c3s2)cc1 ; c1ccc(-c2nc3ccc4ccc5cc(-c6ccc(-c7ccc8c9ccccc9c9ccccc9c8c7)c7ccccc67)ccc5c4c3s2)cc1]

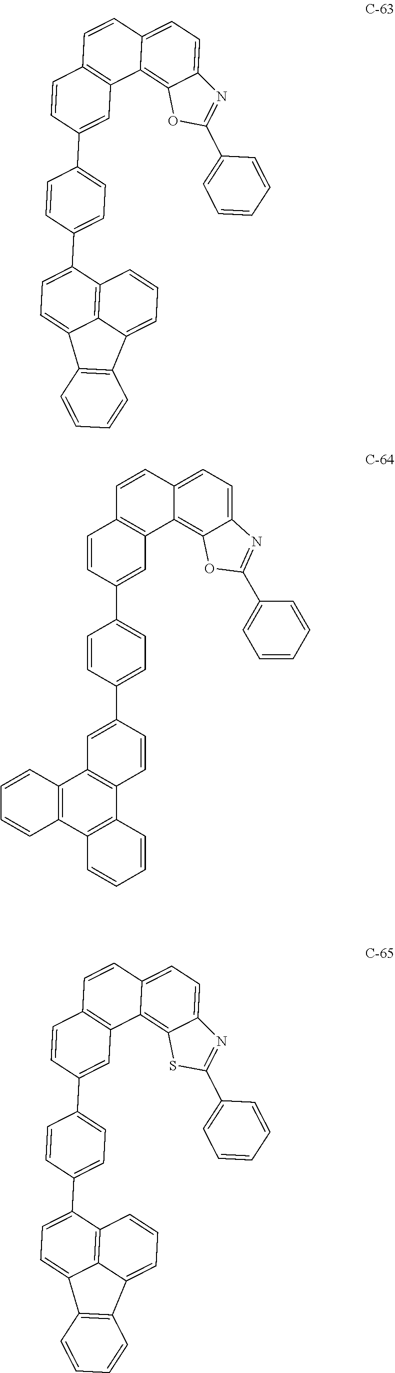 [SMILES: c1ccc(-c2nc3ccc4ccc5ccc(-c6ccc(-c7ccc8c9c(cccc79)-c7ccccc7-8)cc6)cc5c4c3o2)cc1 ; c1ccc(-c2nc3ccc4ccc5ccc(-c6ccc(-c7ccc8c9ccccc9c9ccccc9c8c7)cc6)cc5c4c3o2)cc1 ; c1ccc(-c2nc3ccc4ccc5ccc(-c6ccc(-c7ccc8c9c(cccc79)-c7ccccc7-8)cc6)cc5c4c3s2)cc1]

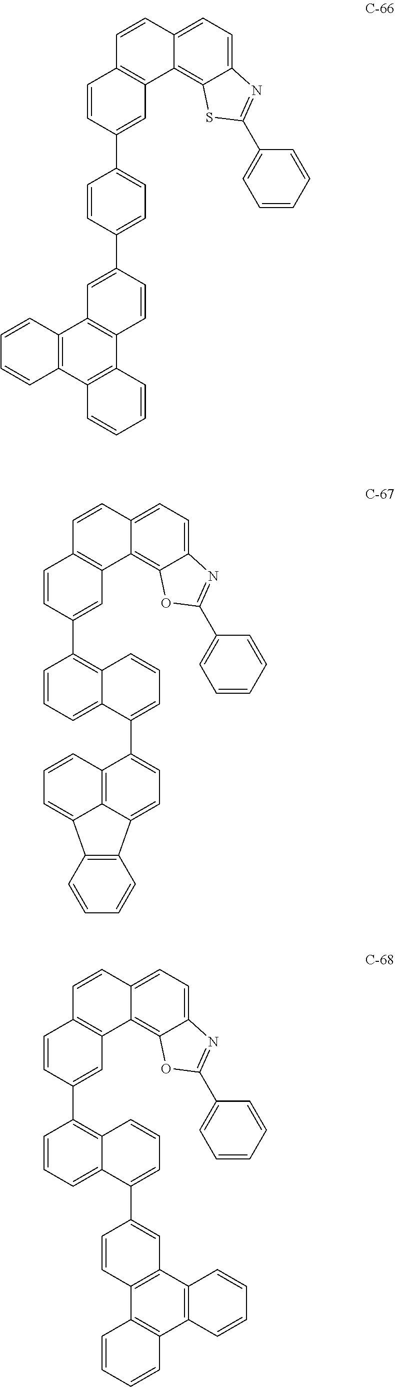 [SMILES: c1ccc(-c2nc3ccc4ccc5ccc(-c6ccc(-c7ccc8c9ccccc9c9ccccc9c8c7)cc6)cc5c4c3s2)cc1 ; c1ccc(-c2nc3ccc4ccc5ccc(-c6cccc7c(-c8ccc9c%10c(cccc8%10)-c8ccccc8-9)cccc67)cc5c4c3o2)cc1 ; c1ccc(-c2nc3ccc4ccc5ccc(-c6cccc7c(-c8ccc9c%10ccccc%10c%10ccccc%10c9c8)cccc67)cc5c4c3o2)cc1]

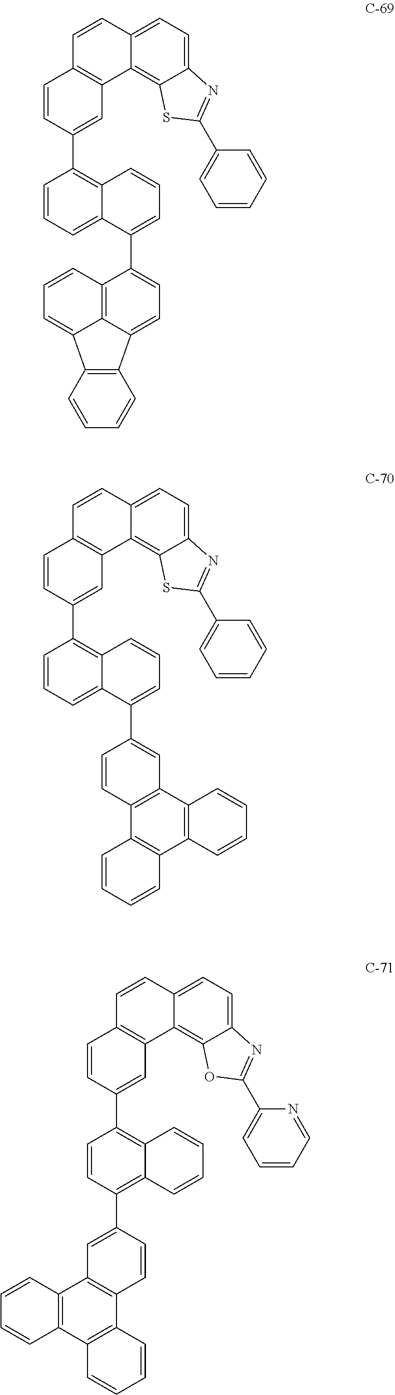 [SMILES: c1ccc(-c2nc3ccc4ccc5ccc(-c6cccc7c(-c8ccc9c%10c(cccc8%10)-c8ccccc8-9)cccc67)cc5c4c3s2)cc1 ; c1ccc(-c2nc3ccc4ccc5ccc(-c6cccc7c(-c8ccc9c%10ccccc%10c%10ccccc%10c9c8)cccc67)cc5c4c3s2)cc1 ; c1ccc(-c2nc3ccc4ccc5ccc(-c6ccc(-c7ccc8c9ccccc9c9ccccc9c8c7)c7ccccc67)cc5c4c3o2)nc1]

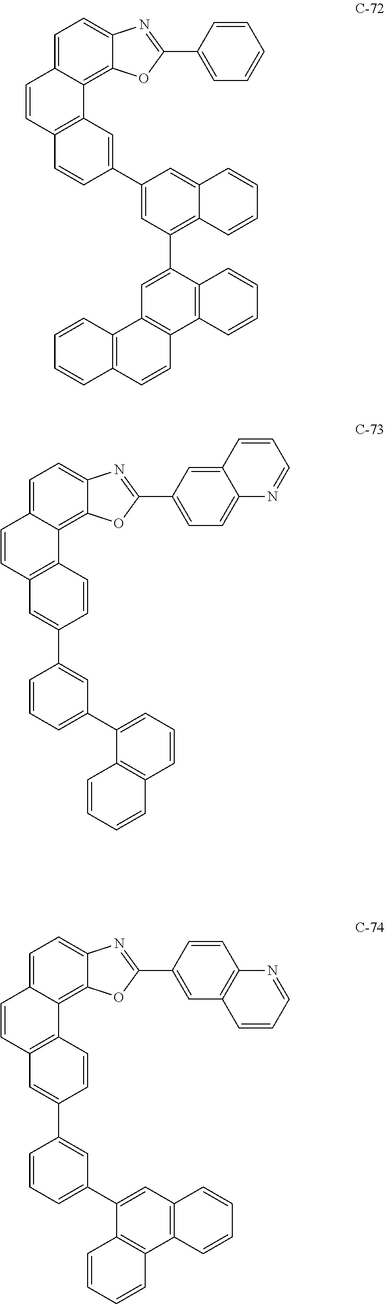 [SMILES: c1ccc(-c2nc3ccc4ccc5ccc(-c6cc(-c7cc8c9ccccc9ccc8c8ccccc78)c7ccccc7c6)cc5c4c3o2)cc1 ; c1cc(-c2ccc3c(ccc4ccc5nc(-c6ccc7ncccc7c6)oc5c43)c2)cc(-c2cccc3ccccc23)c1 ; c1cc(-c2ccc3c(ccc4ccc5nc(-c6ccc7ncccc7c6)oc5c43)c2)cc(-c2cc3ccccc3c3ccccc23)c1]

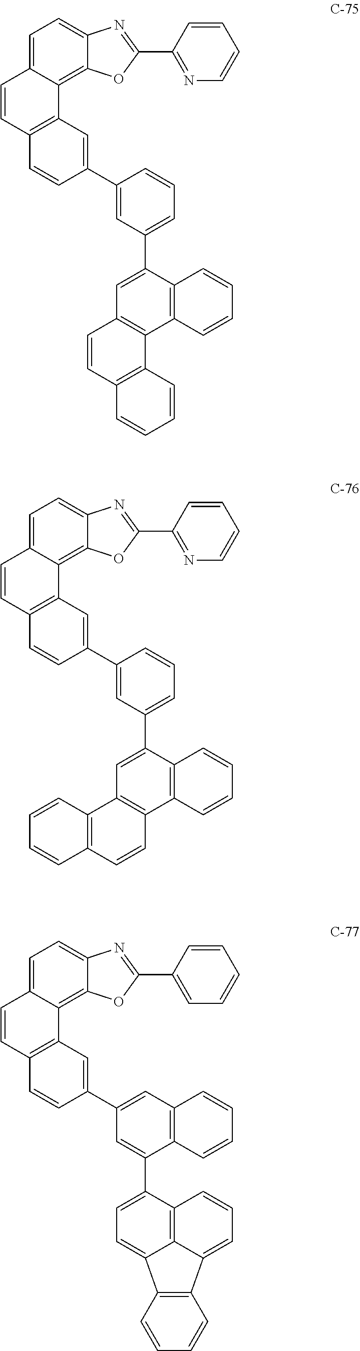 [SMILES: c1ccc(-c2nc3ccc4ccc5ccc(-c6cccc(-c7cc8ccc9ccccc9c8c8ccccc78)c6)cc5c4c3o2)nc1 ; c1ccc(-c2nc3ccc4ccc5ccc(-c6cccc(-c7cc8c9ccccc9ccc8c8ccccc78)c6)cc5c4c3o2)nc1 ; c1ccc(-c2nc3ccc4ccc5ccc(-c6cc(-c7ccc8c9c(cccc79)-c7ccccc7-8)c7ccccc7c6)cc5c4c3o2)cc1]

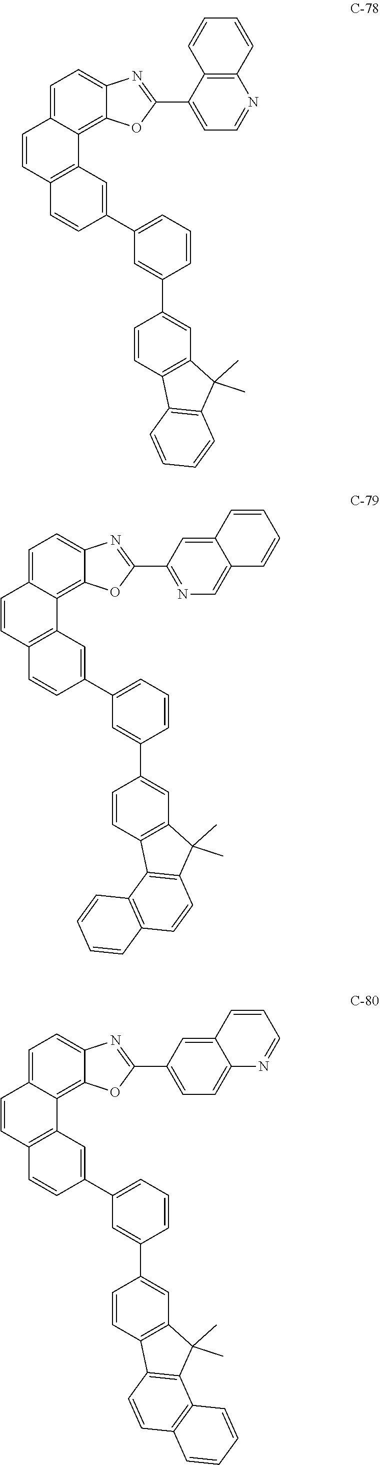 [SMILES: CC1(C)c2ccccc2-c2ccc(-c3cccc(-c4ccc5ccc6ccc7nc(-c8ccnc9ccccc89)oc7c6c5c4)c3)cc21 ; CC1(C)c2cc(-c3cccc(-c4ccc5ccc6ccc7nc(-c8cc9ccccc9cn8)oc7c6c5c4)c3)ccc2-c2c1ccc1ccccc21 ; CC1(C)c2cc(-c3cccc(-c4ccc5ccc6ccc7nc(-c8ccc9ncccc9c8)oc7c6c5c4)c3)ccc2-c2ccc3ccccc3c21]

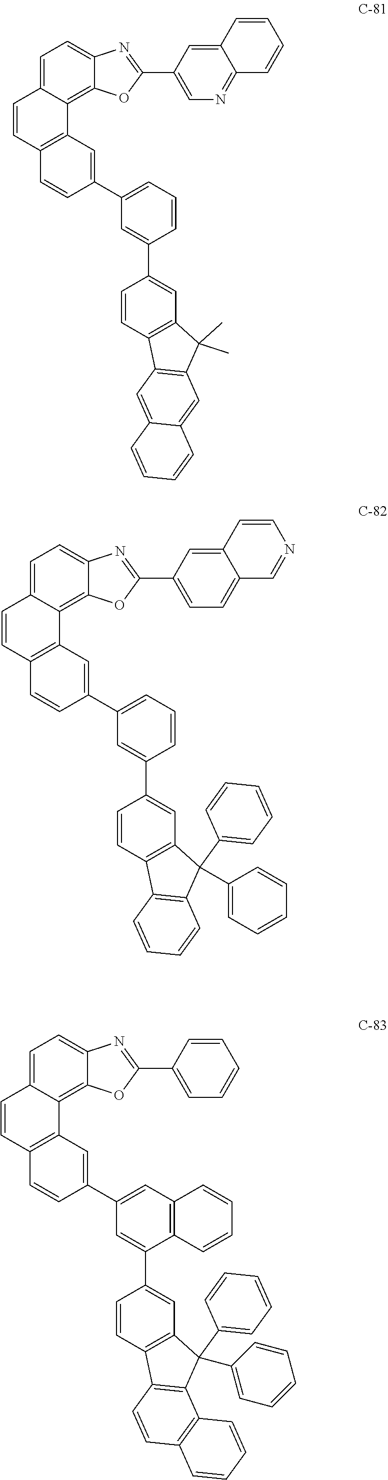 [SMILES: CC1(C)c2cc(-c3cccc(-c4ccc5ccc6ccc7nc(-c8cnc9ccccc9c8)oc7c6c5c4)c3)ccc2-c2cc3ccccc3cc21 ; c1ccc(C2(c3ccccc3)c3ccccc3-c3ccc(-c4cccc(-c5ccc6ccc7ccc8nc(-c9ccc%10cnccc%10c9)oc8c7c6c5)c4)cc32)cc1 ; c1ccc(-c2nc3ccc4ccc5ccc(-c6cc(-c7ccc8c(c7)C(c7ccccc7)(c7ccccc7)c7c-8ccc8ccccc78)c7ccccc7c6)cc5c4c3o2)cc1]

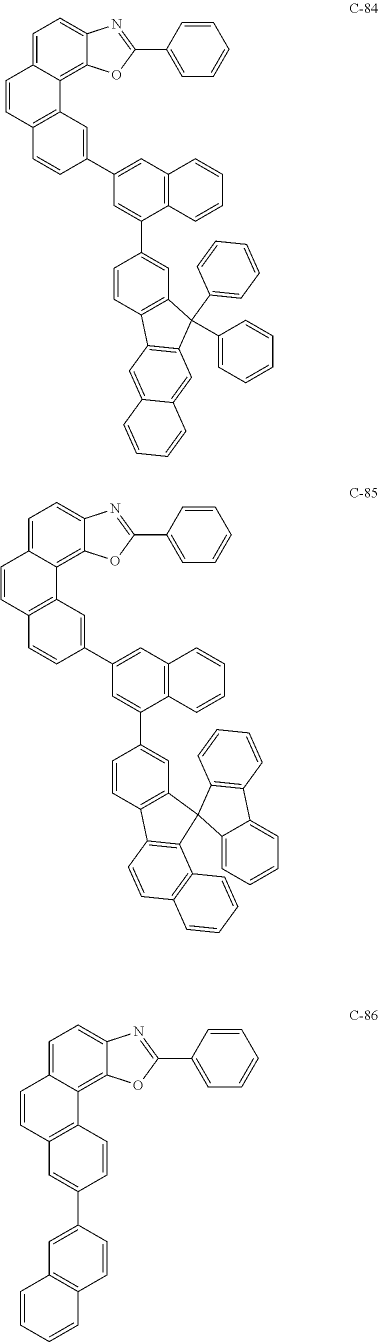 [SMILES: c1ccc(-c2nc3ccc4ccc5ccc(-c6cc(-c7ccc8c(c7)C(c7ccccc7)(c7ccccc7)c7cc9ccccc9cc7-8)c7ccccc7c6)cc5c4c3o2)cc1 ; c1ccc(-c2nc3ccc4ccc5ccc(-c6cc(-c7ccc8c(c7)C7(c9ccccc9-c9ccccc97)c7c-8ccc8ccccc78)c7ccccc7c6)cc5c4c3o2)cc1 ; c1ccc(-c2nc3ccc4ccc5cc(-c6ccc7ccccc7c6)ccc5c4c3o2)cc1]

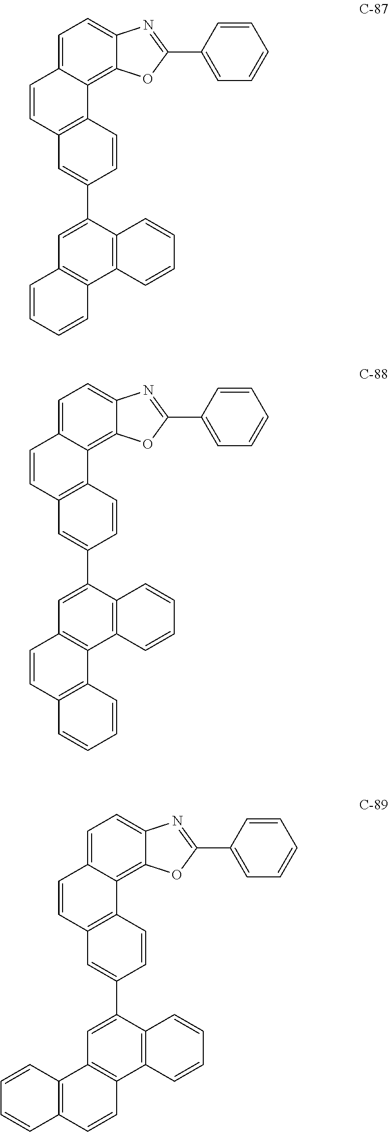 [SMILES: c1ccc(-c2nc3ccc4ccc5cc(-c6cc7ccccc7c7ccccc67)ccc5c4c3o2)cc1 ; c1ccc(-c2nc3ccc4ccc5cc(-c6cc7ccc8ccccc8c7c7ccccc67)ccc5c4c3o2)cc1 ; c1ccc(-c2nc3ccc4ccc5cc(-c6cc7c8ccccc8ccc7c7ccccc67)ccc5c4c3o2)cc1]

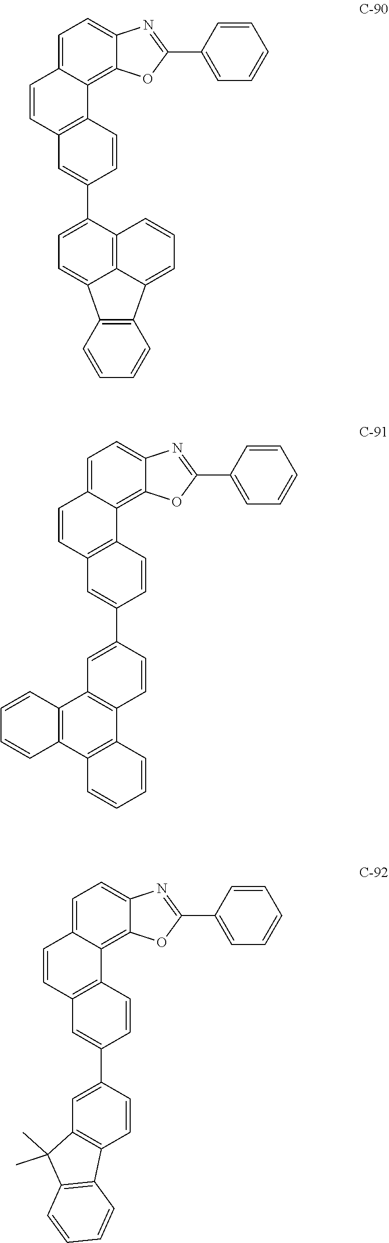 [SMILES: c1ccc(-c2nc3ccc4ccc5cc(-c6ccc7c8c(cccc68)-c6ccccc6-7)ccc5c4c3o2)cc1 ; c1ccc(-c2nc3ccc4ccc5cc(-c6ccc7c8ccccc8c8ccccc8c7c6)ccc5c4c3o2)cc1 ; CC1(C)c2ccccc2-c2ccc(-c3ccc4c(ccc5ccc6nc(-c7ccccc7)oc6c54)c3)cc21]

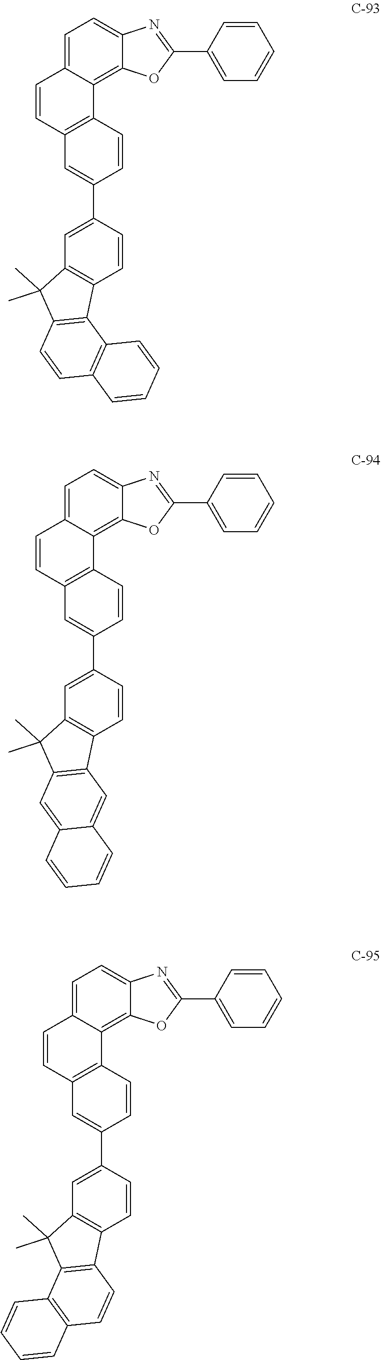 [SMILES: CC1(C)c2cc(-c3ccc4c(ccc5ccc6nc(-c7ccccc7)oc6c54)c3)ccc2-c2c1ccc1ccccc21 ; CC1(C)c2cc(-c3ccc4c(ccc5ccc6nc(-c7ccccc7)oc6c54)c3)ccc2-c2cc3ccccc3cc21 ; CC1(C)c2cc(-c3ccc4c(ccc5ccc6nc(-c7ccccc7)oc6c54)c3)ccc2-c2ccc3ccccc3c21]

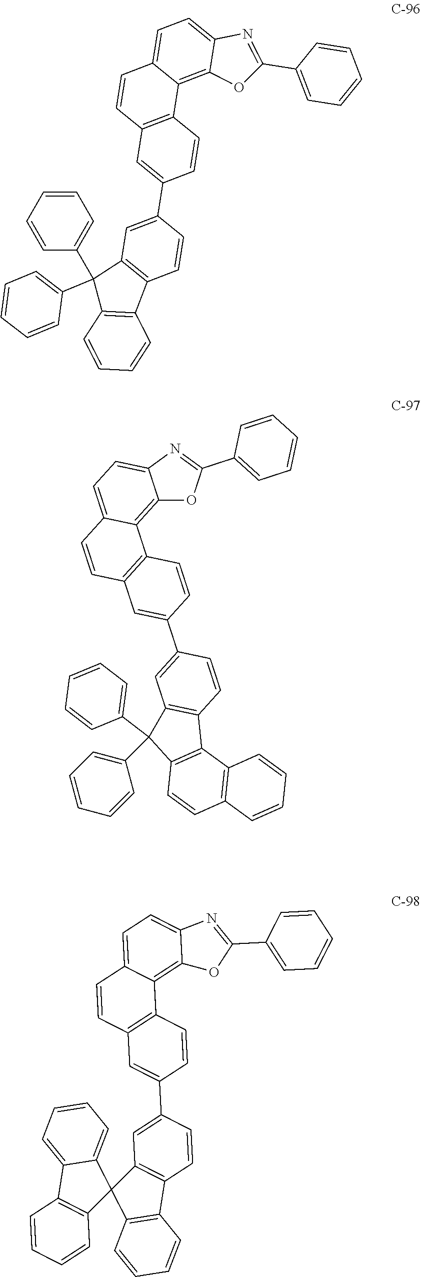 [SMILES: c1ccc(-c2nc3ccc4ccc5cc(-c6ccc7c(c6)C(c6ccccc6)(c6ccccc6)c6ccccc6-7)ccc5c4c3o2)cc1 ; c1ccc(-c2nc3ccc4ccc5cc(-c6ccc7c(c6)C(c6ccccc6)(c6ccccc6)c6ccc8ccccc8c6-7)ccc5c4c3o2)cc1 ; c1ccc(-c2nc3ccc4ccc5cc(-c6ccc7c(c6)C6(c8ccccc8-c8ccccc86)c6ccccc6-7)ccc5c4c3o2)cc1]

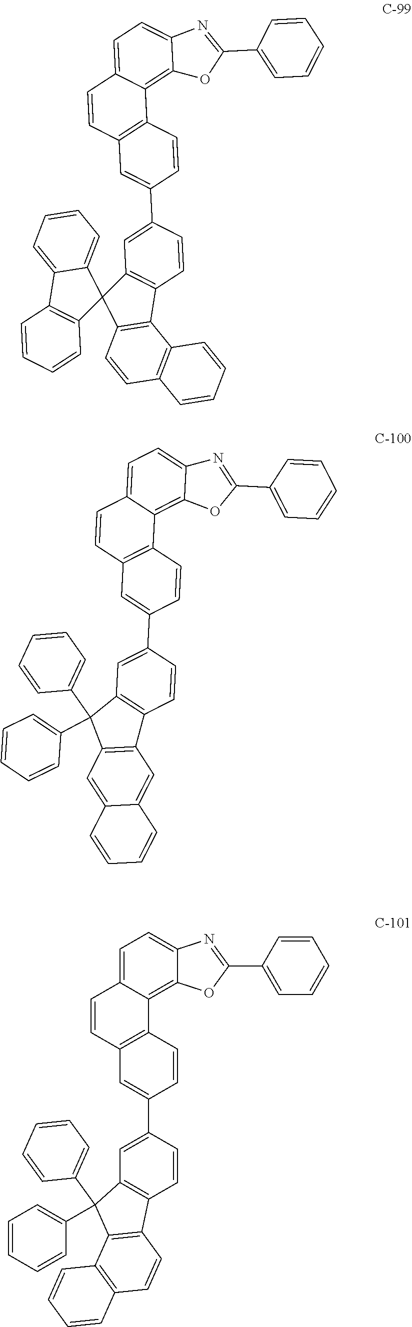 [SMILES: c1ccc(-c2nc3ccc4ccc5cc(-c6ccc7c(c6)C6(c8ccccc8-c8ccccc86)c6ccc8ccccc8c6-7)ccc5c4c3o2)cc1 ; c1ccc(-c2nc3ccc4ccc5cc(-c6ccc7c(c6)C(c6ccccc6)(c6ccccc6)c6cc8ccccc8cc6-7)ccc5c4c3o2)cc1 ; c1ccc(-c2nc3ccc4ccc5cc(-c6ccc7c(c6)C(c6ccccc6)(c6ccccc6)c6c-7ccc7ccccc67)ccc5c4c3o2)cc1]

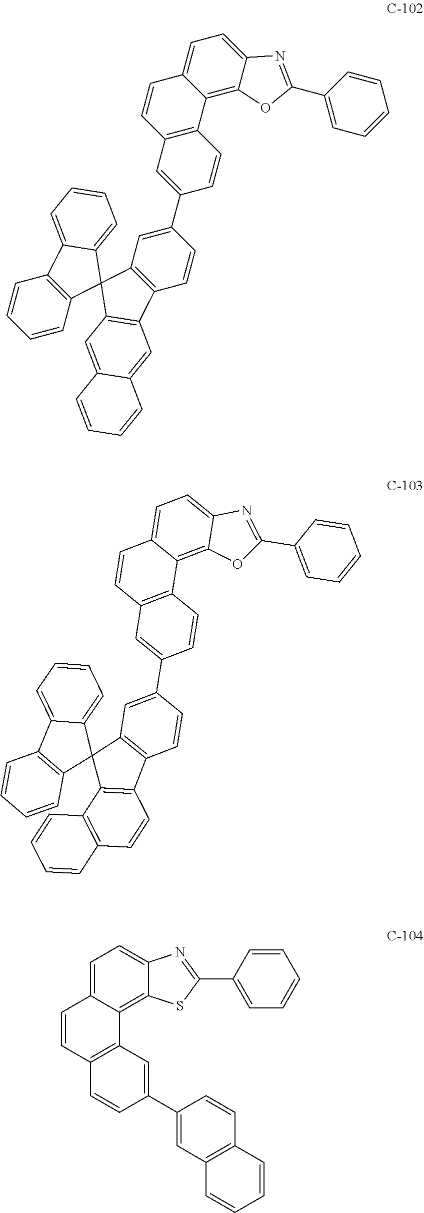 [SMILES: c1ccc(-c2nc3ccc4ccc5cc(-c6ccc7c(c6)C6(c8ccccc8-c8ccccc86)c6cc8ccccc8cc6-7)ccc5c4c3o2)cc1 ; c1ccc(-c2nc3ccc4ccc5cc(-c6ccc7c(c6)C6(c8ccccc8-c8ccccc86)c6c-7ccc7ccccc67)ccc5c4c3o2)cc1 ; c1ccc(-c2nc3ccc4ccc5ccc(-c6ccc7ccccc7c6)cc5c4c3s2)cc1]

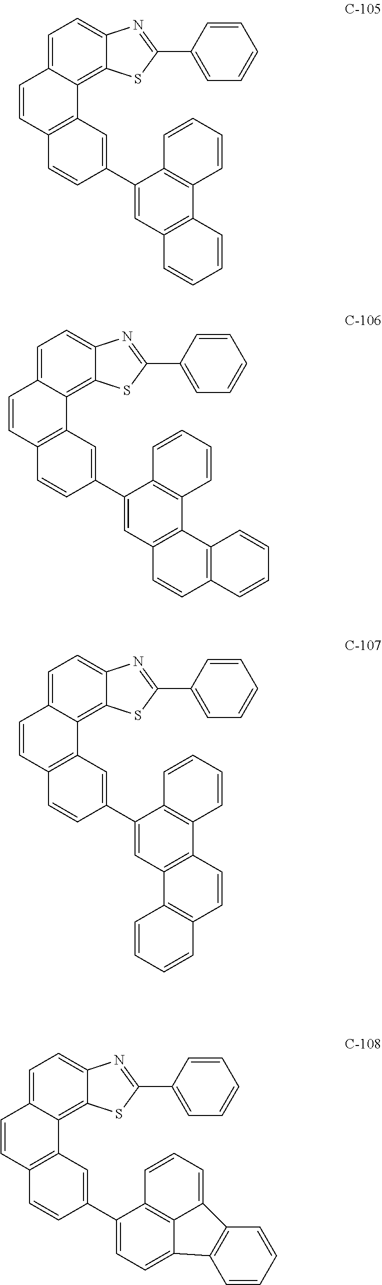 [SMILES: c1ccc(-c2nc3ccc4ccc5ccc(-c6cc7ccccc7c7ccccc67)cc5c4c3s2)cc1 ; c1ccc(-c2nc3ccc4ccc5ccc(-c6cc7ccc8ccccc8c7c7ccccc67)cc5c4c3s2)cc1 ; c1ccc(-c2nc3ccc4ccc5ccc(-c6cc7c8ccccc8ccc7c7ccccc67)cc5c4c3s2)cc1 ; c1ccc(-c2nc3ccc4ccc5ccc(-c6ccc7c8c(cccc68)-c6ccccc6-7)cc5c4c3s2)cc1]

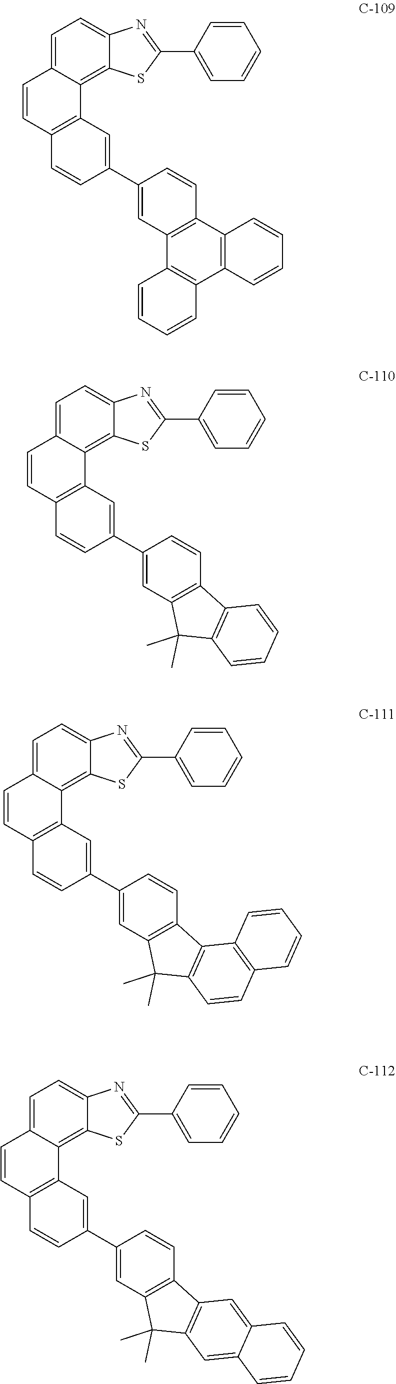 [SMILES: c1ccc(-c2nc3ccc4ccc5ccc(-c6ccc7c8ccccc8c8ccccc8c7c6)cc5c4c3s2)cc1 ; CC1(C)c2ccccc2-c2ccc(-c3ccc4ccc5ccc6nc(-c7ccccc7)sc6c5c4c3)cc21 ; CC1(C)c2cc(-c3ccc4ccc5ccc6nc(-c7ccccc7)sc6c5c4c3)ccc2-c2c1ccc1ccccc21 ; CC1(C)c2cc(-c3ccc4ccc5ccc6nc(-c7ccccc7)sc6c5c4c3)ccc2-c2cc3ccccc3cc21]

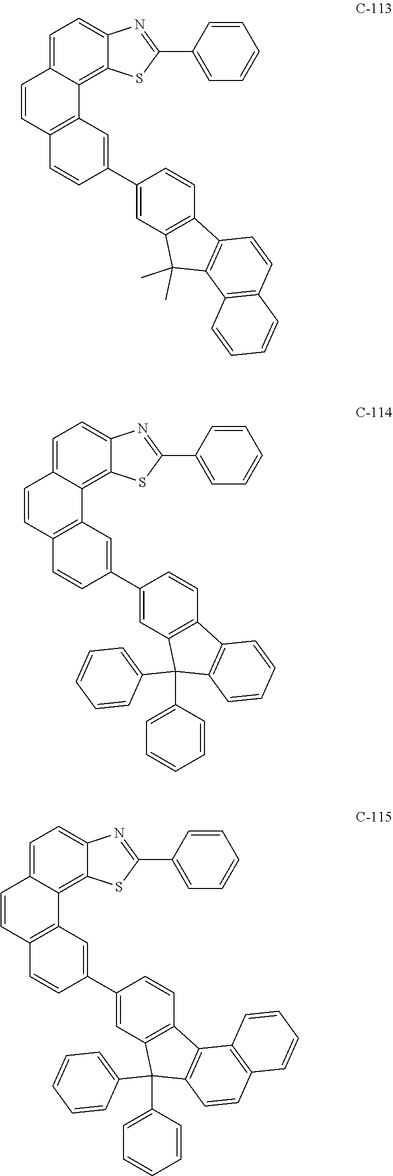 [SMILES: CC1(C)c2cc(-c3ccc4ccc5ccc6nc(-c7ccccc7)sc6c5c4c3)ccc2-c2ccc3ccccc3c21 ; c1ccc(-c2nc3ccc4ccc5ccc(-c6ccc7c(c6)C(c6ccccc6)(c6ccccc6)c6ccccc6-7)cc5c4c3s2)cc1 ; c1ccc(-c2nc3ccc4ccc5ccc(-c6ccc7c(c6)C(c6ccccc6)(c6ccccc6)c6ccc8ccccc8c6-7)cc5c4c3s2)cc1]

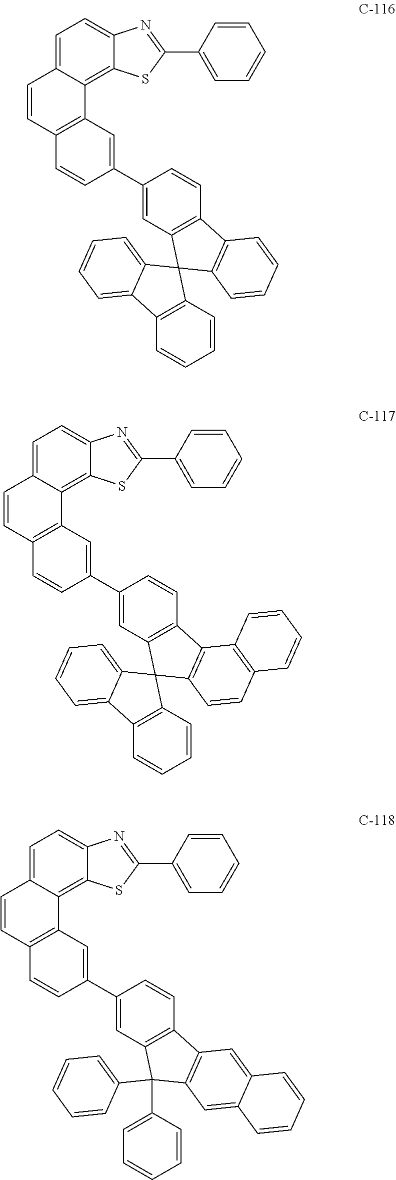 [SMILES: c1ccc(-c2nc3ccc4ccc5ccc(-c6ccc7c(c6)C6(c8ccccc8-c8ccccc86)c6ccccc6-7)cc5c4c3s2)cc1 ; c1ccc(-c2nc3ccc4ccc5ccc(-c6ccc7c(c6)C6(c8ccccc8-c8ccccc86)c6ccc8ccccc8c6-7)cc5c4c3s2)cc1 ; c1ccc(-c2nc3ccc4ccc5ccc(-c6ccc7c(c6)C(c6ccccc6)(c6ccccc6)c6cc8ccccc8cc6-7)cc5c4c3s2)cc1]

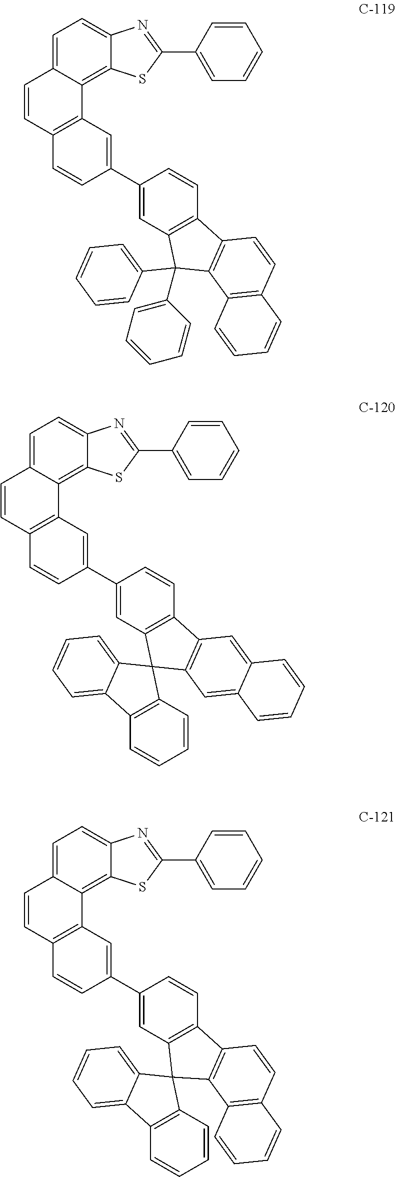 [SMILES: c1ccc(-c2nc3ccc4ccc5ccc(-c6ccc7c(c6)C(c6ccccc6)(c6ccccc6)c6c-7ccc7ccccc67)cc5c4c3s2)cc1 ; c1ccc(-c2nc3ccc4ccc5ccc(-c6ccc7c(c6)C6(c8ccccc8-c8ccccc86)c6cc8ccccc8cc6-7)cc5c4c3s2)cc1 ; c1ccc(-c2nc3ccc4ccc5ccc(-c6ccc7c(c6)C6(c8ccccc8-c8ccccc86)c6c-7ccc7ccccc67)cc5c4c3s2)cc1]

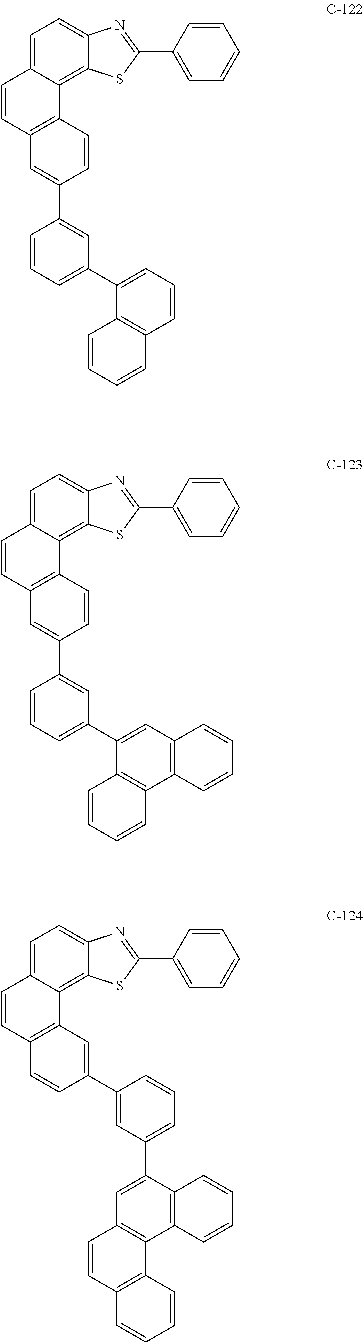 [SMILES: c1ccc(-c2nc3ccc4ccc5cc(-c6cccc(-c7cccc8ccccc78)c6)ccc5c4c3s2)cc1 ; c1ccc(-c2nc3ccc4ccc5cc(-c6cccc(-c7cc8ccccc8c8ccccc78)c6)ccc5c4c3s2)cc1 ; c1ccc(-c2nc3ccc4ccc5ccc(-c6cccc(-c7cc8ccc9ccccc9c8c8ccccc78)c6)cc5c4c3s2)cc1]

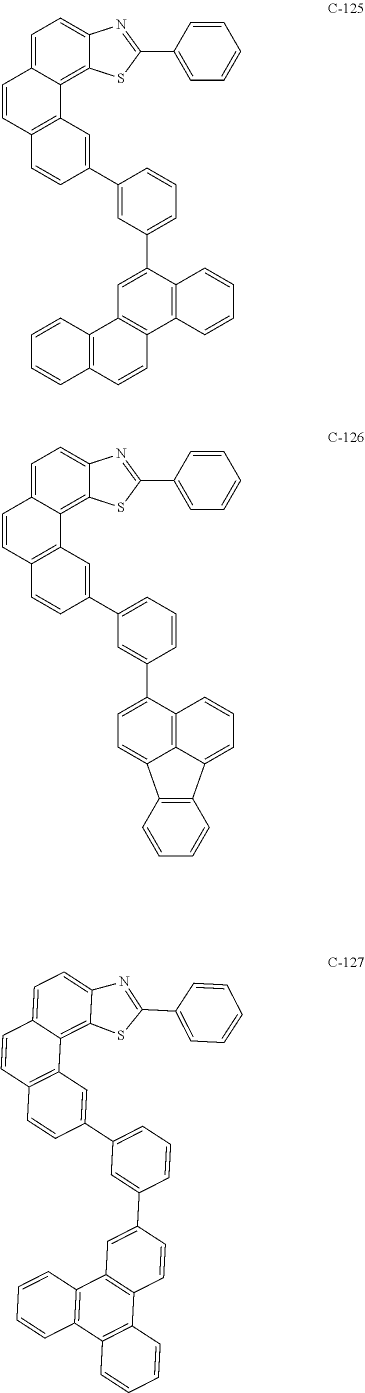 [SMILES: c1ccc(-c2nc3ccc4ccc5ccc(-c6cccc(-c7cc8c9ccccc9ccc8c8ccccc78)c6)cc5c4c3s2)cc1 ; c1ccc(-c2nc3ccc4ccc5ccc(-c6cccc(-c7ccc8c9c(cccc79)-c7ccccc7-8)c6)cc5c4c3s2)cc1 ; c1ccc(-c2nc3ccc4ccc5ccc(-c6cccc(-c7ccc8c9ccccc9c9ccccc9c8c7)c6)cc5c4c3s2)cc1]

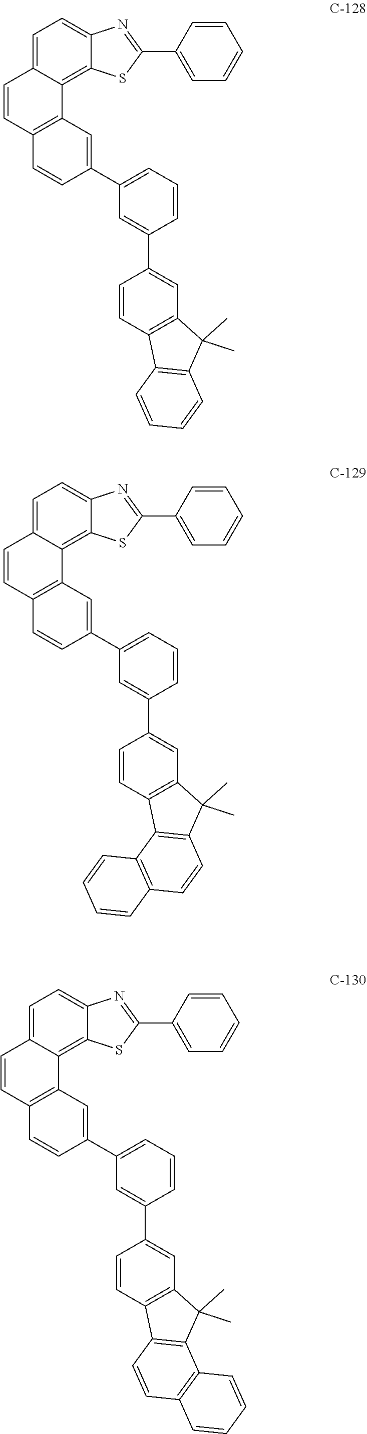 [SMILES: CC1(C)c2ccccc2-c2ccc(-c3cccc(-c4ccc5ccc6ccc7nc(-c8ccccc8)sc7c6c5c4)c3)cc21 ; CC1(C)c2cc(-c3cccc(-c4ccc5ccc6ccc7nc(-c8ccccc8)sc7c6c5c4)c3)ccc2-c2c1ccc1ccccc21 ; CC1(C)c2cc(-c3cccc(-c4ccc5ccc6ccc7nc(-c8ccccc8)sc7c6c5c4)c3)ccc2-c2ccc3ccccc3c21]

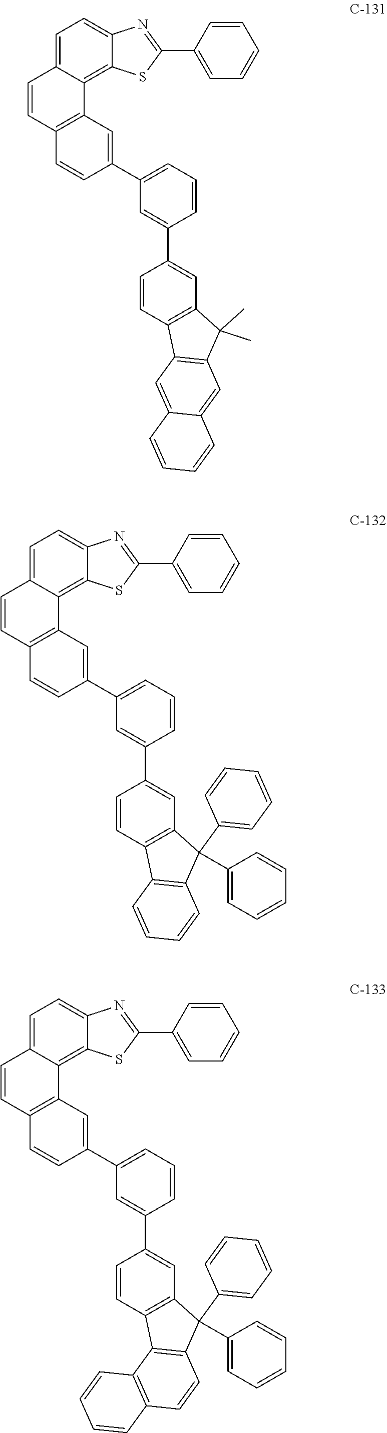 [SMILES: CC1(C)c2cc(-c3cccc(-c4ccc5ccc6ccc7nc(-c8ccccc8)sc7c6c5c4)c3)ccc2-c2cc3ccccc3cc21 ; c1ccc(-c2nc3ccc4ccc5ccc(-c6cccc(-c7ccc8c(c7)C(c7ccccc7)(c7ccccc7)c7ccccc7-8)c6)cc5c4c3s2)cc1 ; c1ccc(-c2nc3ccc4ccc5ccc(-c6cccc(-c7ccc8c(c7)C(c7ccccc7)(c7ccccc7)c7ccc9ccccc9c7-8)c6)cc5c4c3s2)cc1]

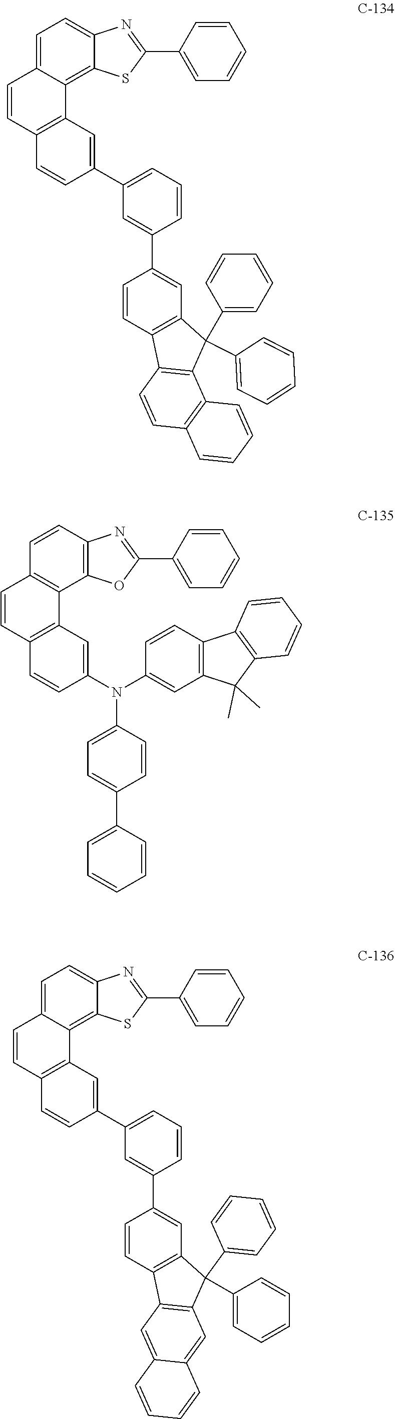 [SMILES: c1ccc(-c2nc3ccc4ccc5ccc(-c6cccc(-c7ccc8c(c7)C(c7ccccc7)(c7ccccc7)c7c-8ccc8ccccc78)c6)cc5c4c3s2)cc1 ; CC1(C)c2ccccc2-c2ccc(N(c3ccc(-c4ccccc4)cc3)c3ccc4ccc5ccc6nc(-c7ccccc7)oc6c5c4c3)cc21 ; c1ccc(-c2nc3ccc4ccc5ccc(-c6cccc(-c7ccc8c(c7)C(c7ccccc7)(c7ccccc7)c7cc9ccccc9cc7-8)c6)cc5c4c3s2)cc1]

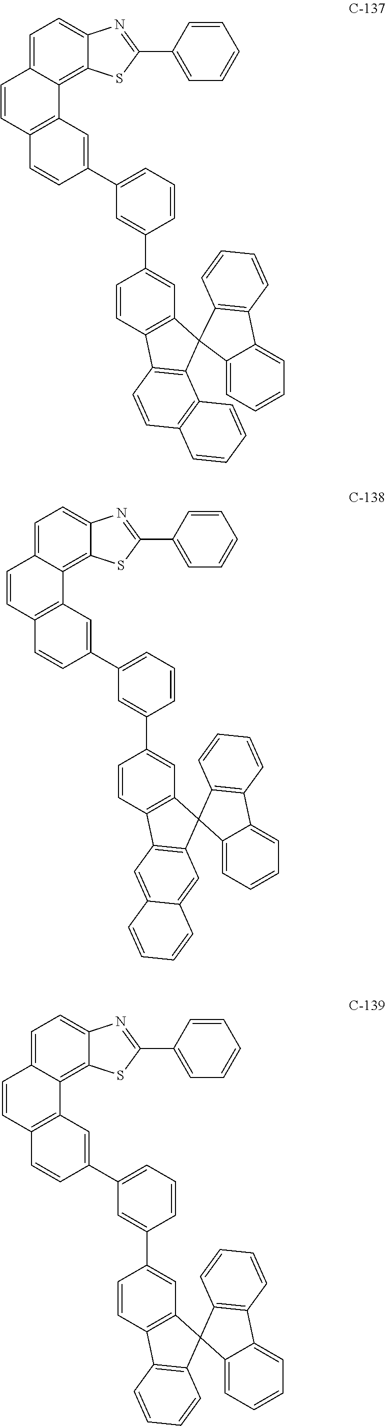 [SMILES: c1ccc(-c2nc3ccc4ccc5ccc(-c6cccc(-c7ccc8c(c7)C7(c9ccccc9-c9ccccc97)c7c-8ccc8ccccc78)c6)cc5c4c3s2)cc1 ; c1ccc(-c2nc3ccc4ccc5ccc(-c6cccc(-c7ccc8c(c7)C7(c9ccccc9-c9ccccc97)c7cc9ccccc9cc7-8)c6)cc5c4c3s2)cc1 ; c1ccc(-c2nc3ccc4ccc5ccc(-c6cccc(-c7ccc8c(c7)C7(c9ccccc9-c9ccccc97)c7ccccc7-8)c6)cc5c4c3s2)cc1]

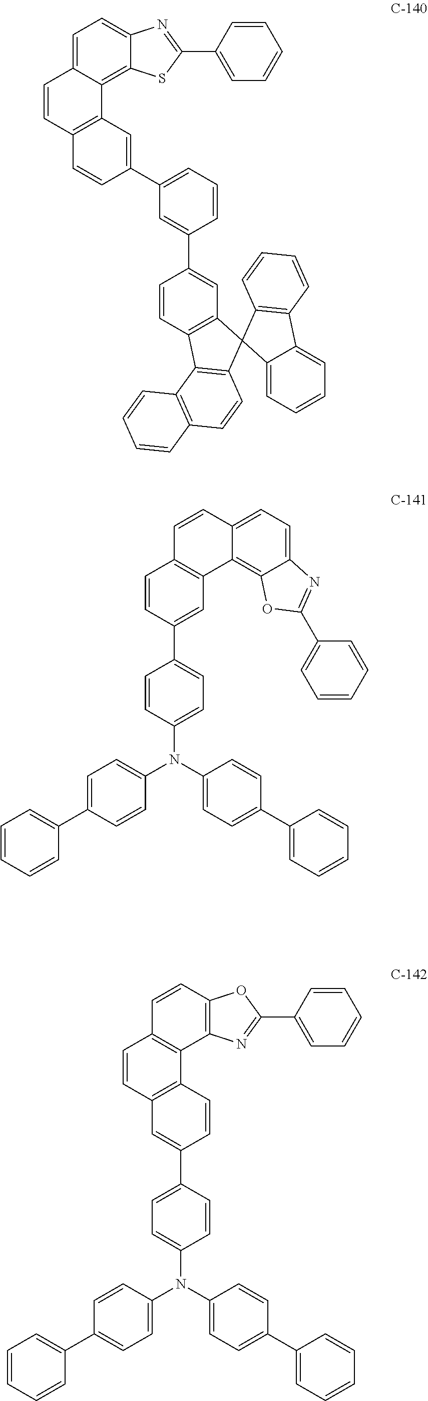 [SMILES: c1ccc(-c2nc3ccc4ccc5ccc(-c6cccc(-c7ccc8c(c7)C7(c9ccccc9-c9ccccc97)c7ccc9ccccc9c7-8)c6)cc5c4c3s2)cc1 ; c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2ccc(N(c3ccc(-c4ccccc4)cc3)c3ccc(-c4ccc5c(ccc6ccc7oc(-c8ccccc8)nc7c65)c4)cc3)cc2)cc1]

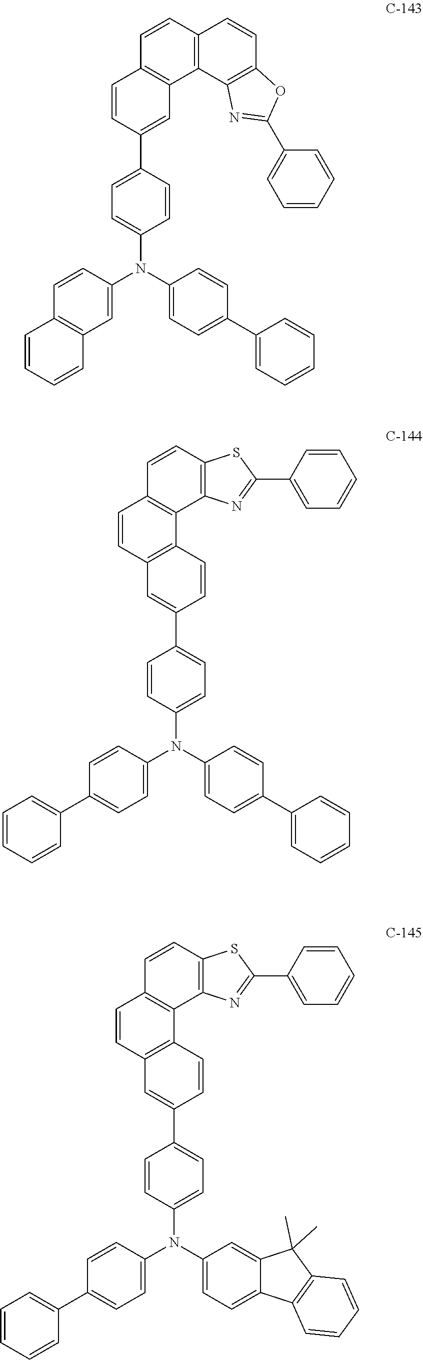 [SMILES: c1ccc(-c2ccc(N(c3ccc(-c4ccc5ccc6ccc7oc(-c8ccccc8)nc7c6c5c4)cc3)c3ccc4ccccc4c3)cc2)cc1 ; c1ccc(-c2ccc(N(c3ccc(-c4ccccc4)cc3)c3ccc(-c4ccc5c(ccc6ccc7sc(-c8ccccc8)nc7c65)c4)cc3)cc2)cc1 ; CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21]

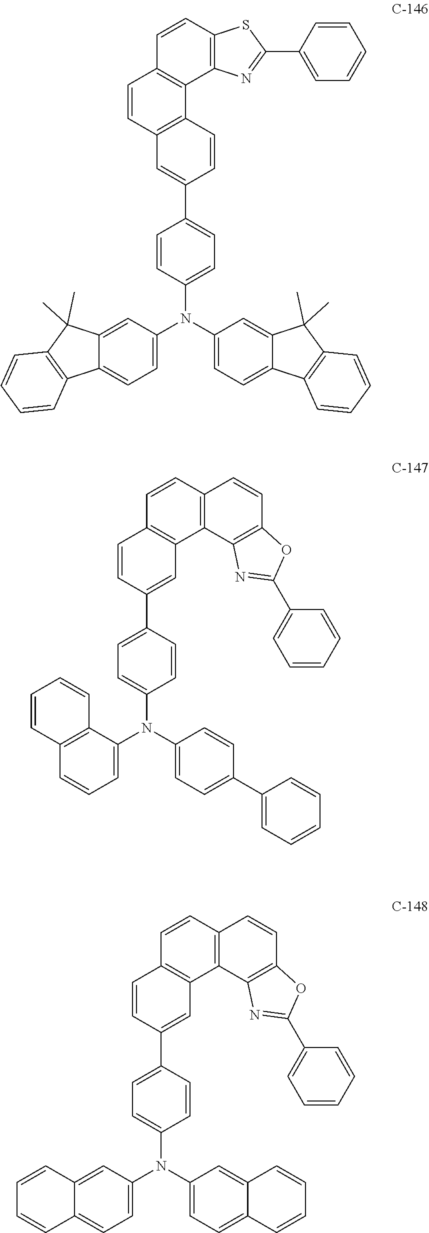 [SMILES: CC1(C)c2ccccc2-c2ccc(N(c3ccc(-c4ccc5c(ccc6ccc7sc(-c8ccccc8)nc7c65)c4)cc3)c3ccc4c(c3)C(C)(C)c3ccccc3-4)cc21 ; c1ccc(-c2ccc(N(c3ccc(-c4ccc5ccc6ccc7oc(-c8ccccc8)nc7c6c5c4)cc3)c3cccc4ccccc34)cc2)cc1 ; c1ccc(-c2nc3c(ccc4ccc5ccc(-c6ccc(N(c7ccc8ccccc8c7)c7ccc8ccccc8c7)cc6)cc5c43)o2)cc1]

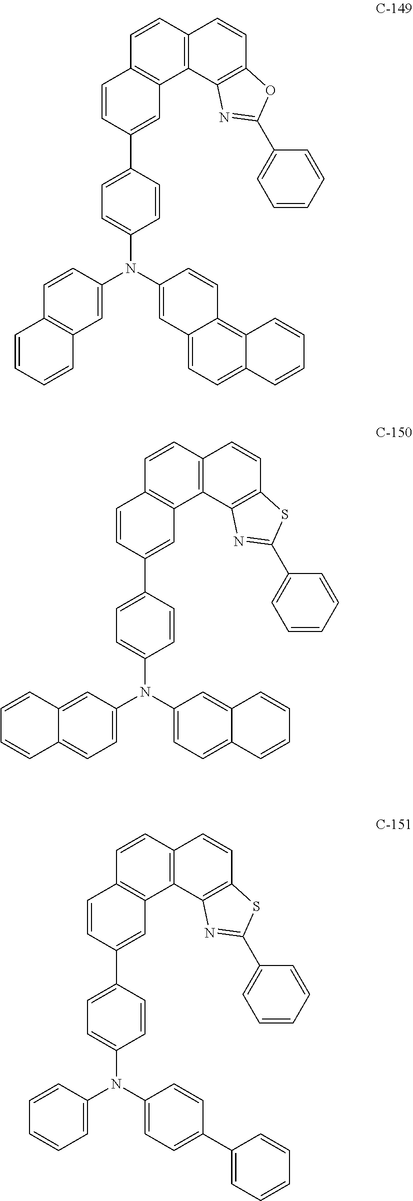 [SMILES: c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2nc3c(ccc4ccc5ccc(-c6ccc(N(c7ccc8ccccc8c7)c7ccc8ccccc8c7)cc6)cc5c43)s2)cc1 ; c1ccc(-c2ccc(N(c3ccccc3)c3ccc(-c4ccc5ccc6ccc7sc(-c8ccccc8)nc7c6c5c4)cc3)cc2)cc1]

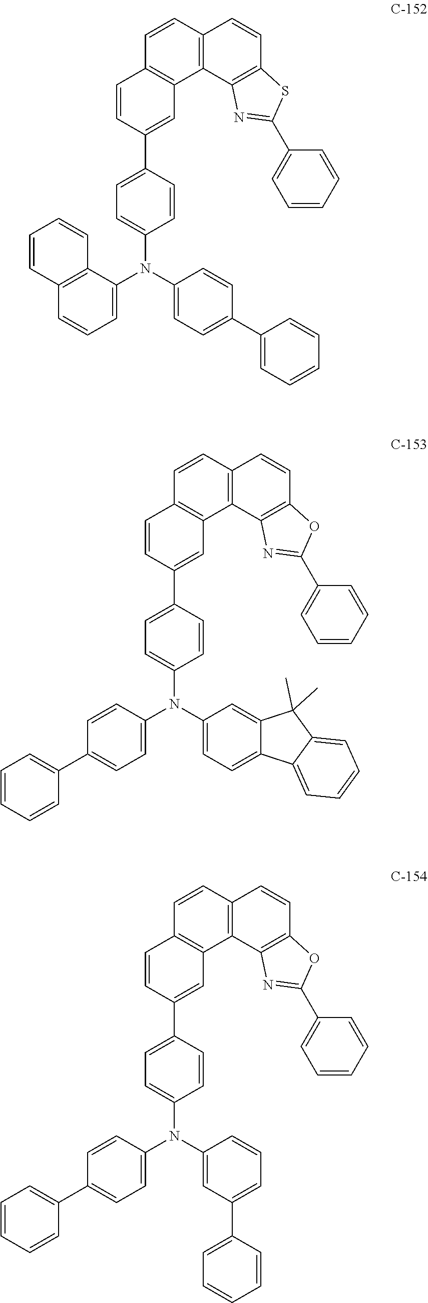 [SMILES: c1ccc(-c2ccc(N(c3ccc(-c4ccc5ccc6ccc7sc(-c8ccccc8)nc7c6c5c4)cc3)c3cccc4ccccc34)cc2)cc1 ; CC1(C)c2ccccc2-c2ccc(N(c3ccc(-c4ccccc4)cc3)c3ccc(-c4ccc5ccc6ccc7oc(-c8ccccc8)nc7c6c5c4)cc3)cc21 ; c1ccc(-c2ccc(N(c3ccc(-c4ccc5ccc6ccc7oc(-c8ccccc8)nc7c6c5c4)cc3)c3cccc(-c4ccccc4)c3)cc2)cc1]

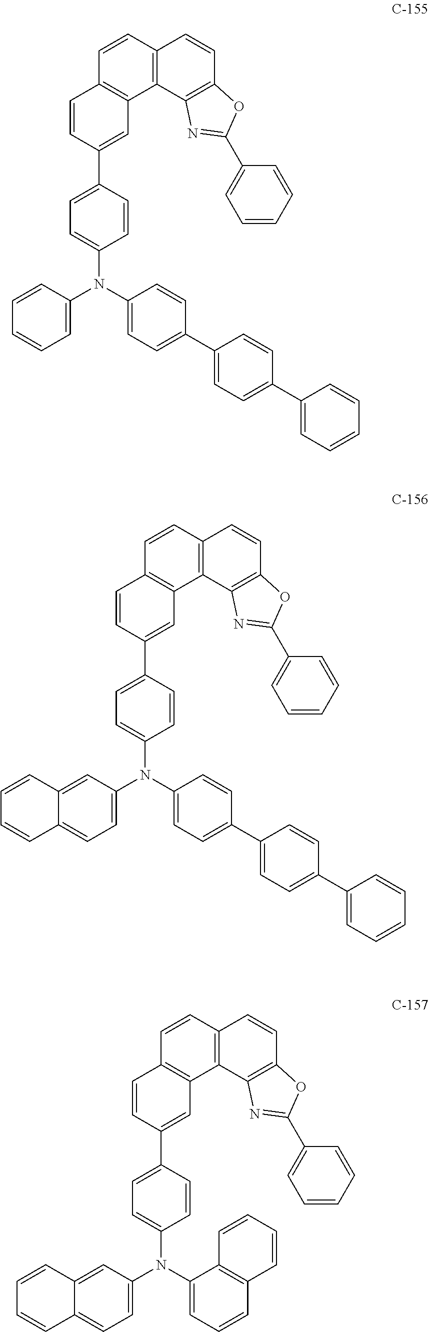 [SMILES: c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5ccc(-c6ccc(N(c7ccc8ccccc8c7)c7cccc8ccccc78)cc6)cc5c43)o2)cc1]

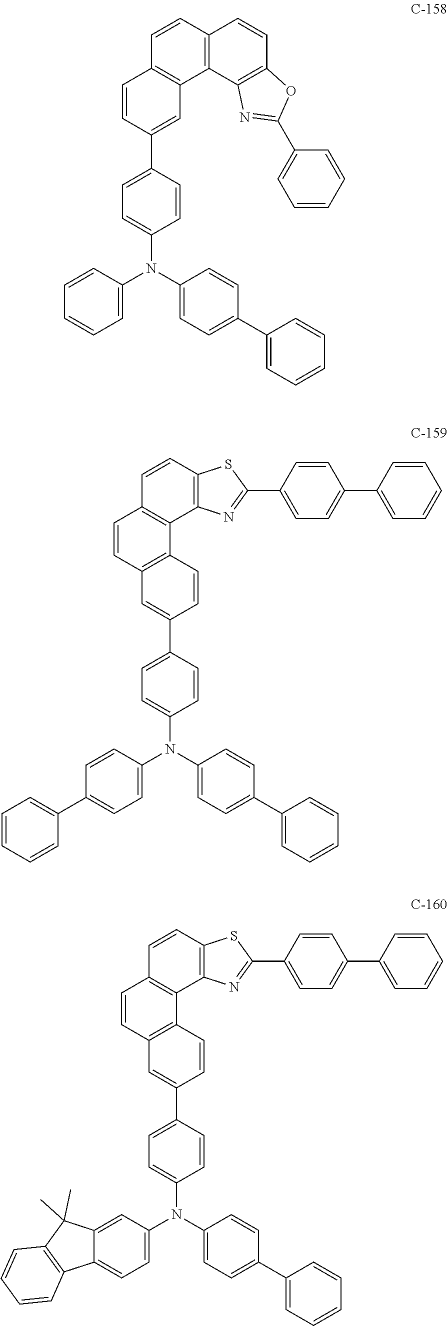 [SMILES: c1ccc(-c2ccc(N(c3ccccc3)c3ccc(-c4ccc5ccc6ccc7oc(-c8ccccc8)nc7c6c5c4)cc3)cc2)cc1 ; c1ccc(-c2ccc(-c3nc4c(ccc5ccc6cc(-c7ccc(N(c8ccc(-c9ccccc9)cc8)c8ccc(-c9ccccc9)cc8)cc7)ccc6c54)s3)cc2)cc1 ; CC1(C)c2ccccc2-c2ccc(N(c3ccc(-c4ccccc4)cc3)c3ccc(-c4ccc5c(ccc6ccc7sc(-c8ccc(-c9ccccc9)cc8)nc7c65)c4)cc3)cc21]

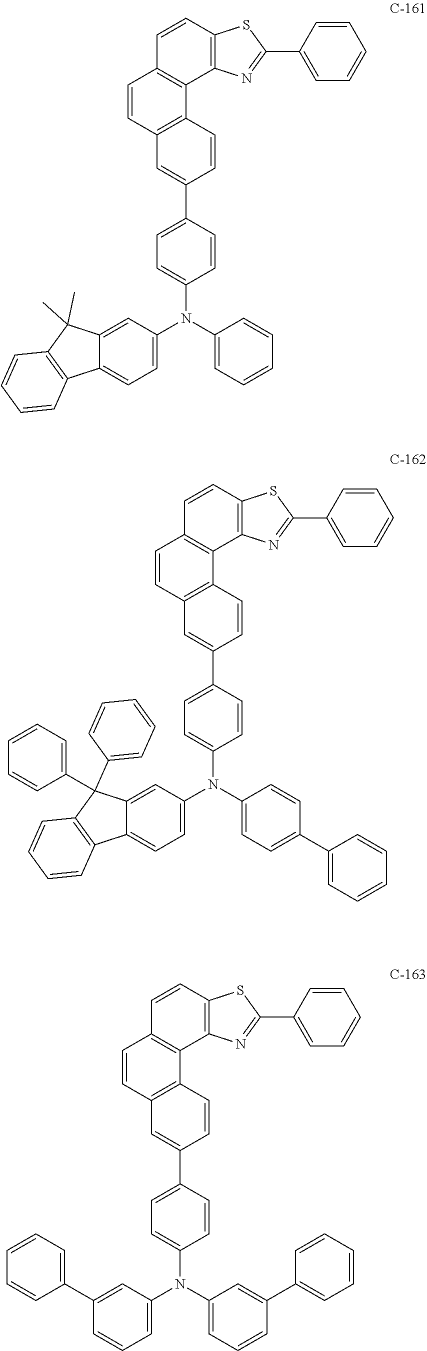 [SMILES: CC1(C)c2ccccc2-c2ccc(N(c3ccccc3)c3ccc(-c4ccc5c(ccc6ccc7sc(-c8ccccc8)nc7c65)c4)cc3)cc21 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1 ; c1ccc(-c2cccc(N(c3ccc(-c4ccc5c(ccc6ccc7sc(-c8ccccc8)nc7c65)c4)cc3)c3cccc(-c4ccccc4)c3)c2)cc1]

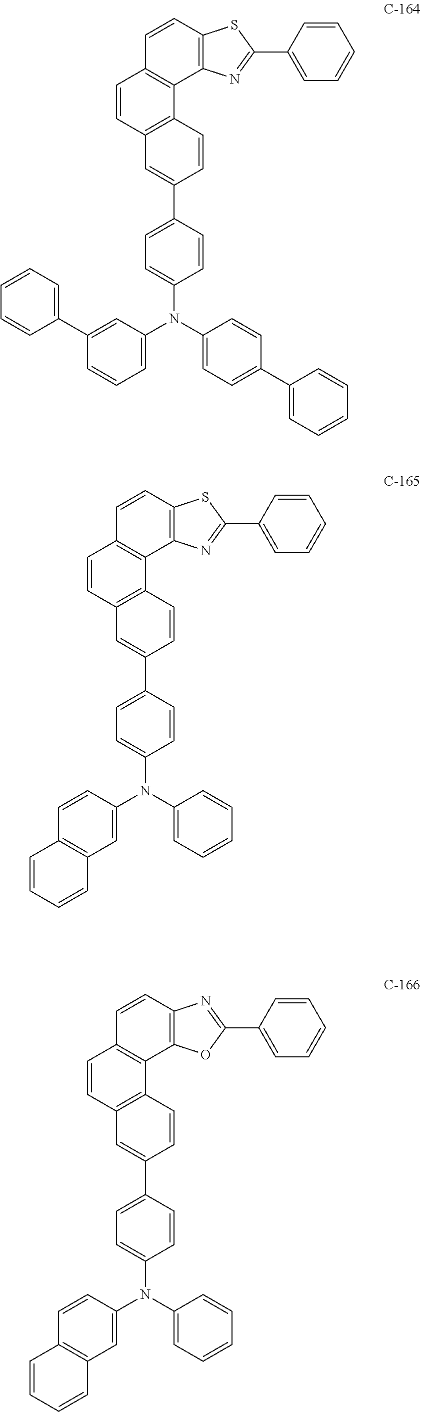 [SMILES: c1ccc(-c2ccc(N(c3ccc(-c4ccc5c(ccc6ccc7sc(-c8ccccc8)nc7c65)c4)cc3)c3cccc(-c4ccccc4)c3)cc2)cc1 ; c1ccc(-c2nc3c(ccc4ccc5cc(-c6ccc(N(c7ccccc7)c7ccc8ccccc8c7)cc6)ccc5c43)s2)cc1 ; c1ccc(-c2nc3ccc4ccc5cc(-c6ccc(N(c7ccccc7)c7ccc8ccccc8c7)cc6)ccc5c4c3o2)cc1]

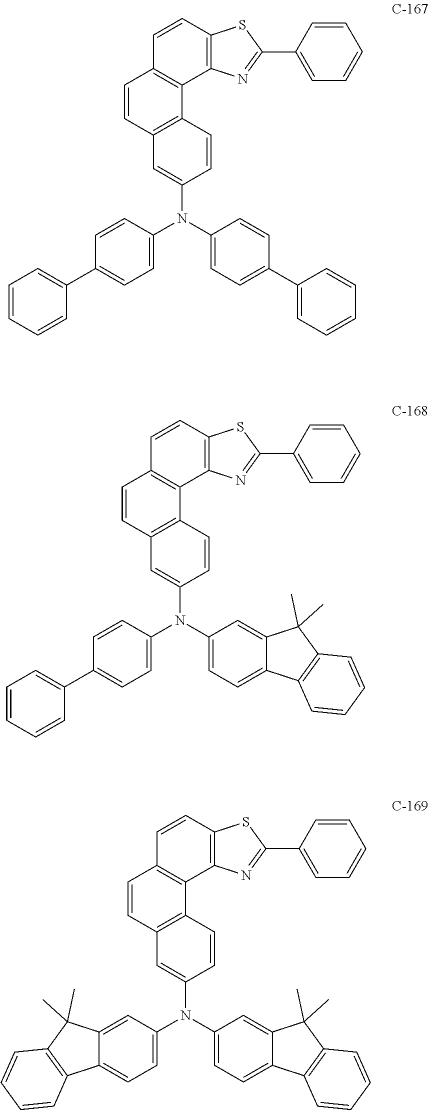 [SMILES: c1ccc(-c2ccc(N(c3ccc(-c4ccccc4)cc3)c3ccc4c(ccc5ccc6sc(-c7ccccc7)nc6c54)c3)cc2)cc1 ; CC1(C)c2ccccc2-c2ccc(N(c3ccc(-c4ccccc4)cc3)c3ccc4c(ccc5ccc6sc(-c7ccccc7)nc6c54)c3)cc21 ; CC1(C)c2ccccc2-c2ccc(N(c3ccc4c(c3)C(C)(C)c3ccccc3-4)c3ccc4c(ccc5ccc6sc(-c7ccccc7)nc6c54)c3)cc21]

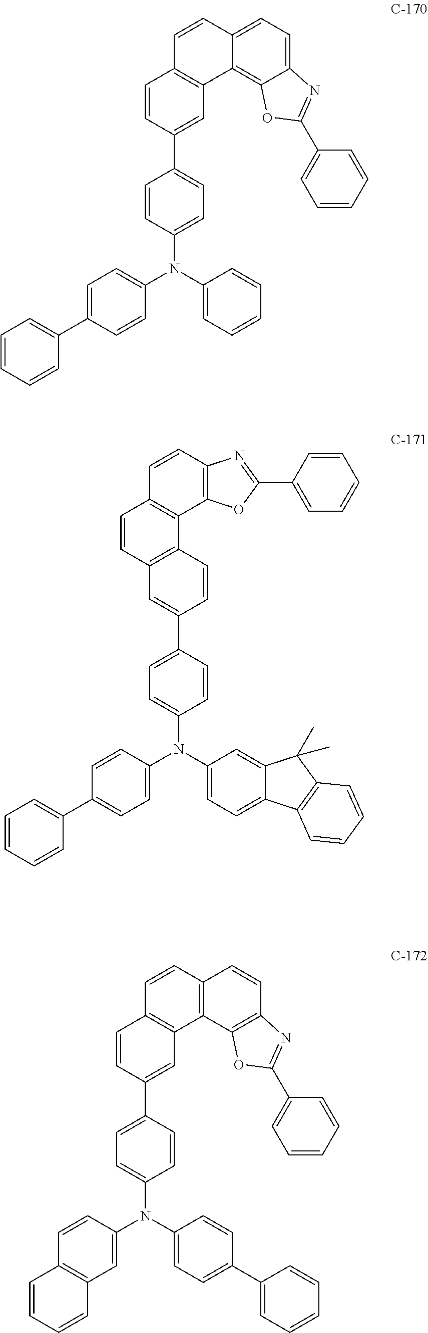 [SMILES: c1ccc(-c2ccc(N(c3ccccc3)c3ccc(-c4ccc5ccc6ccc7nc(-c8ccccc8)oc7c6c5c4)cc3)cc2)cc1 ; CC1(C)c2ccccc2-c2ccc(N(c3ccc(-c4ccccc4)cc3)c3ccc(-c4ccc5c(ccc6ccc7nc(-c8ccccc8)oc7c65)c4)cc3)cc21 ; c1ccc(-c2ccc(N(c3ccc(-c4ccc5ccc6ccc7nc(-c8ccccc8)oc7c6c5c4)cc3)c3ccc4ccccc4c3)cc2)cc1]

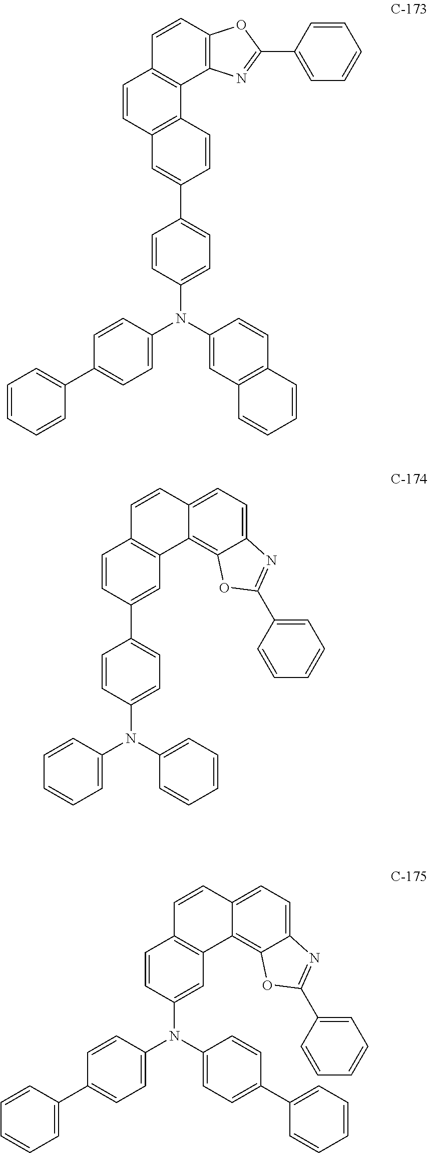 [SMILES: c1ccc(-c2ccc(N(c3ccc(-c4ccc5c(ccc6ccc7oc(-c8ccccc8)nc7c65)c4)cc3)c3ccc4ccccc4c3)cc2)cc1 ; c1ccc(-c2nc3ccc4ccc5ccc(-c6ccc(N(c7ccccc7)c7ccccc7)cc6)cc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1]

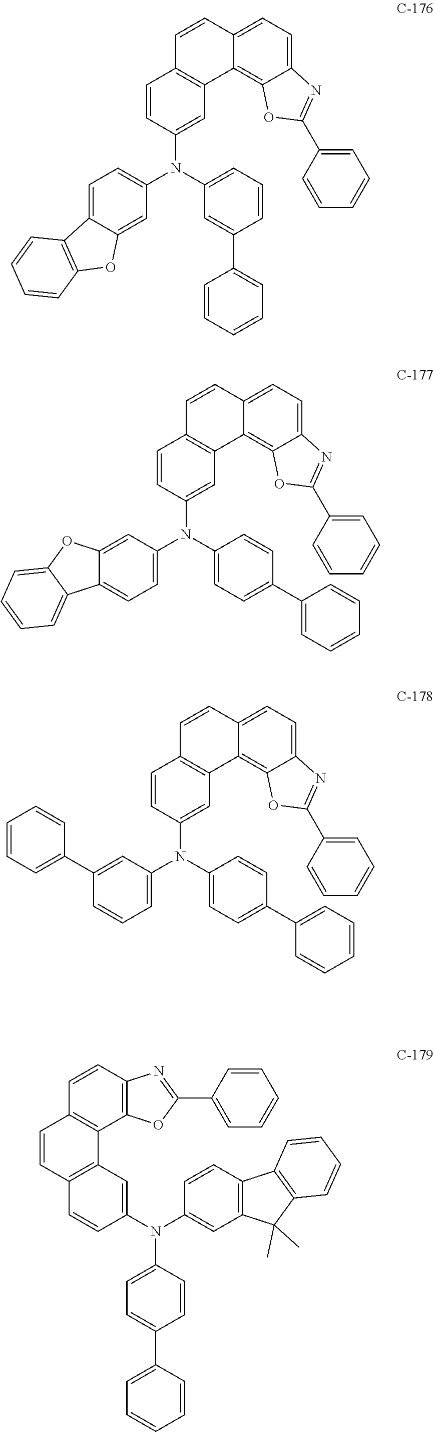 [SMILES: c1ccc(-c2cccc(N(c3ccc4c(c3)oc3ccccc34)c3ccc4ccc5ccc6nc(-c7ccccc7)oc6c5c4c3)c2)cc1 ; c1ccc(-c2ccc(N(c3ccc4c(c3)oc3ccccc34)c3ccc4ccc5ccc6nc(-c7ccccc7)oc6c5c4c3)cc2)cc1 ; c1ccc(-c2ccc(N(c3cccc(-c4ccccc4)c3)c3ccc4ccc5ccc6nc(-c7ccccc7)oc6c5c4c3)cc2)cc1 ; CC1(C)c2ccccc2-c2ccc(N(c3ccc(-c4ccccc4)cc3)c3ccc4ccc5ccc6nc(-c7ccccc7)oc6c5c4c3)cc21]

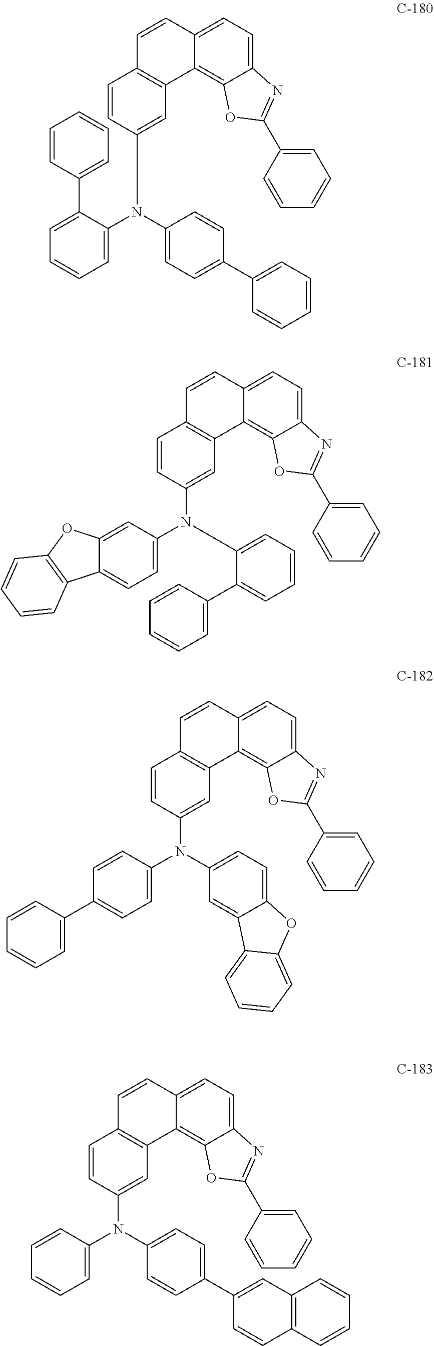

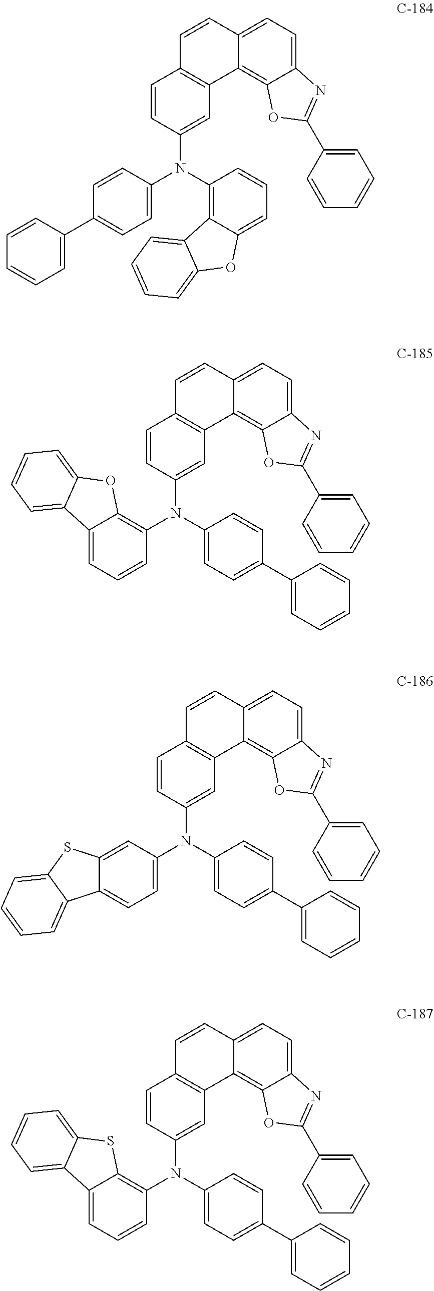 [SMILES: c1ccc(-c2ccc(N(c3ccc4ccc5ccc6nc(-c7ccccc7)oc6c5c4c3)c3cccc4oc5ccccc5c34)cc2)cc1 ; c1ccc(-c2ccc(N(c3ccc4ccc5ccc6nc(-c7ccccc7)oc6c5c4c3)c3cccc4c3oc3ccccc34)cc2)cc1 ; c1ccc(-c2ccc(N(c3ccc4c(c3)sc3ccccc34)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4c3sc3ccccc34)cc2)cc1]

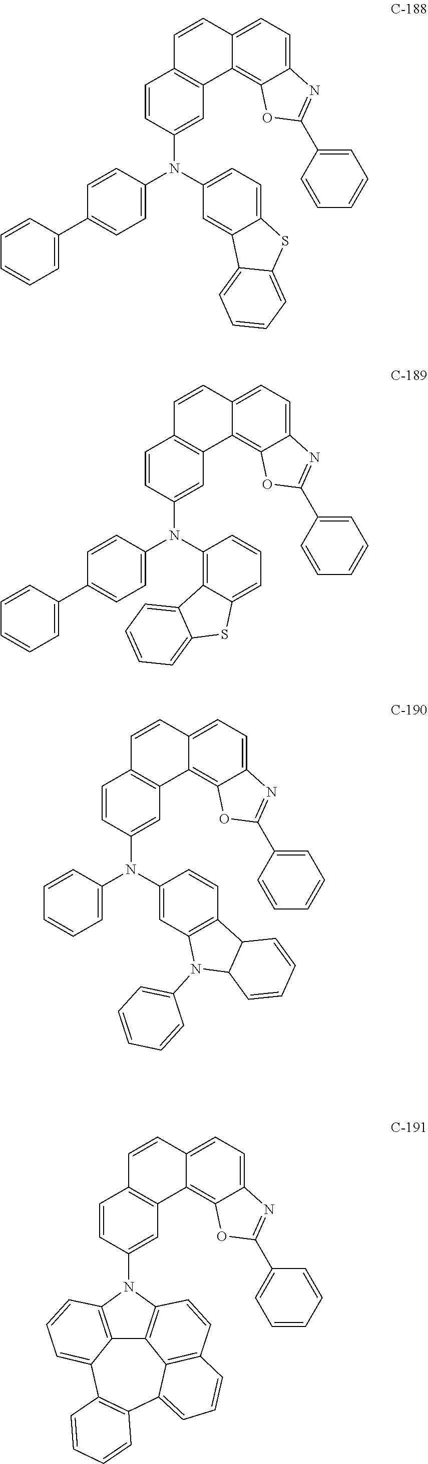 [SMILES: c1ccc(-c2ccc(N(c3ccc4sc5ccccc5c4c3)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4sc5ccccc5c34)cc2)cc1 ; C1=CC2c3ccc(N(c4ccccc4)c4ccc5ccc6ccc7nc(-c8ccccc8)oc7c6c5c4)cc3N(c3ccccc3)C2C=C1 ; c1ccc(-c2nc3ccc4ccc5ccc(-n6c7cccc8c7c7c9c(cccc9ccc76)-c6ccccc6-8)cc5c4c3o2)cc1]

The compound represented by formula 2 may be specifically exemplified by any one of the following compounds C2-1 to C2-259, but is not limited thereto. Compounds C2-1 to C2-259, each independently, are represented by any one of formulas 2-11 to 2-38, Ls represents a single bond, or any one of the structures 3-1 to 3-40, and HAr represents any one of the structures 4-1 to 4-28.

| Compound | Formula | L₂ | HAr | Compound | Formula | L₂ | HAr |
|---|---|---|---|---|---|---|---|
| C2-1 | 2-11 | 3-3 | 4-1 | C2-2 | 2-11 | 3-3 | 4-6 |
| C2-3 | 2-11 | 3-3 | 4-9 | C2-4 | 2-11 | 3-8 | 4-6 |
| C2-5 | 2-11 | 3-3 | 4-11 | C2-6 | 2-11 | 3-8 | 4-11 |
| C2-7 | 2-12 | 3-3 | 4-1 | C2-8 | 2-12 | 3-8 | 4-1 |
| C2-9 | 2-12 | 3-3 | 4-11 | C2-10 | 2-12 | 3-8 | 4-11 |
| C2-11 | 2-12 | 3-16 | 4-1 | C2-12 | 2-12 | 3-27 | 4-1 |
| C2-13 | 2-12 | 3-3 | 4-6 | C2-14 | 2-12 | 3-8 | 4-6 |
| C2-15 | 2-12 | 3-16 | 4-6 | C2-16 | 2-12 | 3-27 | 4-6 |
| C2-17 | 2-12 | 3-3 | 4-9 | C2-18 | 2-12 | 3-8 | 4-9 |
| C2-19 | 2-12 | 3-16 | 4-9 | C2-20 | 2-12 | 3-27 | 4-9 |
| C2-21 | 2-13 | 3-3 | 4-1 | C2-22 | 2-13 | 3-3 | 4-6 |
| C2-23 | 2-13 | 3-3 | 4-9 | C2-24 | 2-13 | 3-8 | 4-6 |
| C2-25 | 2-13 | 3-3 | 4-11 | C2-26 | 2-13 | 3-8 | 4-11 |
| C2-27 | 2-14 | 3-3 | 4-1 | C2-28 | 2-14 | 3-3 | 4-6 |
| C2-29 | 2-14 | 3-3 | 4-9 | C2-30 | 2-14 | 3-8 | 4-6 |
| C2-31 | 2-14 | 3-3 | 4-11 | C2-32 | 2-14 | 3-8 | 4-11 |
| C2-33 | 2-15 | 3-3 | 4-1 | C2-34 | 2-15 | 3-3 | 4-6 |
| C2-35 | 2-15 | 3-3 | 4-9 | C2-36 | 2-15 | 3-8 | 4-6 |
| C2-37 | 2-15 | 3-3 | 4-11 | C2-38 | 2-15 | 3-8 | 4-11 |
| C2-39 | 2-16 | 3-3 | 4-1 | C2-40 | 2-16 | 3-8 | 4-1 |
| C2-41 | 2-16 | 3-16 | 4-1 | C2-42 | 2-16 | 3-27 | 4-1 |
| C2-43 | 2-16 | 3-3 | 4-6 | C2-44 | 2-16 | 3-8 | 4-6 |
| C2-45 | 2-16 | 3-3 | 4-11 | C2-46 | 2-16 | 3-8 | 4-11 |
| C2-47 | 2-16 | 3-16 | 4-6 | C2-48 | 2-16 | 3-27 | 4-6 |
| C2-49 | 2-16 | 3-3 | 4-9 | C2-50 | 2-16 | 3-8 | 4-9 |
| C2-51 | 2-16 | 3-16 | 4-9 | C2-52 | 2-16 | 3-27 | 4-9 |
| C2-53 | 2-17 | 3-3 | 4-1 | C2-54 | 2-17 | 3-3 | 4-6 |
| C2-55 | 2-17 | 3-3 | 4-9 | C2-56 | 2-17 | 3-8 | 4-6 |
| C2-57 | 2-17 | 3-3 | 4-11 | C2-58 | 2-17 | 3-8 | 4-11 |
| C2-59 | 2-18 | 3-3 | 4-1 | C2-60 | 2-18 | 3-3 | 4-6 |
| C2-61 | 2-18 | 3-3 | 4-9 | C2-62 | 2-18 | 3-8 | 4-6 |
| C2-63 | 2-18 | 3-3 | 4-11 | C2-64 | 2-18 | 3-8 | 4-11 |
| C2-65 | 2-19 | 3-3 | 4-1 | C2-66 | 2-19 | 3-3 | 4-6 |
| C2-67 | 2-19 | 3-3 | 4-9 | C2-68 | 2-19 | 3-8 | 4-6 |
| C2-69 | 2-19 | 3-3 | 4-11 | C2-70 | 2-19 | 3-8 | 4-11 |
| C2-71 | 2-20 | 3-3 | 4-1 | C2-72 | 2-20 | 3-3 | 4-6 |
| C2-73 | 2-20 | 3-3 | 4-9 | C2-74 | 2-20 | 3-8 | 4-6 |
| C2-75 | 2-20 | 3-3 | 4-11 | C2-76 | 2-20 | 3-8 | 4-11 |
| C2-77 | 2-21 | 3-3 | 4-1 | C2-78 | 2-21 | 3-3 | 4-6 |
| C2-79 | 2-21 | 3-3 | 4-9 | C2-80 | 2-21 | 3-8 | 4-6 |
| C2-81 | 2-21 | 3-3 | 4-11 | C2-82 | 2-21 | 3-8 | 4-11 |
| C2-83 | 2-22 | 3-3 | 4-1 | C2-84 | 2-22 | 3-3 | 4-6 |
| C2-85 | 2-22 | 3-3 | 4-9 | C2-86 | 2-22 | 3-8 | 4-6 |
| C2-87 | 2-22 | 3-3 | 4-11 | C2-88 | 2-22 | 3-8 | 4-11 |
| C2-89 | 2-23 | 3-3 | 4-1 | C2-90 | 2-23 | 3-8 | 4-1 |
| C2-91 | 2-23 | 3-16 | 4-1 | C2-92 | 2-23 | 3-27 | 4-1 |
| C2-93 | 2-23 | 3-3 | 4-11 | C2-94 | 2-23 | 3-8 | 4-11 |
| C2-95 | 2-23 | 3-3 | 4-6 | C2-96 | 2-23 | 3-8 | 4-6 |
| C2-97 | 2-23 | 3-16 | 4-6 | C2-98 | 2-23 | 3-27 | 4-6 |
| C2-99 | 2-23 | 3-3 | 4-9 | C2-100 | 2-23 | 3-8 | 4-9 |
| C2-101 | 2-23 | 3-16 | 4-9 | C2-102 | 2-23 | 3-27 | 4-9 |
| C2-103 | 2-24 | 3-3 | 4-1 | C2-104 | 2-24 | 3-3 | 4-6 |
| C2-105 | 2-24 | 3-3 | 4-9 | C2-106 | 2-24 | 3-8 | 4-6 |
| C2-107 | 2-24 | 3-3 | 4-11 | C2-108 | 2-24 | 3-8 | 4-11 |
| C2-109 | 2-25 | 3-3 | 4-1 | C2-110 | 2-25 | 3-3 | 4-6 |
| C2-111 | 2-25 | 3-3 | 4-9 | C2-112 | 2-25 | 3-8 | 4-6 |
| C2-113 | 2-25 | 3-3 | 4-11 | C2-114 | 2-25 | 3-8 | 4-11 |
| C2-115 | 2-26 | 3-3 | 4-1 | C2-116 | 2-26 | 3-3 | 4-6 |
| C2-117 | 2-26 | 3-3 | 4-9 | C2-118 | 2-26 | 3-8 | 4-6 |
| C2-119 | 2-26 | 3-3 | 4-11 | C2-120 | 2-26 | 3-8 | 4-11 |
| C2-121 | 2-27 | 3-3 | 4-1 | C2-122 | 2-27 | 3-3 | 4-6 |
| C2-123 | 2-27 | 3-3 | 4-9 | C2-124 | 2-27 | 3-8 | 4-6 |
| C2-125 | 2-27 | 3-3 | 4-11 | C2-126 | 2-27 | 3-8 | 4-11 |
| C2-127 | 2-28 | 3-3 | 4-1 | C2-128 | 2-28 | 3-3 | 4-6 |
| C2-129 | 2-28 | 3-3 | 4-9 | C2-130 | 2-28 | 3-8 | 4-6 |
| C2-131 | 2-28 | 3-3 | 4-11 | C2-132 | 2-28 | 3-8 | 4-11 |
| C2-133 | 2-29 | 3-3 | 4-1 | C2-134 | 2-29 | 3-3 | 4-6 |
| C2-135 | 2-29 | 3-3 | 4-9 | C2-136 | 2-29 | 3-8 | 4-6 |
| C2-137 | 2-29 | 3-3 | 4-11 | C2-138 | 2-29 | 3-8 | 4-11 |
| C2-139 | 2-30 | 3-3 | 4-1 | C2-140 | 2-30 | 3-8 | 4-1 |
| C2-141 | 2-30 | 3-16 | 4-1 | C2-142 | 2-30 | 3-27 | 4-1 |
| C2-143 | 2-30 | 3-3 | 4-11 | C2-144 | 2-30 | 3-8 | 4-11 |
| C2-145 | 2-30 | 3-3 | 4-6 | C2-146 | 2-30 | 3-8 | 4-6 |
| C2-147 | 2-30 | 3-16 | 4-6 | C2-148 | 2-30 | 3-27 | 4-6 |
| C2-149 | 2-30 | 3-3 | 4-9 | C2-150 | 2-30 | 3-8 | 4-9 |
| C2-151 | 2-30 | 3-16 | 4-9 | C2-152 | 2-30 | 3-27 | 4-9 |
| C2-153 | 2-31 | 3-3 | 4-1 | C2-154 | 2-31 | 3-3 | 4-6 |
| C2-155 | 2-31 | 3-3 | 4-9 | C2-156 | 2-31 | 3-8 | 4-6 |
| C2-157 | 2-31 | 3-3 | 4-11 | C2-158 | 2-31 | 3-8 | 4-11 |
| C2-159 | 2-32 | 3-3 | 4-1 | C2-160 | 2-32 | 3-3 | 4-6 |
| C2-161 | 2-32 | 3-3 | 4-9 | C2-162 | 2-32 | 3-8 | 4-6 |
| C2-163 | 2-32 | 3-3 | 4-11 | C2-164 | 2-32 | 3-8 | 4-11 |
| C2-165 | 2-33 | 3-3 | 4-1 | C2-166 | 2-33 | 3-3 | 4-6 |
| C2-167 | 2-33 | 3-3 | 4-9 | C2-168 | 2-33 | 3-8 | 4-6 |
| C2-169 | 2-33 | 3-3 | 4-11 | C2-170 | 2-33 | 3-8 | 4-11 |
| C2-171 | 2-34 | 3-3 | 4-1 | C2-172 | 2-34 | 3-3 | 4-6 |
| C2-173 | 2-34 | 3-3 | 4-9 | C2-174 | 2-34 | 3-8 | 4-6 |
| C2-175 | 2-34 | 3-3 | 4-11 | C2-176 | 2-34 | 3-8 | 4-11 |
| C2-177 | 2-35 | 3-3 | 4-1 | C2-178 | 2-35 | 3-3 | 4-6 |
| C2-179 | 2-35 | 3-3 | 4-9 | C2-180 | 2-35 | 3-8 | 4-6 |
| C2-181 | 2-35 | 3-3 | 4-11 | C2-182 | 2-35 | 3-8 | 4-11 |
| C2-183 | 2-36 | 3-3 | 4-1 | C2-184 | 2-36 | 3-3 | 4-6 |
| C2-185 | 2-36 | 3-3 | 4-9 | C2-186 | 2-36 | 3-8 | 4-6 |
| C2-187 | 2-36 | 3-3 | 4-11 | C2-188 | 2-36 | 3-8 | 4-11 |
| C2-189 | 2-37 | 3-3 | 4-1 | C2-190 | 2-37 | 3-3 | 4-6 |
| C2-191 | 2-37 | 3-3 | 4-9 | C2-192 | 2-37 | 3-8 | 4-6 |
| C2-193 | 2-37 | 3-3 | 4-11 | C2-194 | 2-37 | 3-8 | 4-11 |
| C2-195 | 2-38 | 3-3 | 4-1 | C2-196 | 2-38 | 3-3 | 4-6 |
| C2-197 | 2-38 | 3-3 | 4-9 | C2-198 | 2-38 | 3-8 | 4-6 |
| C2-199 | 2-38 | 3-3 | 4-11 | C2-200 | 2-38 | 3-8 | 4-11 |
| C2-201 | 2-12 | Single | 4-9 | C2-202 | 2-16 | Single | 4-9 |
| | | Bond | | | | Bond | |
| C2-203 | 2-23 | Single | 4-9 | C2-204 | 2-26 | Single | 4-9 |
| | | Bond | | | | Bond | |
| C2-205 | 2-30 | Single | 4-9 | C2-206 | 2-37 | Single | 4-9 |
| | | Bond | | | | Bond | |
| C2-207 | 2-11 | Single | 4-5 | C2-208 | 2-12 | Single | 4-6 |
| | | Bond | | | | Bond | |
| C2-209 | 2-16 | Single | 4-8 | C2-210 | 2-23 | Single | 4-1 |
| | | Bond | | | | Bond | |
| C2-211 | 2-30 | Single | 4-1 | C2-212 | 2-37 | Single | 4-1 |
| | | Bond | | | | Bond | |
| C2-213 | 2-12 | 3-8 | 4-20 | C2-214 | 2-12 | 3-8 | 4-21 |
| C2-215 | 2-12 | 3-8 | 4-22 | C2-216 | 2-12 | 3-8 | 4-23 |
| C2-217 | 2-12 | 3-8 | 4-24 | C2-218 | 2-12 | 3-8 | 4-25 |
| C2-219 | 2-12 | 3-8 | 4-26 | C2-220 | 2-12 | 3-8 | 4-27 |
| C2-221 | 2-12 | 3-8 | 4-28 | C2-222 | 2-12 | 3-1 | 4-1 |
| C2-223 | 2-12 | 3-2 | 4-1 | C2-224 | 2-12 | 3-4 | 4-1 |
| C2-225 | 2-12 | 3-5 | 4-1 | C2-226 | 2-12 | 3-6 | 4-1 |
| C2-227 | 2-12 | 3-7 | 4-1 | C2-228 | 2-12 | 3-9 | 4-1 |
| C2-229 | 2-12 | 3-10 | 4-1 | C2-230 | 2-12 | 3-11 | 4-1 |
| C2-231 | 2-12 | 3-12 | 4-1 | C2-232 | 2-12 | 3-13 | 4-1 |
| C2-233 | 2-12 | 3-14 | 4-1 | C2-234 | 2-12 | 3-15 | 4-1 |
| C2-235 | 2-12 | 3-40 | 4-1 | C2-236 | 2-12 | 3-17 | 4-1 |
| C2-237 | 2-12 | 3-18 | 4-1 | C2-238 | 2-12 | 3-19 | 4-1 |
| C2-239 | 2-12 | 3-20 | 4-1 | C2-240 | 2-12 | 3-21 | 4-1 |
| C2-241 | 2-12 | 3-22 | 4-1 | C2-242 | 2-12 | 3-23 | 4-1 |
| C2-243 | 2-12 | 3-24 | 4-1 | C2-244 | 2-12 | 3-25 | 4-1 |
| C2-245 | 2-12 | 3-26 | 4-1 | C2-246 | 2-12 | 3-29 | 4-1 |
| C2-247 | 2-12 | 3-28 | 4-1 | C2-248 | 2-12 | 3-31 | 4-1 |
| C2-249 | 2-12 | 3-30 | 4-1 | C2-250 | 2-12 | 3-33 | 4-1 |
| C2-251 | 2-12 | 3-32 | 4-1 | C2-252 | 2-12 | 3-35 | 4-1 |
| C2-253 | 2-12 | 3-34 | 4-1 | C2-254 | 2-12 | 3-37 | 4-1 |
| C2-255 | 2-12 | 3-36 | 4-1 | C2-256 | 2-12 | 3-39 | 4-1 |
| C2-257 | 2-12 | 3-38 | 4-1 | C2-258 | 2-12 | 3-9 | 4-11 |
| C2-259 | 2-12 | 3-8 | 4-5 | | | | |

The combination of at least one of compounds C-1 to C-191 and at least one of compounds C2-1 to C2-259 may be used in an organic electroluminescent device.

The compounds represented by formula 1 according to the present disclosure may be prepared by a synthetic method known to one skilled in the art. For example, the compound represented by formula 1 can be prepared by referring to Korean Patent Appl. Laid-Open No. 10-2017-0022865 A (published on Mar. 2, 2017), but is not limited thereto.

The compounds represented by formula 2 according to the present disclosure may be prepared by a synthetic method known to one skilled in the art. For example, the compound represented by formula 2 can be prepared by referring to Korean Patent Appl. Laid-Open Nos. 10-2010-0007780 A (published on Jan. 22, 2010), 10-2010-0105099 A (published on Sep. 29, 2010), 10-2010-0108903 A (published on Oct. 8, 2010), 10-2015-0032447 A (published on Mar. 26, 2015), 10-2015-0077513 A (published on Jul. 8, 2015), 10-2016-0099471 A (published on Aug. 22, 2016), 10-2016-0136220 A (published on Nov. 29, 2016), and 10-2018-0066818 A (published on Jun. 19, 2018), and Korean Patent No. 10-1478990 B (published on Dec. 29, 2014), but are not limited thereto.

The organic electroluminescent device according to the present disclosure comprises an anode, a cathode, and at least one organic layer between the anode and the cathode. The organic layer may comprise a plurality of organic electroluminescent materials in which the compound represented by formula 1 is included as a first organic electroluminescent material, and the compound represented by formula 2 is included as a second organic electroluminescent material. According to one embodiment of the present disclosure, the organic electroluminescent device comprises an anode, a cathode, and at least one light-emitting layer between the anode and the cathode, and the light-emitting layer comprises a compound(s) represented by formula 1, and a compound(s) represented by formula 2.

The light-emitting layer comprises a host and a dopant. The host comprises a plurality of host materials. The compound represented by formula 1 may be comprised as a first host compound of the plurality of host materials, and the compound represented by formula 2 may be comprised as a second host compound of the plurality of host materials. The weight ratio of the first host compound to the second host compound is in the range of about 1:99 to about 99:1, preferably about 10:90 to about 90:10, more preferably about 30:70 to about 70:30, even more preferably about 40:60 to about 60:40, and still more preferably about 50:50.

The light-emitting layer is a layer from which light is emitted, and can be a single layer or a multi-layer in which two or more layers are stacked. In the plurality of host materials according to the present disclosure, the first and second host materials may both be comprised in one layer, or may be respectively comprised in different light-emitting layers. According to one embodiment of the present disclosure, the doping concentration of the dopant compound with respect to the host compound in the light-emitting layer is less than about 20 wt %.

The organic electroluminescent device of the present disclosure may further comprise at least one layer selected from a hole injection layer, a hole transport layer, a hole auxiliary layer, a light-emitting auxiliary layer, an electron transport layer, an electron injection layer, an interlayer, an electron buffer layer, a hole blocking layer, and an electron blocking layer. According to one embodiment of the present disclosure, the organic electroluminescent device may further comprise amine-based compounds in addition to the plurality of host materials of the present disclosure as at least one of a hole injection material, a hole transport material, a hole auxiliary material, a light-emitting material, a light-emitting auxiliary material, and an electron blocking material. Also, according to one embodiment of the present disclosure, the organic electroluminescent device of the present disclosure may further comprise azine-based compounds in addition to the plurality of host materials of the present disclosure as at least one of an electron transport material, an electron injection material, an electron buffer material, and a hole blocking material.

In order to form each layer of the organic electroluminescent device of the present disclosure, dry film-forming methods such as vacuum evaporation, sputtering, plasma, and ion plating methods, or wet film-forming methods such as ink jet printing, nozzle printing, slot coating, spin coating, dip coating, and flow coating methods can be used.

When using a solvent in a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused, and where there are no problems in film-formation capability.

In addition, the first host compound and the second host compound may be film-formed in the above-listed methods, commonly by a co-evaporation process or a mixture-evaporation process. The co-evaporation is a mixed deposition method in which two or more materials are placed in a respective individual crucible source and an electric current is applied to both cells at the same time to evaporate the materials. The mixture-evaporation is a mixed deposition method in which two or more materials are mixed in one crucible source before evaporating them, and an electric current is applied to the cell to evaporate the materials. Also, when the first and second host compounds are present in the same layer or different layers in the organic electroluminescent device, the two host compounds can be individually deposited. For example, the first host compound may be deposited, and then the second host compound may be deposited.

The present disclosure may provide a display system by using a plurality of host materials comprising the compound represented by formula 1, and the compound represented by formula 2. That is, it is possible to produce a display system or a lighting system by using the plurality of host materials of the present disclosure. Specifically, it is possible to produce a display system, e.g., a display system for smartphones, tablets, notebooks, PCs, TVs, or cars, or a lighting system, e.g., an outdoor or indoor lighting system, by using the plurality of host materials of the present disclosure.

Hereinafter, the properties of an OLED according to the present disclosure will be explained in detail. However, the following examples merely illustrate the properties of an OLED according to the present disclosure in detail, but the present disclosure is not limited to the following examples.

### Device Examples 1 to 12: Producing an OLED According to the Present Disclosure

An OLED according to the present disclosure was produced as follows: A transparent electrode indium tin oxide (ITO) thin film (10 Ω/sq) on a glass substrate for an OLED (GEOMATEC CO., LTD., Japan) was subjected to an ultrasonic washing with trichloroethylene, acetone, ethanol and distilled water, sequentially, and then was stored in isopropanol. The ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁶ torr. Thereafter, an electric current was applied to the cell to evaporate the above-introduced material, thereby forming a first hole injection layer having a thickness of 80 nm on the ITO substrate. Next, compound HI-2 was introduced into another cell of the vacuum vapor deposition apparatus and was evaporated by applying an electric current to the cell, thereby forming a second hole injection layer having a thickness of 5 nm on the first hole injection layer. Compound HT-1 was then introduced into another cell of the vacuum vapor deposition apparatus and was evaporated by applying an electric current to the cell, thereby forming a first hole transport layer having a thickness of 10 nm on the second hole injection layer. The second hole transport compound shown in Table 1 below was then introduced into another cell of the vacuum vapor deposition apparatus and was evaporated by applying an electric current to the cell, thereby forming a second hole transport layer having a thickness of 60 nm on the first hole transport layer. After forming the hole injection layers and the hole transport layers, a light-emitting layer was formed thereon as follows: The first host compound and the second host compound shown in Table 1 below were introduced into two cells of the vacuum vapor depositing apparatus, respectively, as hosts, and compound RD was introduced into another cell as a dopant. The two host materials were evaporated at a rate of 1:1, and at the same time the dopant material was evaporated at different rates to be deposited in a doping amount of 3 wt % based on the total amount of the hosts and dopant to form a light-emitting layer having a thickness of 40 nm on the second hole transport layer. Next, compound ET-1 and compound EI-1 were evaporated at a rate of 1:1 in two other cells to deposit an electron transport layer having a thickness of 35 nm on the light-emitting layer. After depositing compound EI-1 as an electron injection layer having a thickness of 2 nm on the electron transport layer, an Al cathode having a thickness of 80 nm was deposited on the electron injection layer by another vacuum vapor deposition apparatus. Thus, an OLED was produced.

### Comparative Examples 1 and 2: Producing an OLED not According to the Present Disclosure

An OLED was produced in the same manner as in Device Example 4, except that only one host compound shown in Table 1 below was used instead of the two hosts.

The luminous efficiency at a luminance of 1,000 nit, and the time taken to reduce from the initial luminance of 100% to a luminance of 95% at a constant current in a luminance of 5,000 nit (T95) of the OLEDs produced in the Device Examples and the Comparative Examples, are shown in Table 1 below.

TABLE 1

| | Second | | | | |
|---|---|---|---|---|---|
| | Hole | | | Luminous | |
| | Transport | First | Second | Efficiency | T95 |
| | Compound | Host | Host | [cd/A] | [hr] |
| Device Example | HT-2 | C-170 | C2-8 | 27.3 | 528 |
| 1 | | | | | |
| Device Example | HT-3 | C-179 | C2-8 | 26.9 | 334 |
| 2 | | | | | |
| Device Example | HT-4 | C-179 | C2-8 | 28.0 | 327 |
| 3 | | | | | |
| Device Example | HT-2 | C-141 | C2-8 | 26.5 | 997 |
| 4 | | | | | |
| Device Example | HT-2 | C-191 | C2-8 | 26.4 | 284 |
| 5 | | | | | |
| Device Example | HT-2 | C-170 | C2-259 | 29.9 | 446 |
| 6 | | | | | |
| Device Example | HT-2 | C-174 | C2-8 | 30.2 | 230 |
| 7 | | | | | |
| Device Example | HT-2 | C-175 | C2-8 | 26.5 | 723 |
| 8 | | | | | |
| Device Example | HT-2 | C-176 | C2-8 | 31.2 | 298 |
| 9 | | | | | |
| Device Example | HT-2 | C-170 | C2-10 | 29.7 | 285 |
| 10 | | | | | |
| Device Example | HT-2 | C-170 | C2-228 | 28.9 | 273 |
| 11 | | | | | |
| Device Example | HT-2 | C-177 | C2-228 | 29.3 | 442 |
| 12 | | | | | |
| Comparative | HT-2 | C-146 | — | 9.3 | 7 |
| Example 1 | | | | | |
| Comparative | HT-2 | — | C2-8 | 21.6 | 58 |
| Example 2 | | | | | |

From the Device Examples and the Comparative Examples above, it can be confirmed that the organic electroluminescent device comprising a specific combination of compounds of the present disclosure as host materials has remarkably improved luminous efficiency and lifetime as compared with a conventional organic electroluminescent device.

The compounds used in the Device Examples and the Comparative Examples are shown in Table 2 below.

TABLE 2

| | | |
|---|---|---|
| Hole Injection Layer/ Hole Transport Layer | 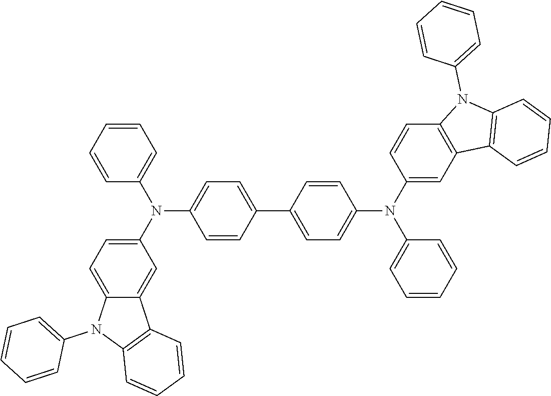 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] | HI-1 |
| | 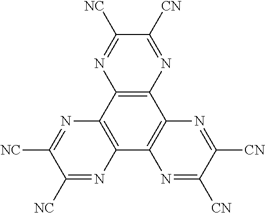 [SMILES: N#Cc1nc2c3nc(C#N)c(C#N)nc3c3nc(C#N)c(C#N)nc3c2nc1C#N] | HI-2 |
| | 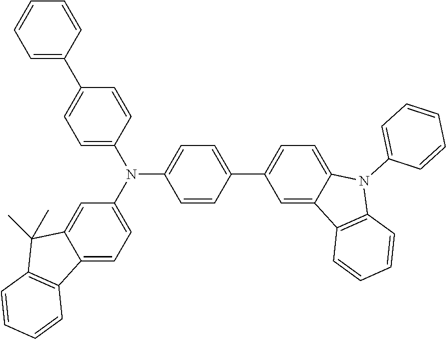 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] | HT-1 |
| | 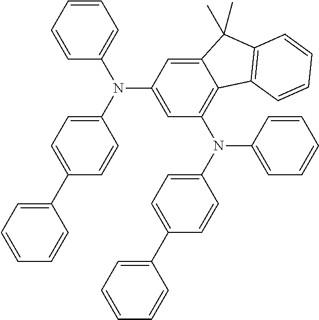 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] | HT-2 |
| | 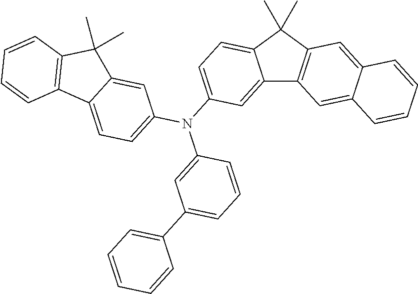 [SMILES: CC1(C)c2ccccc2-c2ccc(N(c3cccc(-c4ccccc4)c3)c3ccc4c(c3)-c3cc5ccccc5cc3C4(C)C)cc21] | HT-3 |
| | 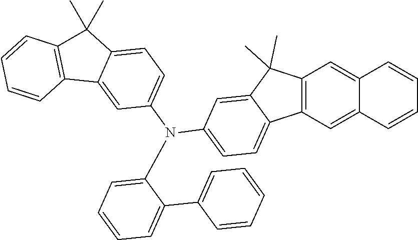 [SMILES: CC1(C)c2ccccc2-c2cc(N(c3ccc4c(c3)C(C)(C)c3cc5ccccc5cc3-4)c3ccccc3-c3ccccc3)ccc21] | HT-4 |
| Light- Emitting Layer | 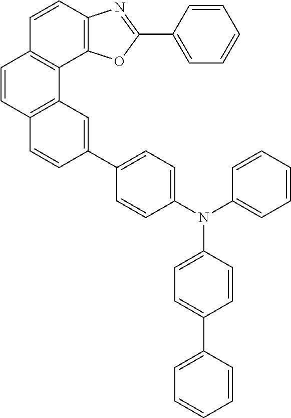 [SMILES: c1ccc(-c2ccc(N(c3ccccc3)c3ccc(-c4ccc5ccc6ccc7nc(-c8ccccc8)oc7c6c5c4)cc3)cc2)cc1] | C-170 |
| | 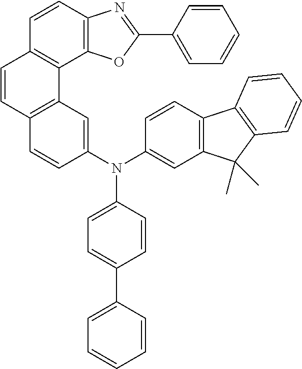 [SMILES: CC1(C)c2ccccc2-c2ccc(N(c3ccc(-c4ccccc4)cc3)c3ccc4ccc5ccc6nc(-c7ccccc7)oc6c5c4c3)cc21] | C-179 |
| | 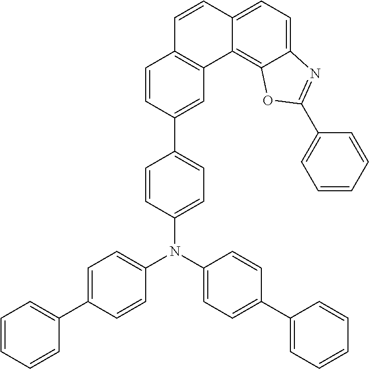 [SMILES: c1ccc(-c2ccc(N(c3ccc(-c4ccccc4)cc3)c3ccc(-c4ccc5ccc6ccc7nc(-c8ccccc8)oc7c6c5c4)cc3)cc2)cc1] | C-141 |
| | 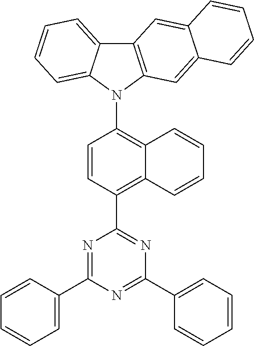 [SMILES: c1ccc(-c2nc(-c3ccccc3)nc(-c3ccc(-n4c5ccccc5c5cc6ccccc6cc54)c4ccccc34)n2)cc1] | C2-8 |
| | 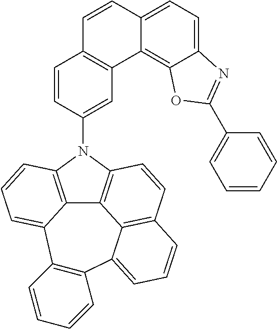 [SMILES: c1ccc(-c2nc3ccc4ccc5ccc(-n6c7cccc8c7c7c9c(cccc9ccc76)-c6ccccc6-8)cc5c4c3o2)cc1] | C-191 |
| | 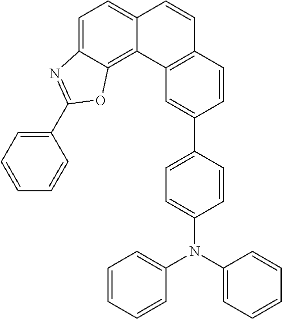 [SMILES: c1ccc(-c2nc3ccc4ccc5ccc(-c6ccc(N(c7ccccc7)c7ccccc7)cc6)cc5c4c3o2)cc1] | C-174 |
| | 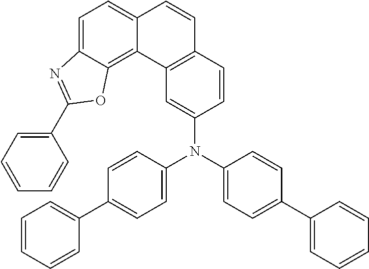 [SMILES: c1ccc(-c2ccc(N(c3ccc(-c4ccccc4)cc3)c3ccc4ccc5ccc6nc(-c7ccccc7)oc6c5c4c3)cc2)cc1] | C-175 |
| | 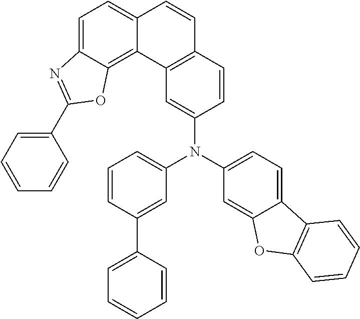 [SMILES: c1ccc(-c2cccc(N(c3ccc4c(c3)oc3ccccc34)c3ccc4ccc5ccc6nc(-c7ccccc7)oc6c5c4c3)c2)cc1] | C-176 |
| | 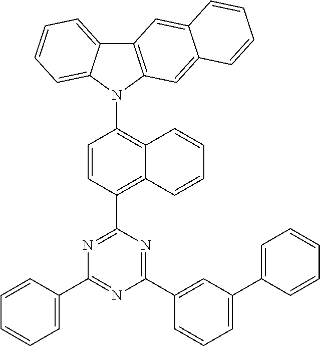 [SMILES: c1ccc(-c2cccc(-c3nc(-c4ccccc4)nc(-c4ccc(-n5c6ccccc6c6cc7ccccc7cc65)c5ccccc45)n3)c2)cc1] | C2-259 |
| | 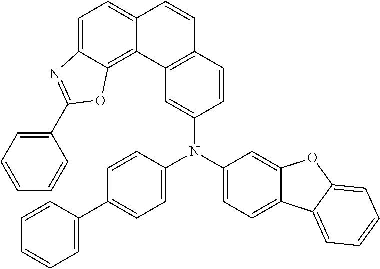 [SMILES: c1ccc(-c2ccc(N(c3ccc4c(c3)oc3ccccc34)c3ccc4ccc5ccc6nc(-c7ccccc7)oc6c5c4c3)cc2)cc1] | C-177 |
| | 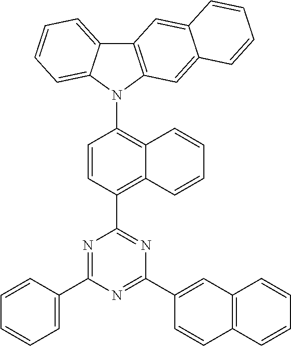 [SMILES: c1ccc(-c2nc(-c3ccc4ccccc4c3)nc(-c3ccc(-n4c5ccccc5c5cc6ccccc6cc54)c4ccccc34)n2)cc1] | C2-10 |
| | 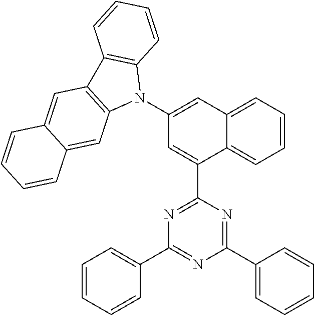 [SMILES: c1ccc(-c2nc(-c3ccccc3)nc(-c3cc(-n4c5ccccc5c5cc6ccccc6cc54)cc4ccccc34)n2)cc1] | C2-228 |
| | 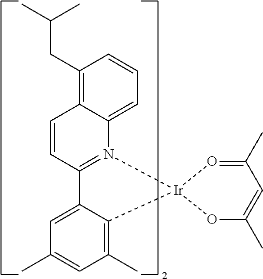 | RD |
| Electron Transport Layer/ Electron Injection Layer | 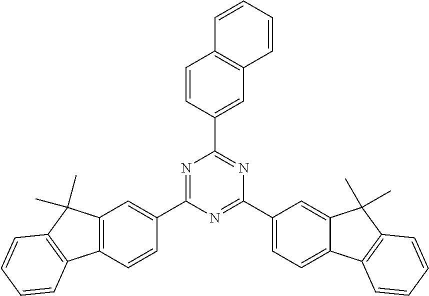 [SMILES: CC1(C)c2ccccc2-c2ccc(-c3nc(-c4ccc5c(c4)C(C)(C)c4ccccc4-5)nc(-c4ccc5ccccc5c4)n3)cc21] | ET-1 |
| | 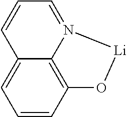 | EI-1 |

1. A plurality of host materials comprising a first host material and a second host material, wherein the first host material comprises a compound represented by the following formula 1: 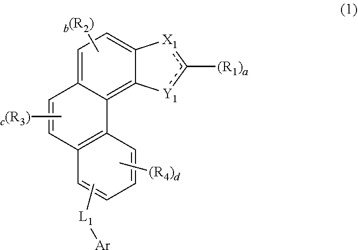
wherein,
X₁ and Y₁, each independently, represent —N═, —NR₅—, —O— or —S—, with a proviso that any one of X₁ and Y₁ represents —N═, and the other one represents —NR₅—, —O— or —S—;
L₁ represents a single bond, or a substituted or unsubstituted (C6-C30)arylene;
Ar represents a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino;
R₁ represents a substituted or unsubstituted (C6-C30)aryl, or a substituted or unsubstituted (3- to 30-membered)heteroaryl;
R₂ to R₅, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or adjacent ones of R₂ to R₅ may be linked to each other to form a ring(s);
a represents an integer of 1; b and c, each independently, represent an integer of 1 or 2; d represents an integer of 1 to 3; where if b to d, each independently, are an integer of 2 or more, each of R₂ to each of R₄ may be the same or different; and
the second host material comprises a compound represented by the following formula 2: 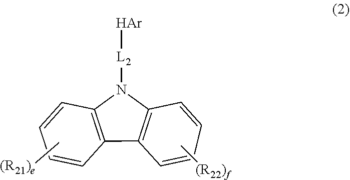
wherein,
HAr represents a substituted or unsubstituted (3- to 30-membered)heteroaryl;
L₂ represents a single bond, a substituted or unsubstituted (C6-C30)arylene, or a substituted or unsubstituted (3- to 30-membered)heteroarylene;
R₂₁ and R₂₂, each independently, represent hydrogen, deuterium, a halogen, a cyano, a substituted or unsubstituted (C1-C30)alkyl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C6-C30)aryl, a substituted or unsubstituted (3- to 30-membered)heteroaryl, —NR₁₁R₁₂, or —SiR₁₃R₁₄R₁₅; or adjacent R₂₁'s or adjacent R₂₂'s, each independently, may be linked to each other to form a ring(s), with a proviso that at least one ring is formed;
R₁₁ to R₁₅, each independently, represent a substituted or unsubstituted (C1-C30)alkyl, a substituted or unsubstituted (C6-C30)aryl, or a substituted or unsubstituted (3- to 30-membered)heteroaryl; and
e and f, each independently, represent an integer of 1 to 4; where if e and f, each independently, are an integer of 2 or more, each of R₂₁ and each of R₂₂ may be the same or different.

2. The plurality of host materials according to claim 1, wherein the substituents of the substituted alkyl, the substituted aryl, the substituted arylene, the substituted heteroaryl, the substituted heteroarylene, the substituted cycloalkyl, the substituted cycloalkenyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di-alkylamino, the substituted mono- or di-arylamino, and the substituted alkylarylamino, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with a (C6-C30)aryl(s); a (C6-C30)aryl unsubstituted or substituted with a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino unsubstituted or substituted with a (C1-C30)alkyl(s); a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The plurality of host materials according to claim 1, wherein the compound represented by formula 1 is represented by at least one of the following formulas 1-1 and 1-2: 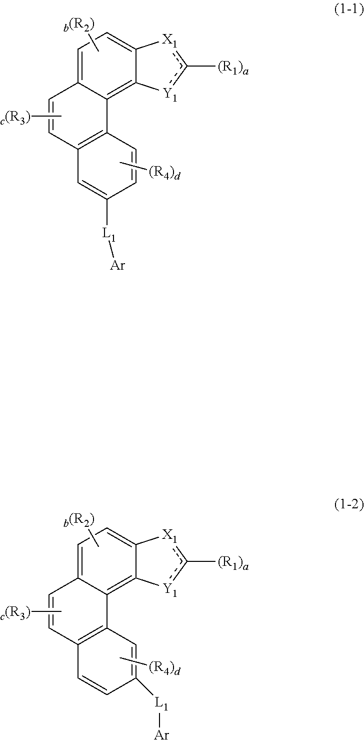
wherein, X₁, Y₁, Ar, L₁, R₁ to R₄, and a to d are as defined in claim 1.

4. The plurality of host materials according to claim 1, wherein the compound represented by formula 2 is represented by at least one of the following formulas 2-1 to 2-7: 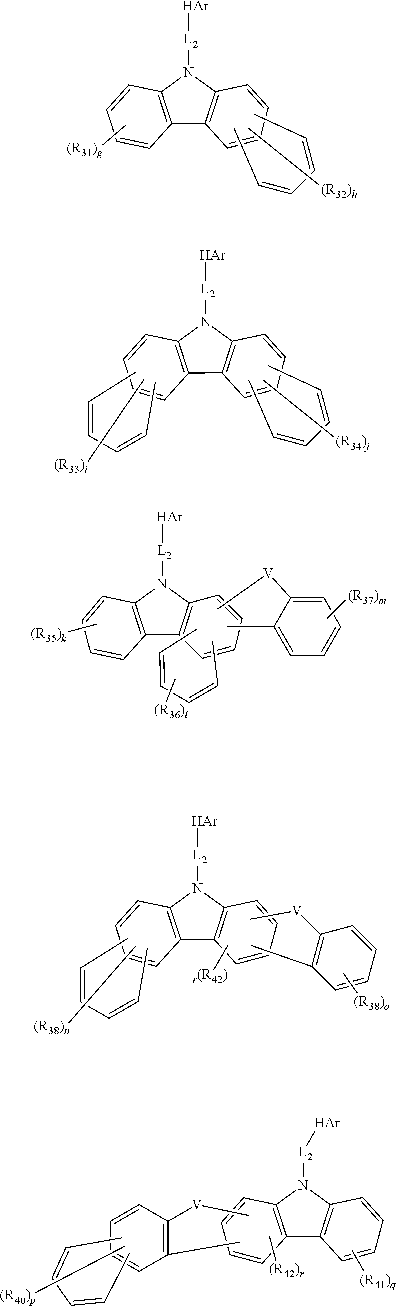 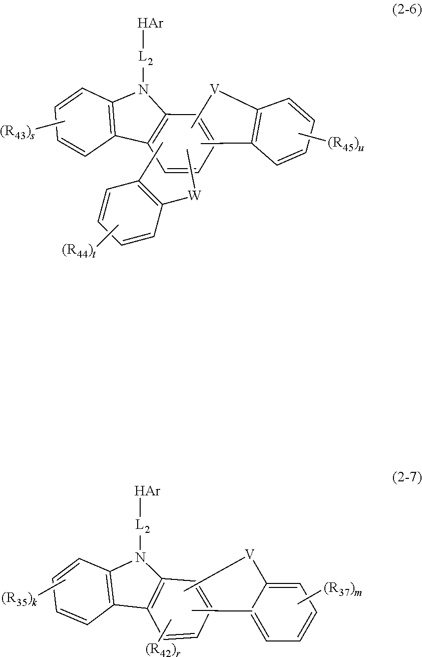
wherein,
HAr and L₂ are as defined in claim 1;
V and W, each independently, represent NR₁₆, O or S;
R₁₆ represents a substituted or unsubstituted (C6-C30)aryl, or a substituted or unsubstituted (3- to 30-membered)heteroaryl;
R₃₁ to R₄₅, each independently, represent hydrogen, deuterium, a halogen, a cyano, a substituted or unsubstituted (C1-C30)alkyl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C6-C30)aryl, a substituted or unsubstituted (3- to 30-membered)heteroaryl, —NR₆R₇, or —SiR₈R₉R₁₀;
R₈ to R₁₀, each independently, represent a substituted or unsubstituted (C1-C30)alkyl, a substituted or unsubstituted (C6-C30)aryl, or a substituted or unsubstituted (3- to 30-membered)heteroaryl; and
g, k, l, m, o, q, s, t and u, each independently, represent an integer of 1 to 4; h, i, j, n and p, each independently, represent an integer of 1 to 6; r represents an integer of 1 or 2; where if g to u, each independently, are an integer of 2 or more, each of R₃₁ to each of R₄₅ may be the same or different.

5. The plurality of host materials according to claim 1, wherein Ar in formula 1 represents a substituted or unsubstituted phenyl, a substituted or unsubstituted naphthyl, a substituted or unsubstituted biphenyl, a substituted or unsubstituted naphthylphenyl, a substituted or unsubstituted phenylnaphthyl, a substituted or unsubstituted terphenyl, a substituted or unsubstituted phenanthrenyl, a substituted or unsubstituted benzophenanthrenyl, a substituted or unsubstituted fluoranthenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted spiro[cyclopentane-fluorene]yl, a substituted or unsubstituted spiro[indan-fluorene]yl, a substituted or unsubstituted spiro[fluorene-benzofluorene]yl, a substituted or unsubstituted nitrogen-containing 23-membered heteroaryl, a substituted or unsubstituted diphenylamino, a substituted or unsubstituted phenylbiphenylamino, a substituted or unsubstituted phenylnaphthylamino, a substituted or unsubstituted phenylterphenylamino, a substituted or unsubstituted phenylfluorenylamino, a substituted or unsubstituted naphthylbiphenylamino, a substituted or unsubstituted naphthylterphenylamino, a substituted or unsubstituted naphthylphenanthrenylamino, a substituted or unsubstituted dinaphthylamino, a substituted or unsubstituted dibiphenylamino, a substituted or unsubstituted biphenylfluorenylamino, a substituted or unsubstituted difluorenylamino, a substituted or unsubstituted biphenyldibenzofuranylamino, a substituted or unsubstituted biphenyidibenzothiophenylamino, or a substituted or unsubstituted phenylcarbazolyamino.

6. The plurality of host materials according to claim 1, wherein HAr in formula 2 represents a substituted or unsubstituted triazinyl, a substituted or unsubstituted pyridyl, a substituted or unsubstituted pyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted naphthyridinyl, or a substituted or unsubstituted benzothienopyrimidinyl.

7. The plurality of host materials according to claim 1, wherein the compound represented by formula 2 is represented by at least one of the following formulas 2-11 to 2-38: 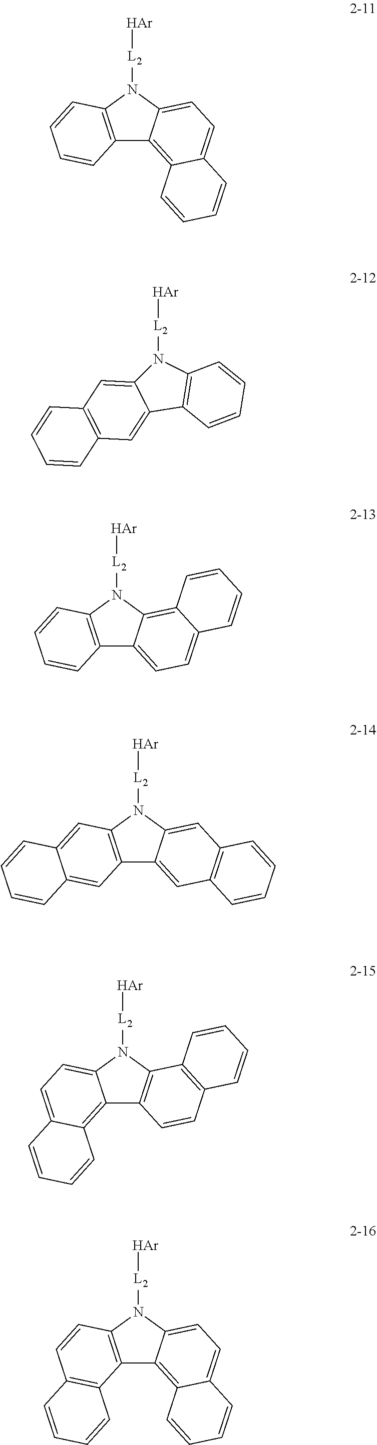 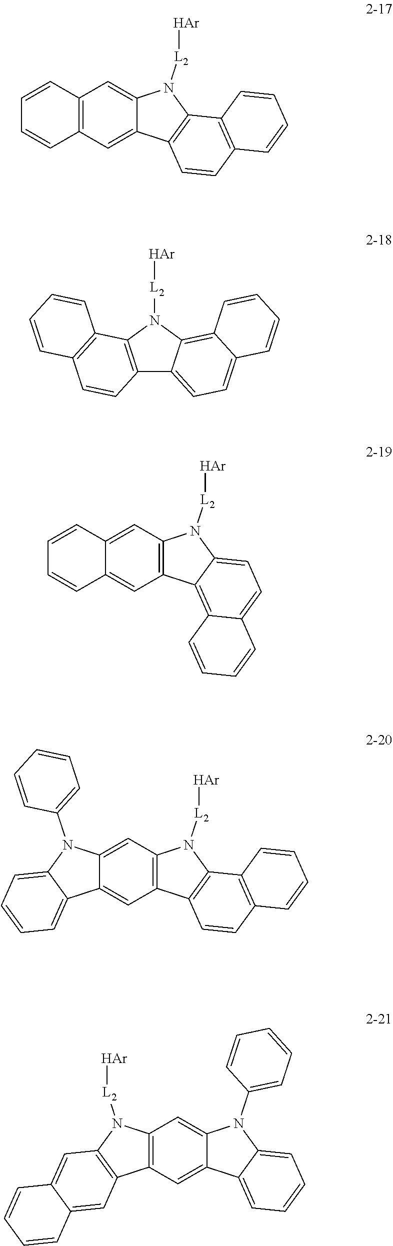 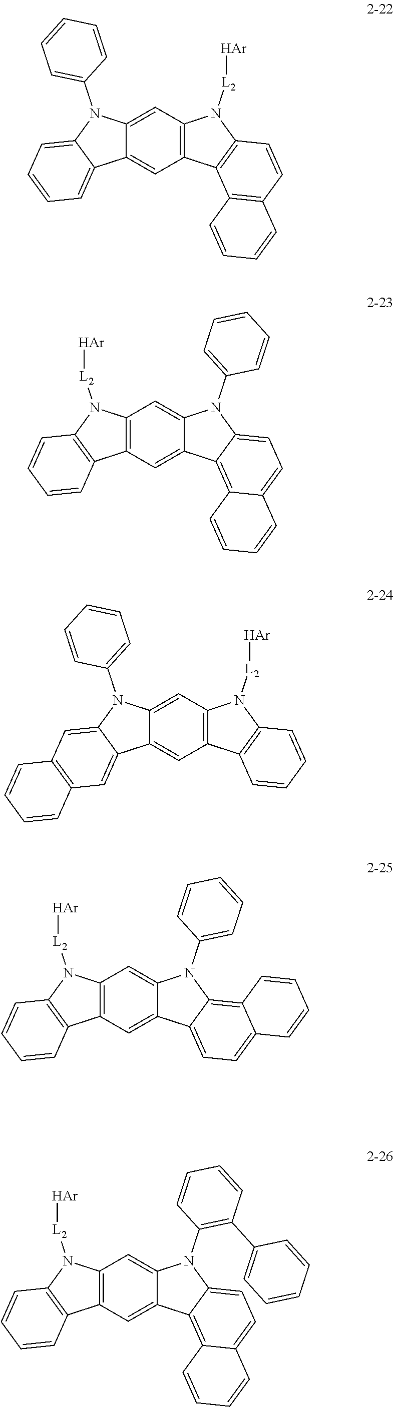 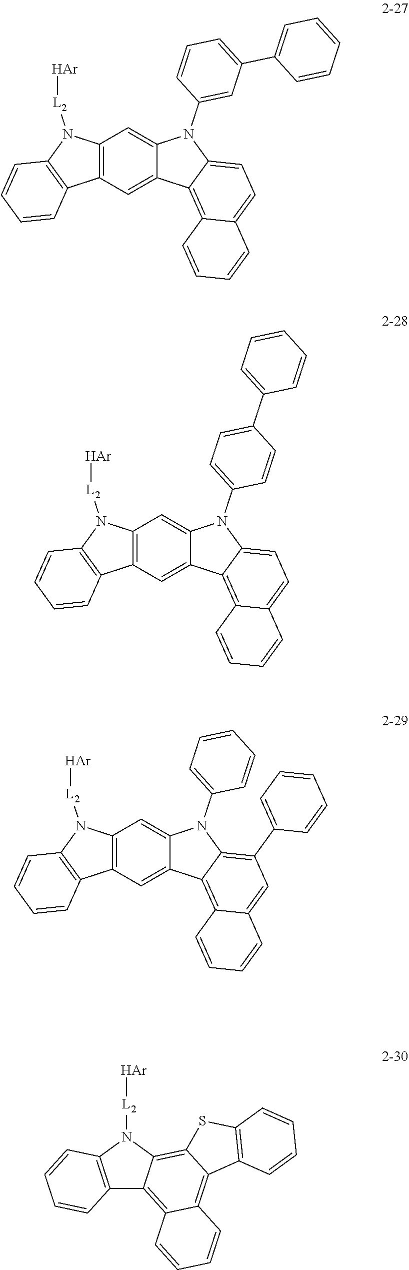 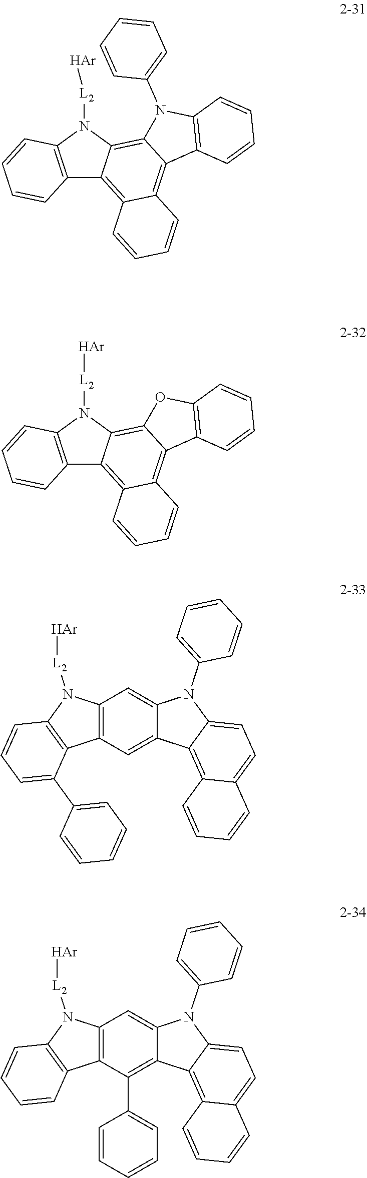 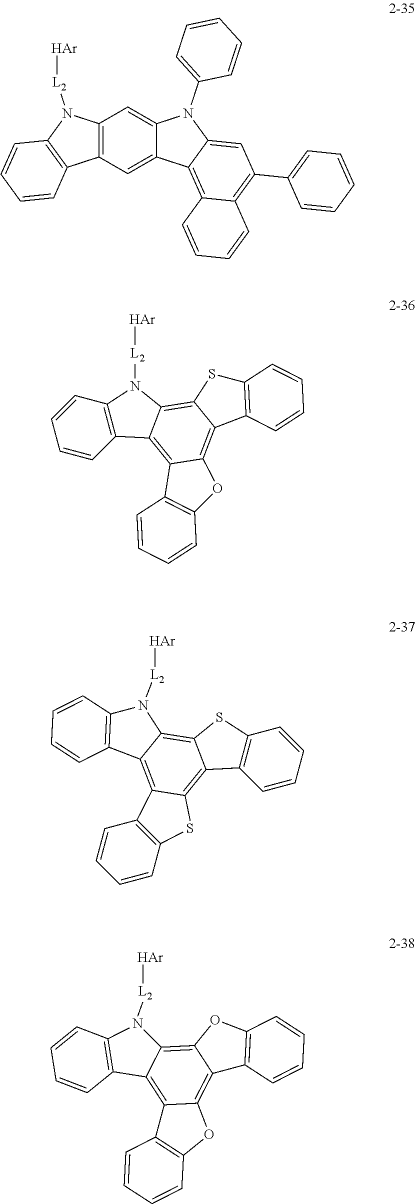
wherein, HAr, each independently, represents any one selected from the group consisting of the following structures 4-1 to 4-28: 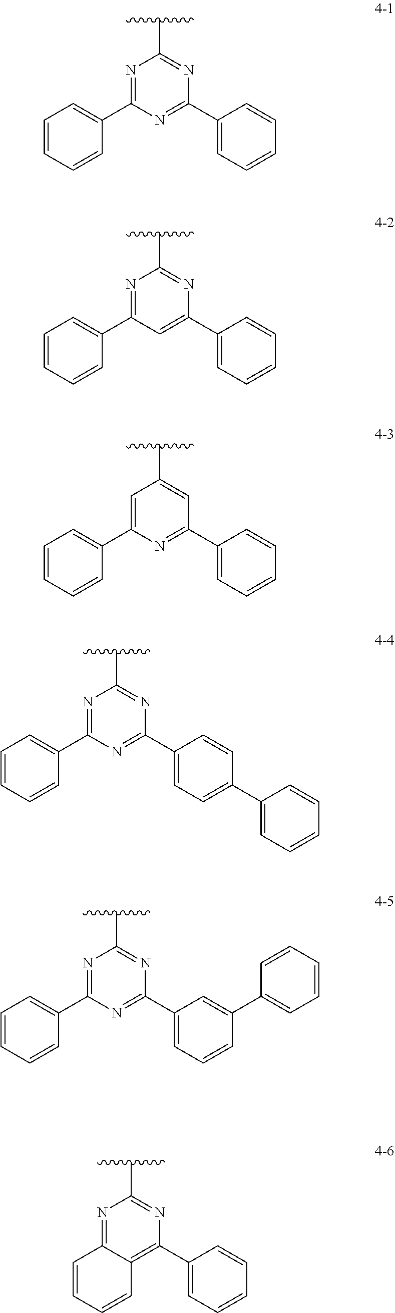 [SMILES: *c1nc(-c2ccccc2)nc(-c2ccccc2)n1 ; *c1nc(-c2ccccc2)cc(-c2ccccc2)n1 ; *c1cc(-c2ccccc2)nc(-c2ccccc2)c1 ; *c1nc(-c2ccccc2)nc(-c2ccc(-c3ccccc3)cc2)n1 ; *c1nc(-c2ccccc2)nc(-c2cccc(-c3ccccc3)c2)n1 ; *c1nc(-c2ccccc2)c2ccccc2n1] 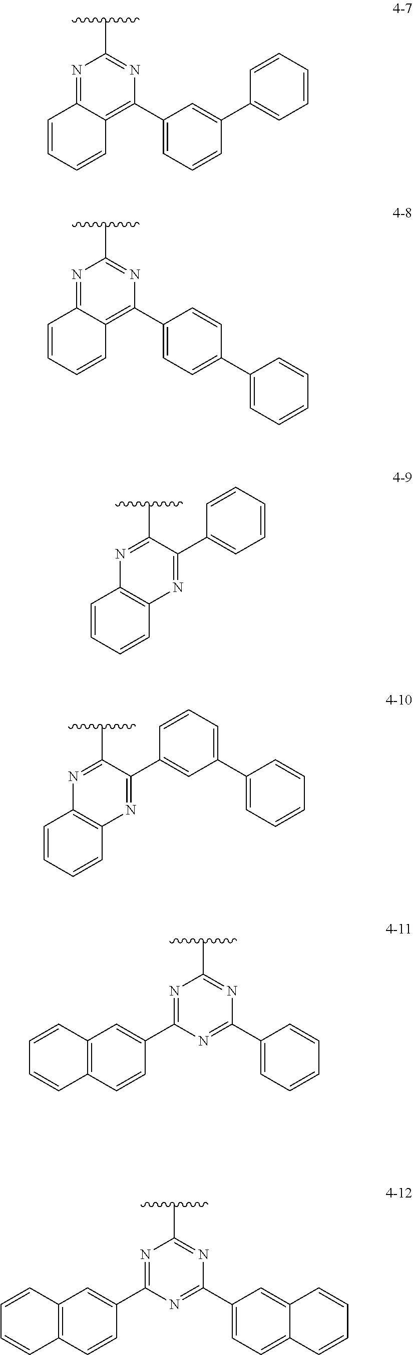 [SMILES: *c1nc(-c2cccc(-c3ccccc3)c2)c2ccccc2n1 ; *c1nc(-c2ccc(-c3ccccc3)cc2)c2ccccc2n1 ; *c1nc2ccccc2nc1-c1ccccc1 ; *c1nc2ccccc2nc1-c1cccc(-c2ccccc2)c1 ; *c1nc(-c2ccccc2)nc(-c2ccc3ccccc3c2)n1 ; *c1nc(-c2ccc3ccccc3c2)nc(-c2ccc3ccccc3c2)n1] 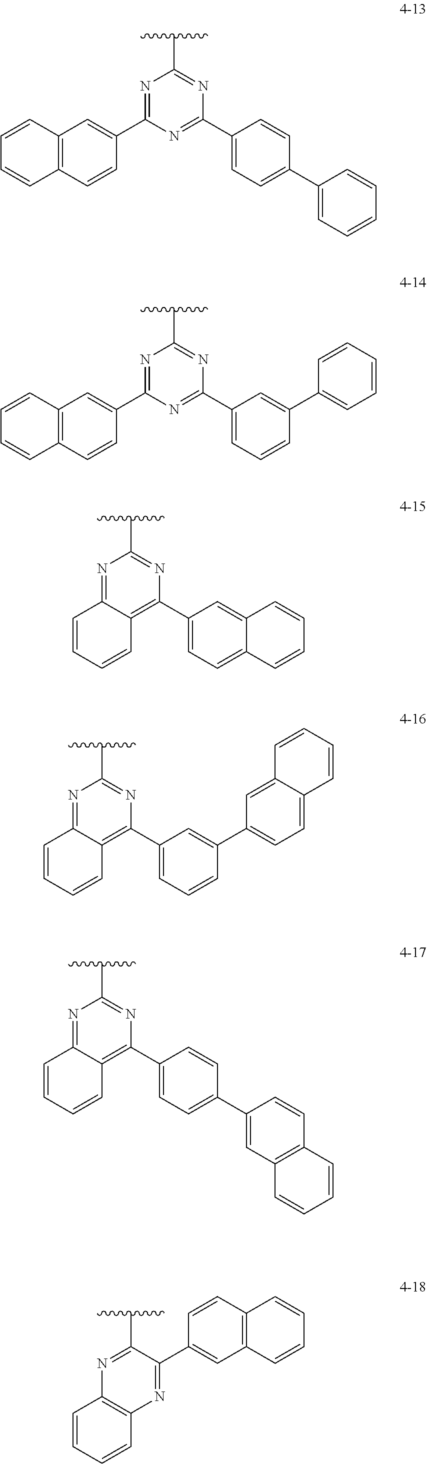 [SMILES: *c1nc(-c2ccc(-c3ccccc3)cc2)nc(-c2ccc3ccccc3c2)n1 ; *c1nc(-c2cccc(-c3ccccc3)c2)nc(-c2ccc3ccccc3c2)n1 ; *c1nc(-c2ccc3ccccc3c2)c2ccccc2n1 ; *c1nc(-c2cccc(-c3ccc4ccccc4c3)c2)c2ccccc2n1 ; *c1nc(-c2ccc(-c3ccc4ccccc4c3)cc2)c2ccccc2n1 ; *c1nc2ccccc2nc1-c1ccc2ccccc2c1] 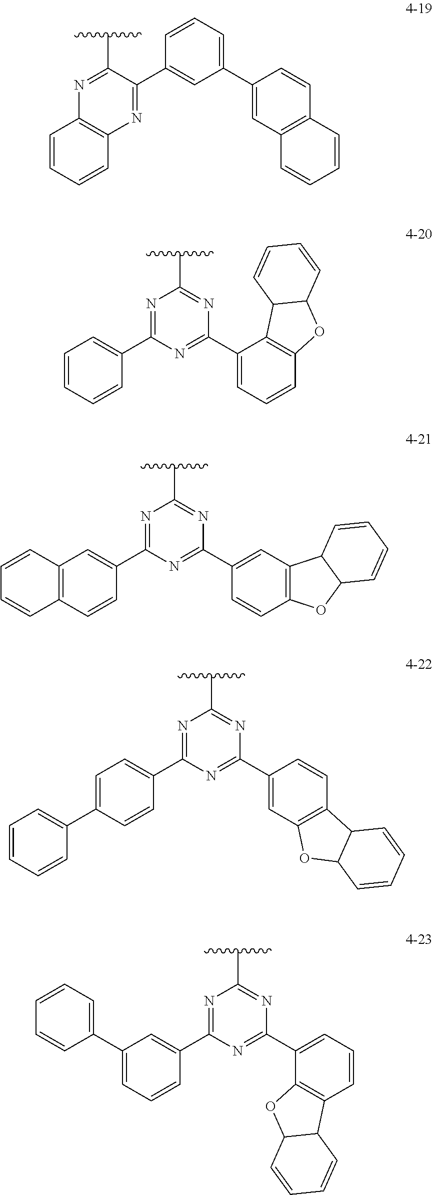 [SMILES: *c1nc2ccccc2nc1-c1cccc(-c2ccc3ccccc3c2)c1 ; *c1nc(-c2ccccc2)nc(-c2cccc3c2C2C=CC=CC2O3)n1 ; *c1nc(-c2ccc3c(c2)C2C=CC=CC2O3)nc(-c2ccc3ccccc3c2)n1 ; *c1nc(-c2ccc(-c3ccccc3)cc2)nc(-c2ccc3c(c2)OC2C=CC=CC32)n1 ; *c1nc(-c2cccc(-c3ccccc3)c2)nc(-c2cccc3c2OC2C=CC=CC32)n1] 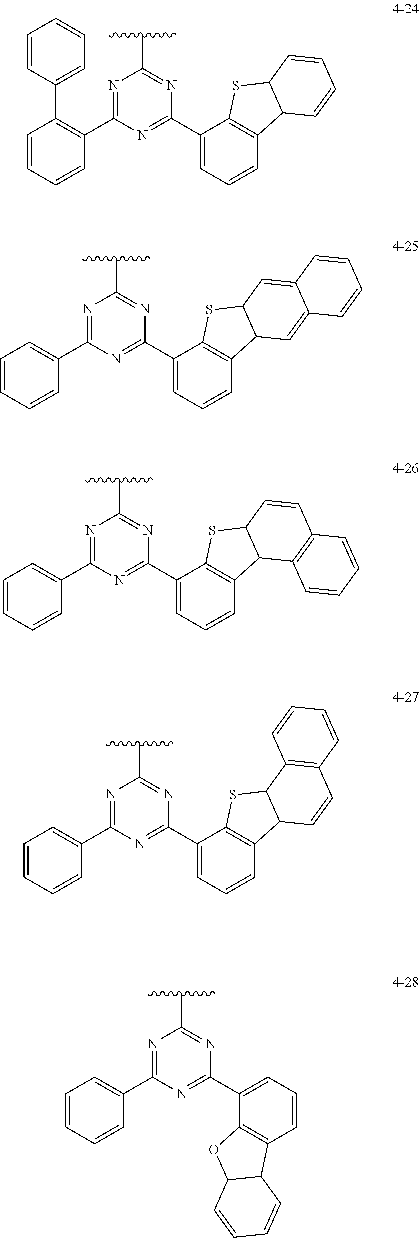 [SMILES: *c1nc(-c2ccccc2-c2ccccc2)nc(-c2cccc3c2SC2C=CC=CC32)n1 ; *c1nc(-c2ccccc2)nc(-c2cccc3c2SC2C=c4ccccc4=CC32)n1 ; *c1nc(-c2ccccc2)nc(-c2cccc3c2SC2C=Cc4ccccc4C32)n1 ; *c1nc(-c2ccccc2)nc(-c2cccc3c2SC2c4ccccc4C=CC32)n1 ; *c1nc(-c2ccccc2)nc(-c2cccc3c2OC2C=CC=CC32)n1]
L₂, each independently, represents a single bond, or any one selected from the group consisting of the following structures 3-1 to 3-40:

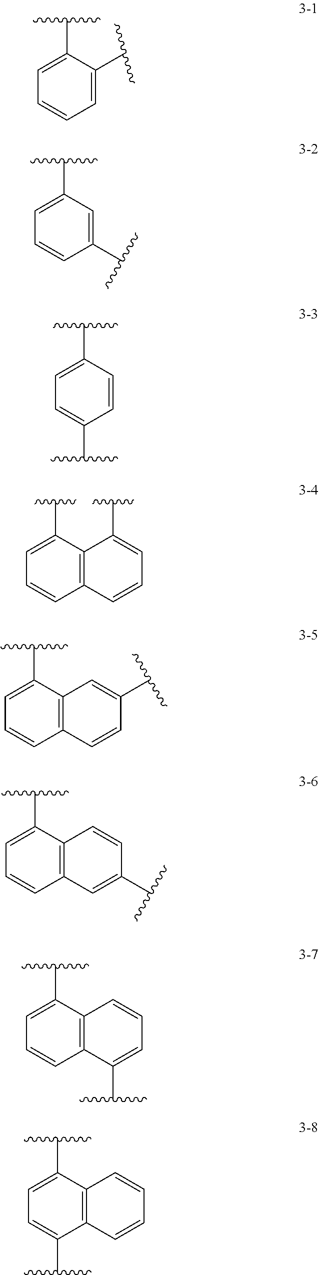

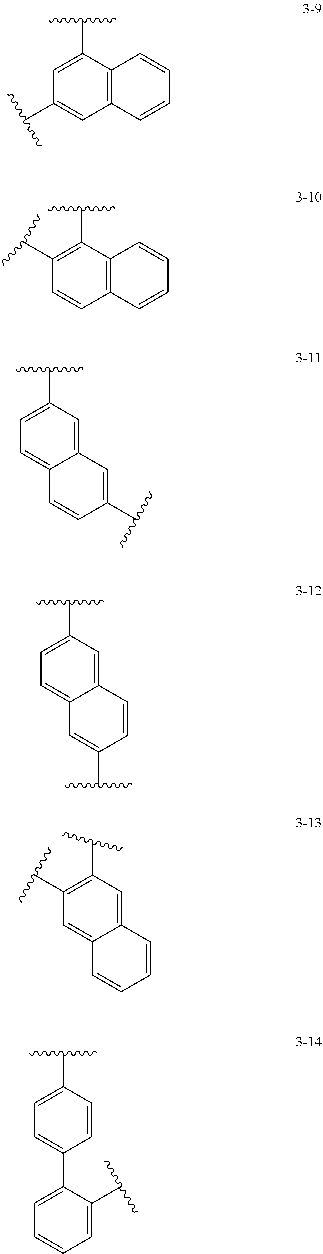 [SMILES: *c1cc(*)c2ccccc2c1 ; *c1ccc2ccccc2c1* ; *c1ccc2ccc(*)cc2c1 ; *c1ccc2cc(*)ccc2c1 ; *c1cc2ccccc2cc1* ; *c1ccc(-c2ccccc2*)cc1]

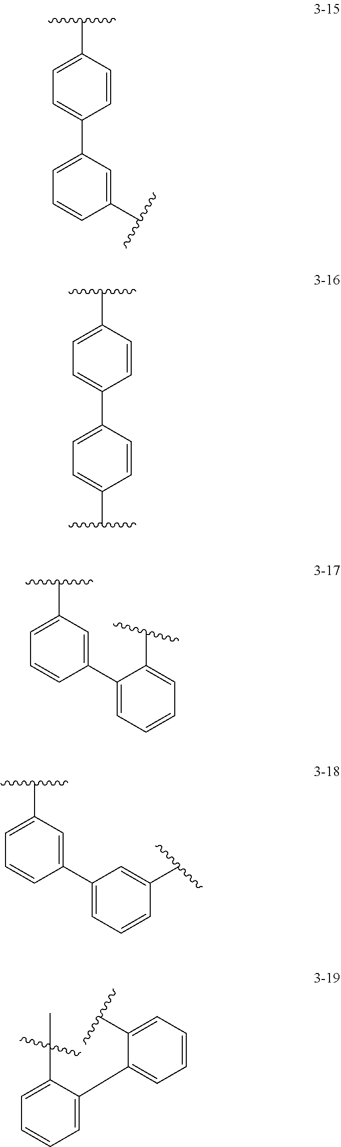 [SMILES: *c1ccc(-c2cccc(*)c2)cc1 ; *c1ccc(-c2ccc(*)cc2)cc1 ; *c1cccc(-c2ccccc2*)c1 ; *c1cccc(-c2cccc(*)c2)c1 ; *c1ccccc1-c1ccccc1*]

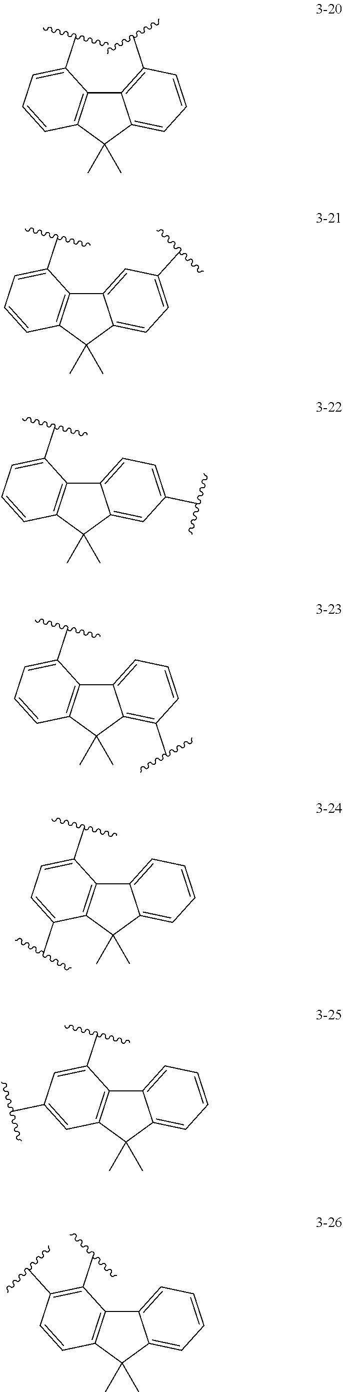

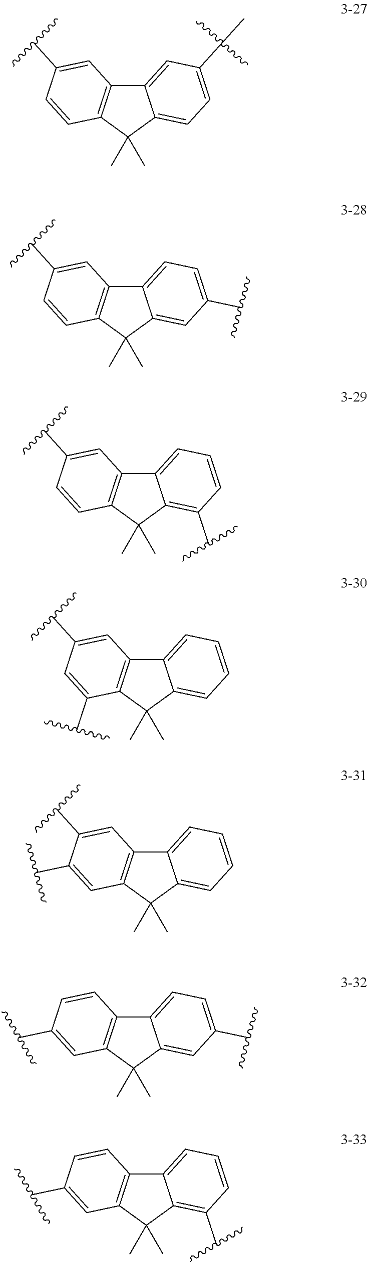

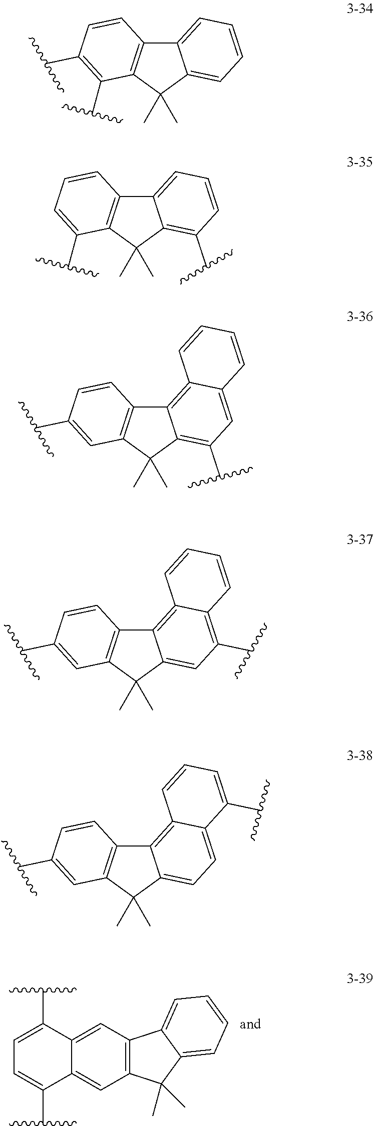 [SMILES: *c1ccc2c(c1*)C(C)(C)c1ccccc1-2 ; *c1cccc2c1C(C)(C)c1c(*)cccc1-2 ; *c1ccc2c(c1)C(C)(C)c1c(*)cc3ccccc3c1-2 ; *c1ccc2c(c1)C(C)(C)c1cc(*)c3ccccc3c1-2 ; *c1ccc2c(c1)C(C)(C)c1ccc3c(*)cccc3c1-2 ; *c1ccc(*)c2cc3c(cc12)-c1ccccc1C3(C)C]

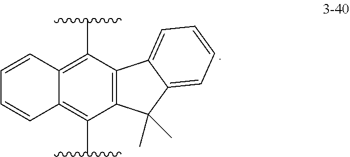 [SMILES: *c1c2c(c(*)c3ccccc13)C(C)(C)c1ccccc1-2]

8. The plurality of host materials according to claim 1, wherein the compound represented by formula 1 is at least one selected from the group consisting of the following compounds:

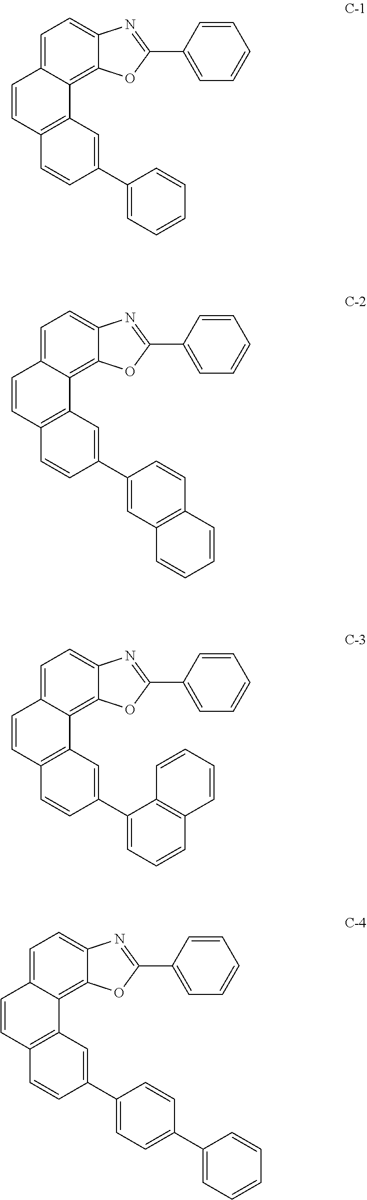 [SMILES: c1ccc(-c2ccc3ccc4ccc5nc(-c6ccccc6)oc5c4c3c2)cc1 ; c1ccc(-c2nc3ccc4ccc5ccc(-c6ccc7ccccc7c6)cc5c4c3o2)cc1 ; c1ccc(-c2nc3ccc4ccc5ccc(-c6cccc7ccccc67)cc5c4c3o2)cc1 ; c1ccc(-c2ccc(-c3ccc4ccc5ccc6nc(-c7ccccc7)oc6c5c4c3)cc2)cc1]

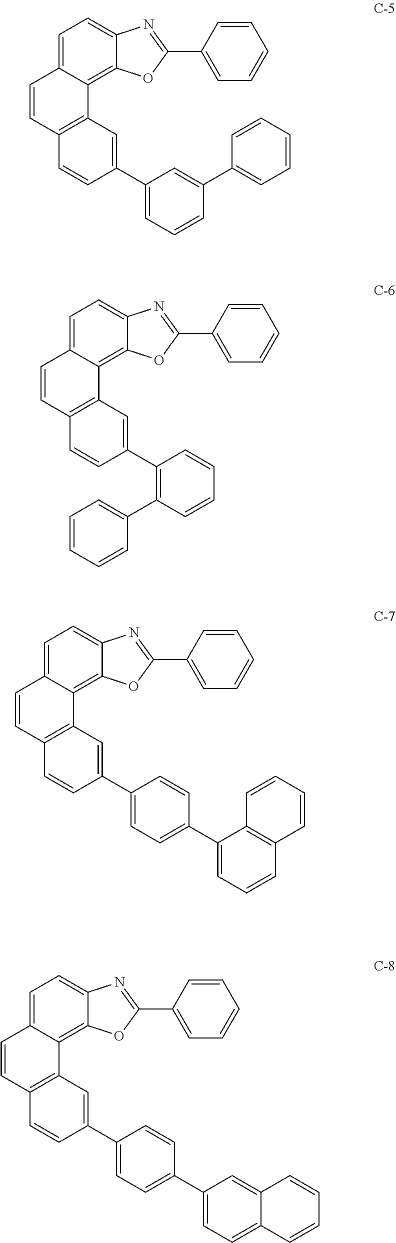 [SMILES: c1ccc(-c2cccc(-c3ccc4ccc5ccc6nc(-c7ccccc7)oc6c5c4c3)c2)cc1 ; c1ccc(-c2nc3ccc4ccc5ccc(-c6ccccc6-c6ccccc6)cc5c4c3o2)cc1 ; c1ccc(-c2nc3ccc4ccc5ccc(-c6ccc(-c7cccc8ccccc78)cc6)cc5c4c3o2)cc1 ; c1ccc(-c2nc3ccc4ccc5ccc(-c6ccc(-c7ccc8ccccc8c7)cc6)cc5c4c3o2)cc1]

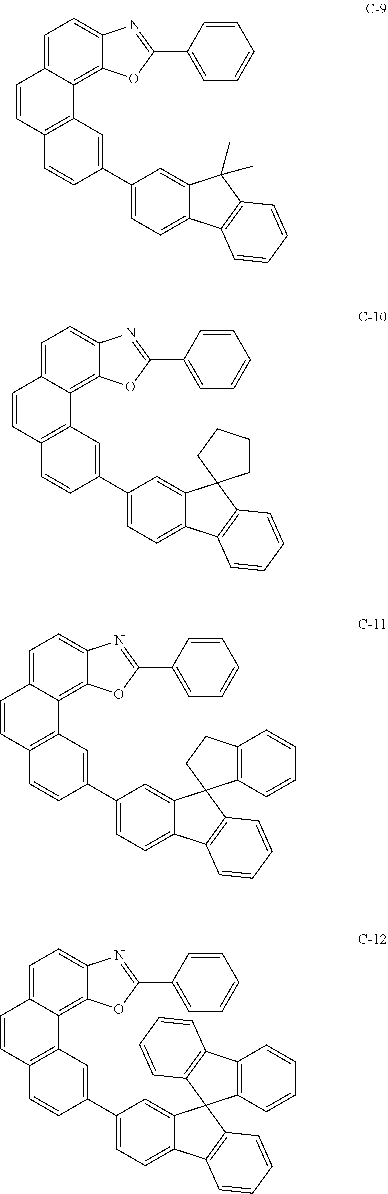 [SMILES: CC1(C)c2ccccc2-c2ccc(-c3ccc4ccc5ccc6nc(-c7ccccc7)oc6c5c4c3)cc21 ; c1ccc(-c2nc3ccc4ccc5ccc(-c6ccc7c(c6)C6(CCCC6)c6ccccc6-7)cc5c4c3o2)cc1 ; c1ccc(-c2nc3ccc4ccc5ccc(-c6ccc7c(c6)C6(CCc8ccccc86)c6ccccc6-7)cc5c4c3o2)cc1 ; c1ccc(-c2nc3ccc4ccc5ccc(-c6ccc7c(c6)C6(c8ccccc8-c8ccccc86)c6ccccc6-7)cc5c4c3o2)cc1]

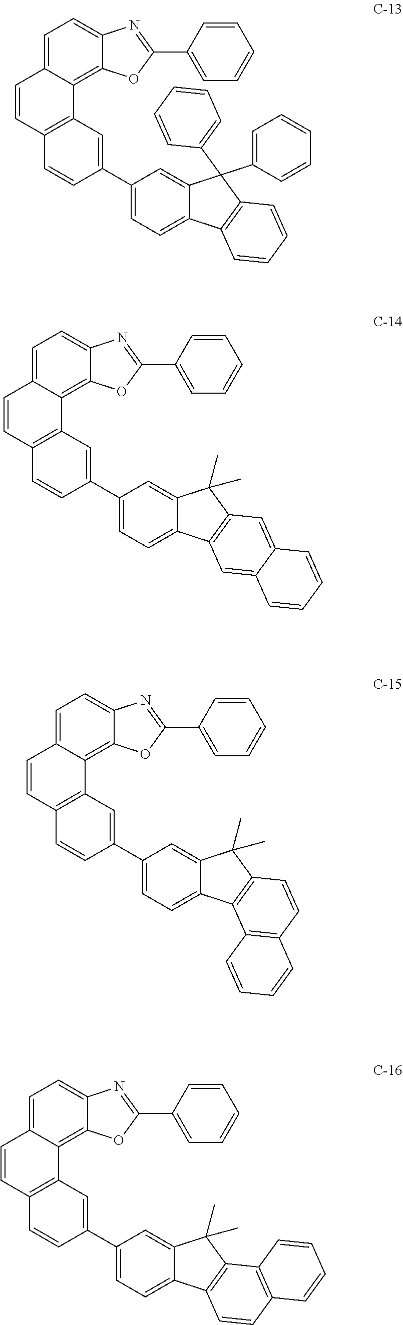 [SMILES: c1ccc(-c2nc3ccc4ccc5ccc(-c6ccc7c(c6)C(c6ccccc6)(c6ccccc6)c6ccccc6-7)cc5c4c3o2)cc1 ; CC1(C)c2cc(-c3ccc4ccc5ccc6nc(-c7ccccc7)oc6c5c4c3)ccc2-c2cc3ccccc3cc21 ; CC1(C)c2cc(-c3ccc4ccc5ccc6nc(-c7ccccc7)oc6c5c4c3)ccc2-c2c1ccc1ccccc21 ; CC1(C)c2cc(-c3ccc4ccc5ccc6nc(-c7ccccc7)oc6c5c4c3)ccc2-c2ccc3ccccc3c21]

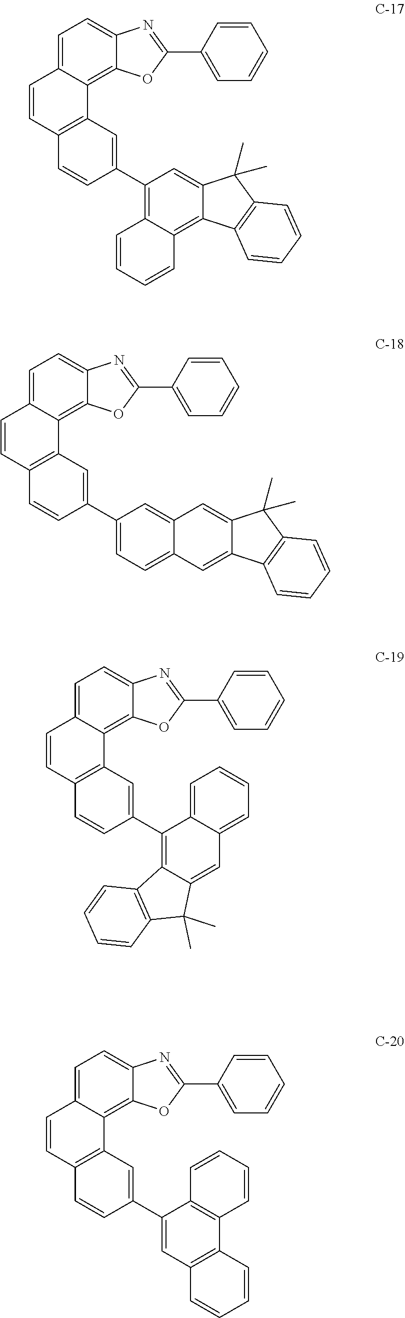 [SMILES: CC1(C)c2ccccc2-c2c1cc(-c1ccc3ccc4ccc5nc(-c6ccccc6)oc5c4c3c1)c1ccccc21 ; CC1(C)c2ccccc2-c2cc3ccc(-c4ccc5ccc6ccc7nc(-c8ccccc8)oc7c6c5c4)cc3cc21 ; CC1(C)c2ccccc2-c2c1cc1ccccc1c2-c1ccc2ccc3ccc4nc(-c5ccccc5)oc4c3c2c1 ; c1ccc(-c2nc3ccc4ccc5ccc(-c6cc7ccccc7c7ccccc67)cc5c4c3o2)cc1]

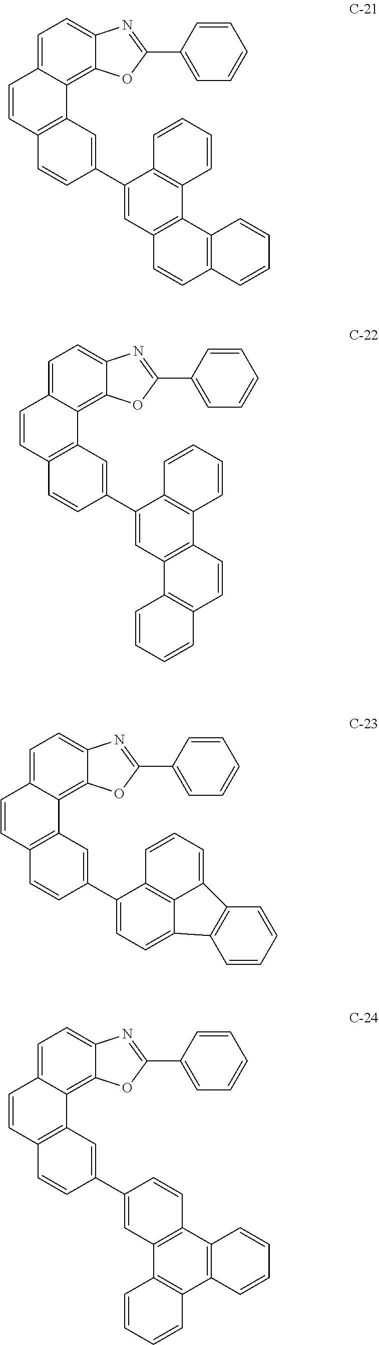 [SMILES: c1ccc(-c2nc3ccc4ccc5ccc(-c6cc7ccc8ccccc8c7c7ccccc67)cc5c4c3o2)cc1 ; c1ccc(-c2nc3ccc4ccc5ccc(-c6cc7c8ccccc8ccc7c7ccccc67)cc5c4c3o2)cc1 ; c1ccc(-c2nc3ccc4ccc5ccc(-c6ccc7c8c(cccc68)-c6ccccc6-7)cc5c4c3o2)cc1 ; c1ccc(-c2nc3ccc4ccc5ccc(-c6ccc7c8ccccc8c8ccccc8c7c6)cc5c4c3o2)cc1]

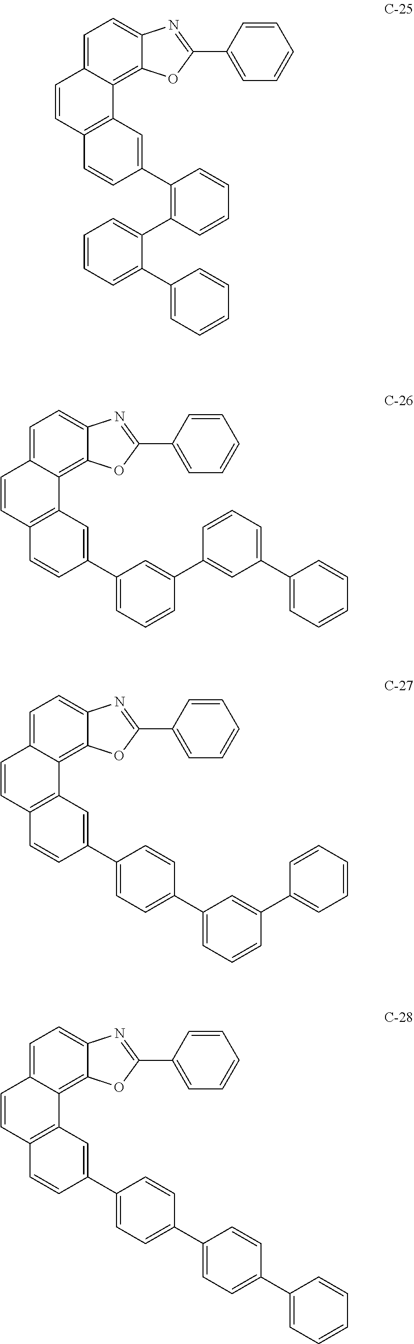 [SMILES: c1ccc(-c2nc3ccc4ccc5ccc(-c6ccccc6-c6ccccc6-c6ccccc6)cc5c4c3o2)cc1 ; c1ccc(-c2cccc(-c3cccc(-c4ccc5ccc6ccc7nc(-c8ccccc8)oc7c6c5c4)c3)c2)cc1 ; c1ccc(-c2cccc(-c3ccc(-c4ccc5ccc6ccc7nc(-c8ccccc8)oc7c6c5c4)cc3)c2)cc1 ; c1ccc(-c2ccc(-c3ccc(-c4ccc5ccc6ccc7nc(-c8ccccc8)oc7c6c5c4)cc3)cc2)cc1]

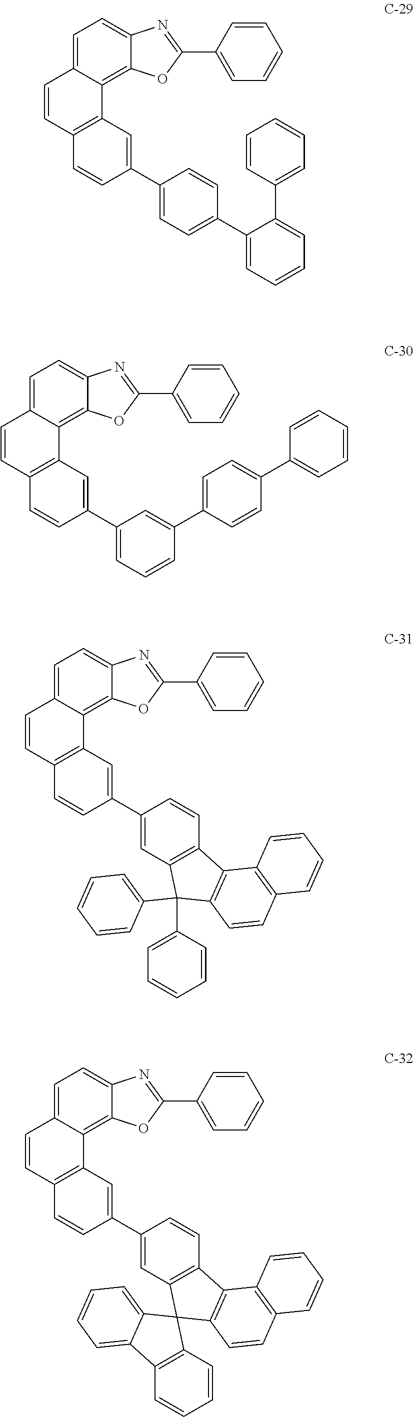 [SMILES: c1ccc(-c2nc3ccc4ccc5ccc(-c6ccc(-c7ccccc7-c7ccccc7)cc6)cc5c4c3o2)cc1 ; c1ccc(-c2ccc(-c3cccc(-c4ccc5ccc6ccc7nc(-c8ccccc8)oc7c6c5c4)c3)cc2)cc1 ; c1ccc(-c2nc3ccc4ccc5ccc(-c6ccc7c(c6)C(c6ccccc6)(c6ccccc6)c6ccc8ccccc8c6-7)cc5c4c3o2)cc1 ; c1ccc(-c2nc3ccc4ccc5ccc(-c6ccc7c(c6)C6(c8ccccc8-c8ccccc86)c6ccc8ccccc8c6-7)cc5c4c3o2)cc1]

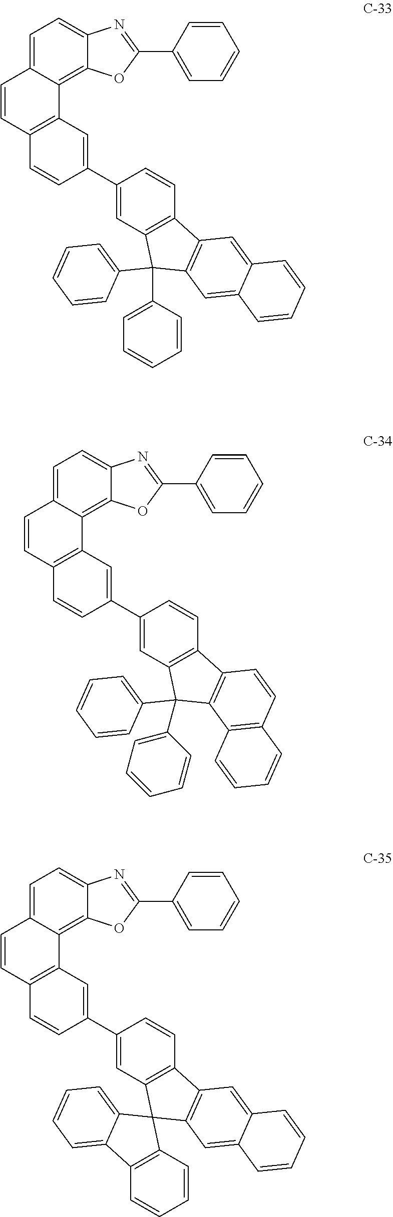 [SMILES: c1ccc(-c2nc3ccc4ccc5ccc(-c6ccc7c(c6)C(c6ccccc6)(c6ccccc6)c6cc8ccccc8cc6-7)cc5c4c3o2)cc1 ; c1ccc(-c2nc3ccc4ccc5ccc(-c6ccc7c(c6)C(c6ccccc6)(c6ccccc6)c6c-7ccc7ccccc67)cc5c4c3o2)cc1 ; c1ccc(-c2nc3ccc4ccc5ccc(-c6ccc7c(c6)C6(c8ccccc8-c8ccccc86)c6cc8ccccc8cc6-7)cc5c4c3o2)cc1]

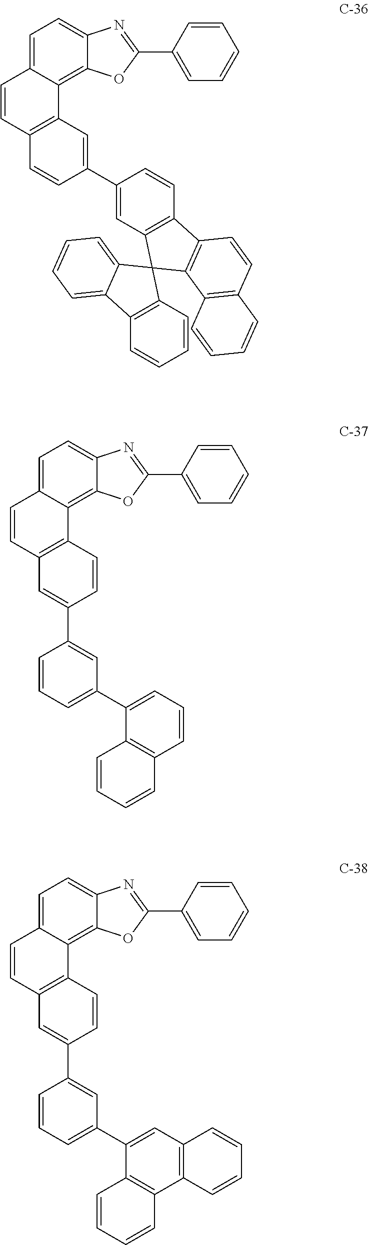 [SMILES: c1ccc(-c2nc3ccc4ccc5ccc(-c6ccc7c(c6)C6(c8ccccc8-c8ccccc86)c6c-7ccc7ccccc67)cc5c4c3o2)cc1 ; c1ccc(-c2nc3ccc4ccc5cc(-c6cccc(-c7cccc8ccccc78)c6)ccc5c4c3o2)cc1 ; c1ccc(-c2nc3ccc4ccc5cc(-c6cccc(-c7cc8ccccc8c8ccccc78)c6)ccc5c4c3o2)cc1]

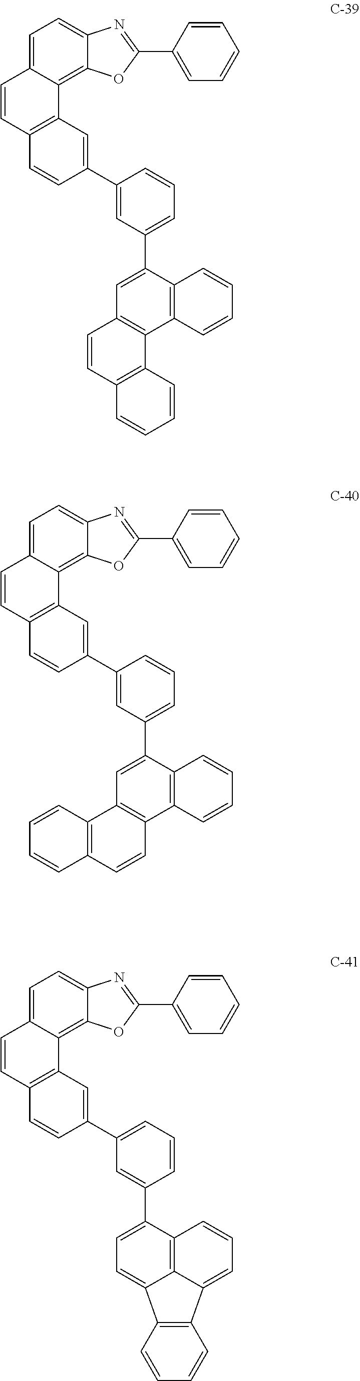 [SMILES: c1ccc(-c2nc3ccc4ccc5ccc(-c6cccc(-c7cc8ccc9ccccc9c8c8ccccc78)c6)cc5c4c3o2)cc1 ; c1ccc(-c2nc3ccc4ccc5ccc(-c6cccc(-c7cc8c9ccccc9ccc8c8ccccc78)c6)cc5c4c3o2)cc1 ; c1ccc(-c2nc3ccc4ccc5ccc(-c6cccc(-c7ccc8c9c(cccc79)-c7ccccc7-8)c6)cc5c4c3o2)cc1]

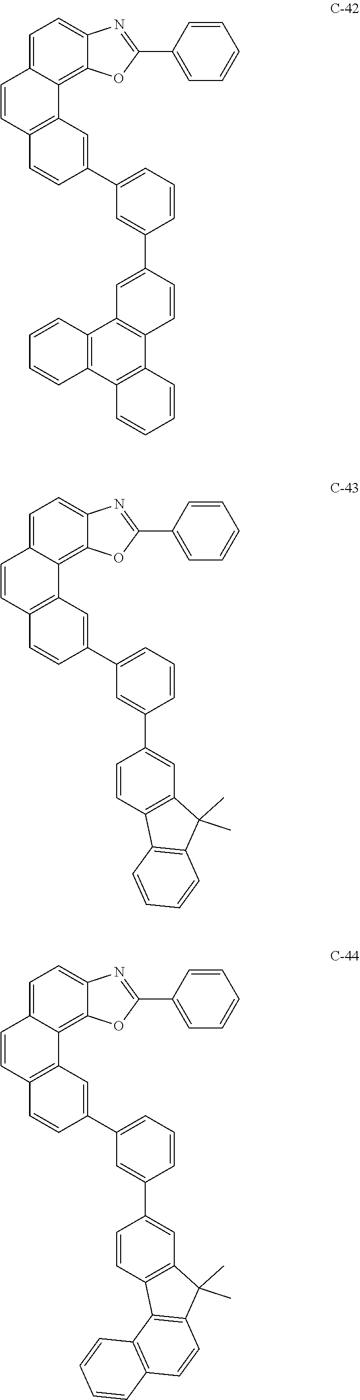 [SMILES: c1ccc(-c2nc3ccc4ccc5ccc(-c6cccc(-c7ccc8c9ccccc9c9ccccc9c8c7)c6)cc5c4c3o2)cc1 ; CC1(C)c2ccccc2-c2ccc(-c3cccc(-c4ccc5ccc6ccc7nc(-c8ccccc8)oc7c6c5c4)c3)cc21 ; CC1(C)c2cc(-c3cccc(-c4ccc5ccc6ccc7nc(-c8ccccc8)oc7c6c5c4)c3)ccc2-c2c1ccc1ccccc21]

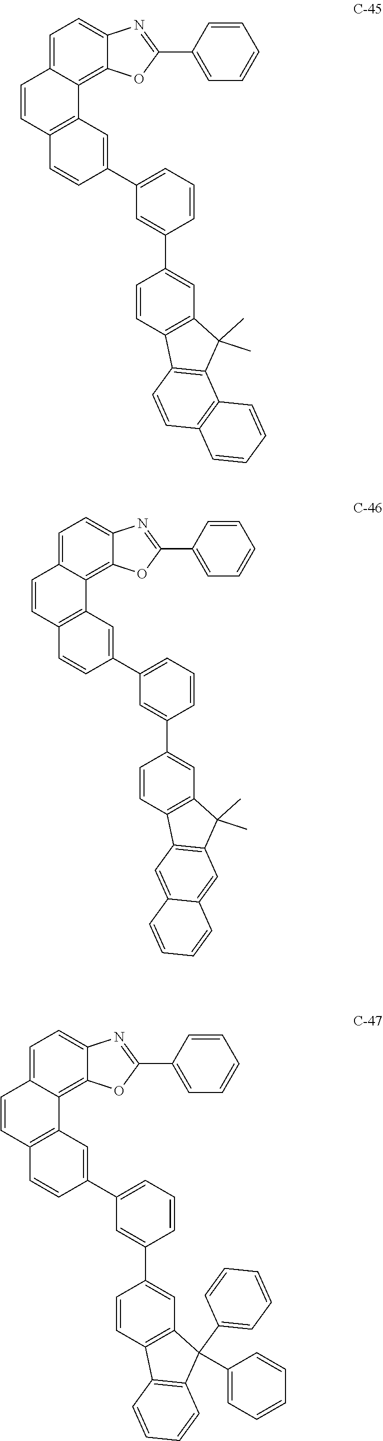 [SMILES: CC1(C)c2cc(-c3cccc(-c4ccc5ccc6ccc7nc(-c8ccccc8)oc7c6c5c4)c3)ccc2-c2ccc3ccccc3c21 ; CC1(C)c2cc(-c3cccc(-c4ccc5ccc6ccc7nc(-c8ccccc8)oc7c6c5c4)c3)ccc2-c2cc3ccccc3cc21 ; c1ccc(-c2nc3ccc4ccc5ccc(-c6cccc(-c7ccc8c(c7)C(c7ccccc7)(c7ccccc7)c7ccccc7-8)c6)cc5c4c3o2)cc1]

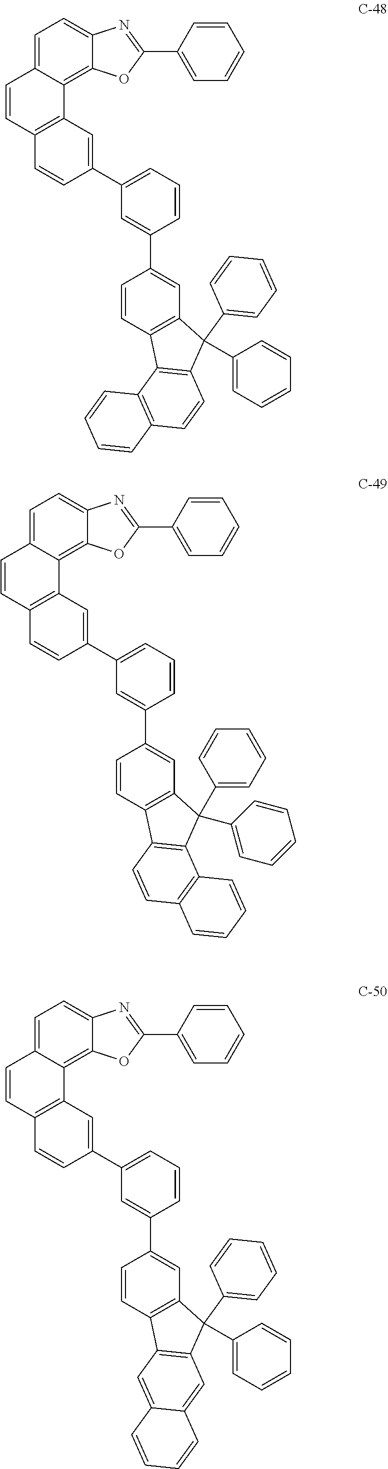 [SMILES: c1ccc(-c2nc3ccc4ccc5ccc(-c6cccc(-c7ccc8c(c7)C(c7ccccc7)(c7ccccc7)c7ccc9ccccc9c7-8)c6)cc5c4c3o2)cc1 ; c1ccc(-c2nc3ccc4ccc5ccc(-c6cccc(-c7ccc8c(c7)C(c7ccccc7)(c7ccccc7)c7c-8ccc8ccccc78)c6)cc5c4c3o2)cc1 ; c1ccc(-c2nc3ccc4ccc5ccc(-c6cccc(-c7ccc8c(c7)C(c7ccccc7)(c7ccccc7)c7cc9ccccc9cc7-8)c6)cc5c4c3o2)cc1]

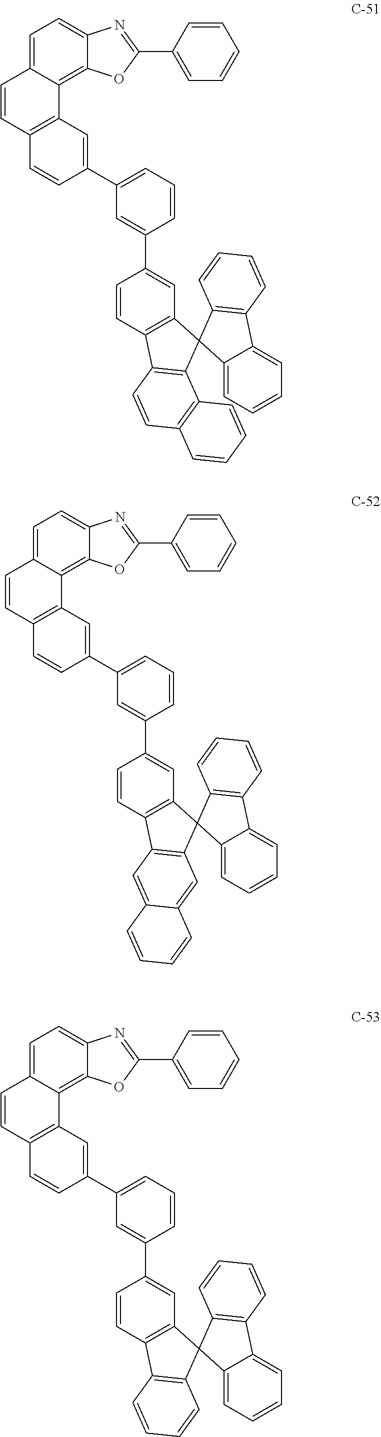 [SMILES: c1ccc(-c2nc3ccc4ccc5ccc(-c6cccc(-c7ccc8c(c7)C7(c9ccccc9-c9ccccc97)c7c-8ccc8ccccc78)c6)cc5c4c3o2)cc1 ; c1ccc(-c2nc3ccc4ccc5ccc(-c6cccc(-c7ccc8c(c7)C7(c9ccccc9-c9ccccc97)c7cc9ccccc9cc7-8)c6)cc5c4c3o2)cc1 ; c1ccc(-c2nc3ccc4ccc5ccc(-c6cccc(-c7ccc8c(c7)C7(c9ccccc9-c9ccccc97)c7ccccc7-8)c6)cc5c4c3o2)cc1]

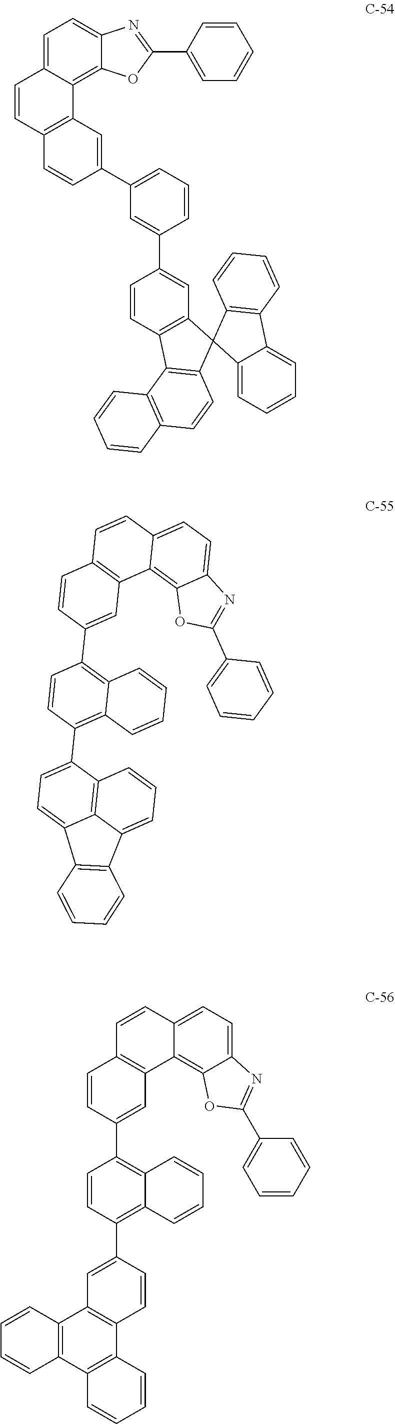 [SMILES: c1ccc(-c2nc3ccc4ccc5ccc(-c6cccc(-c7ccc8c(c7)C7(c9ccccc9-c9ccccc97)c7ccc9ccccc9c7-8)c6)cc5c4c3o2)cc1 ; c1ccc(-c2nc3ccc4ccc5ccc(-c6ccc(-c7ccc8c9c(cccc79)-c7ccccc7-8)c7ccccc67)cc5c4c3o2)cc1 ; c1ccc(-c2nc3ccc4ccc5ccc(-c6ccc(-c7ccc8c9ccccc9c9ccccc9c8c7)c7ccccc67)cc5c4c3o2)cc1]

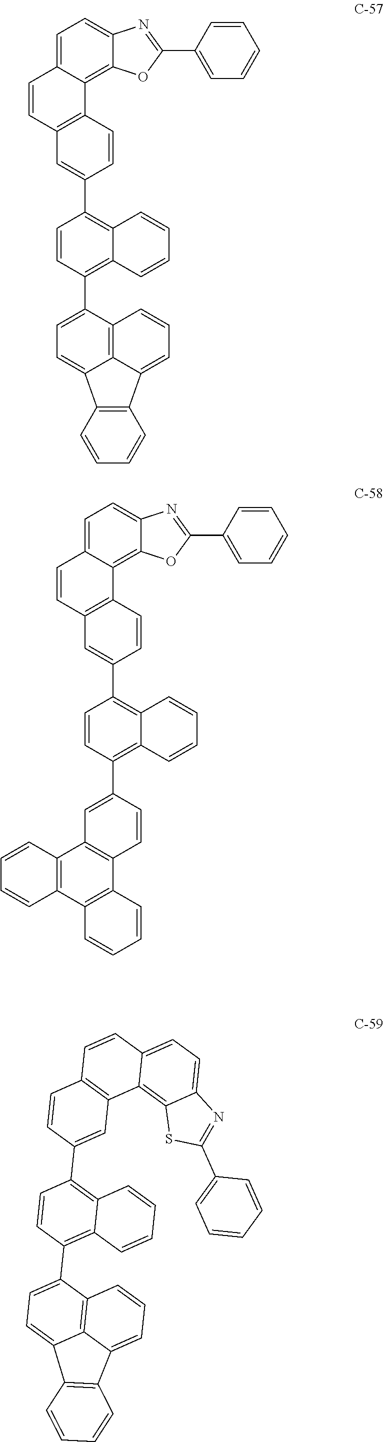

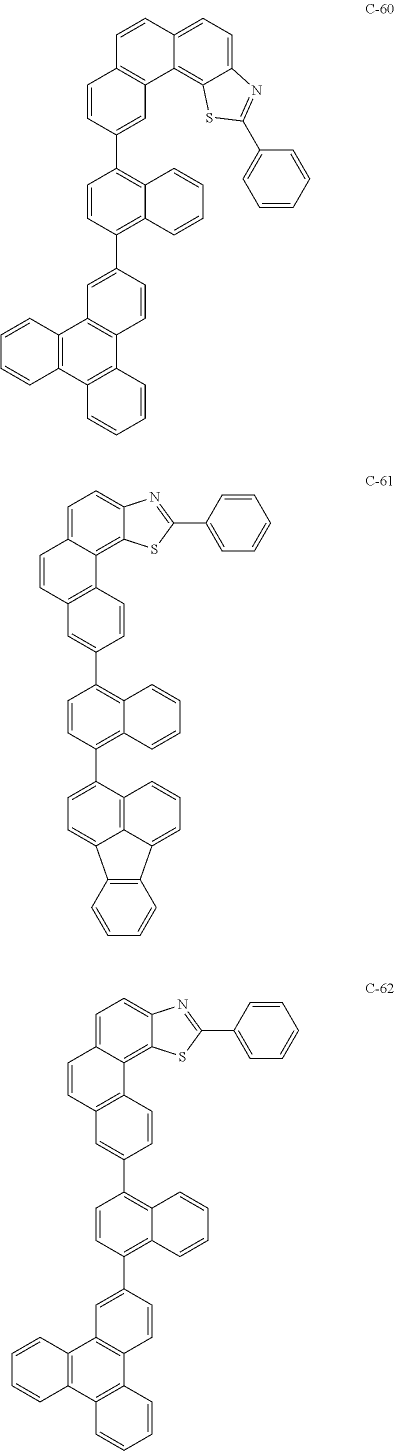 [SMILES: c1ccc(-c2nc3ccc4ccc5ccc(-c6ccc(-c7ccc8c9ccccc9c9ccccc9c8c7)c7ccccc67)cc5c4c3s2)cc1 ; c1ccc(-c2nc3ccc4ccc5cc(-c6ccc(-c7ccc8c9c(cccc79)-c7ccccc7-8)c7ccccc67)ccc5c4c3s2)cc1 ; c1ccc(-c2nc3ccc4ccc5cc(-c6ccc(-c7ccc8c9ccccc9c9ccccc9c8c7)c7ccccc67)ccc5c4c3s2)cc1]

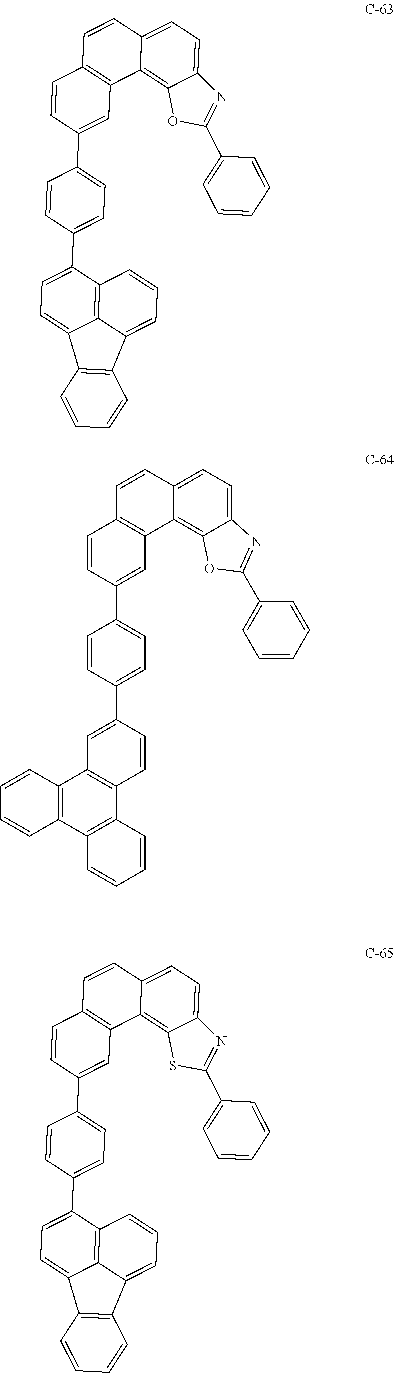 [SMILES: c1ccc(-c2nc3ccc4ccc5ccc(-c6ccc(-c7ccc8c9c(cccc79)-c7ccccc7-8)cc6)cc5c4c3o2)cc1 ; c1ccc(-c2nc3ccc4ccc5ccc(-c6ccc(-c7ccc8c9ccccc9c9ccccc9c8c7)cc6)cc5c4c3o2)cc1 ; c1ccc(-c2nc3ccc4ccc5ccc(-c6ccc(-c7ccc8c9c(cccc79)-c7ccccc7-8)cc6)cc5c4c3s2)cc1]

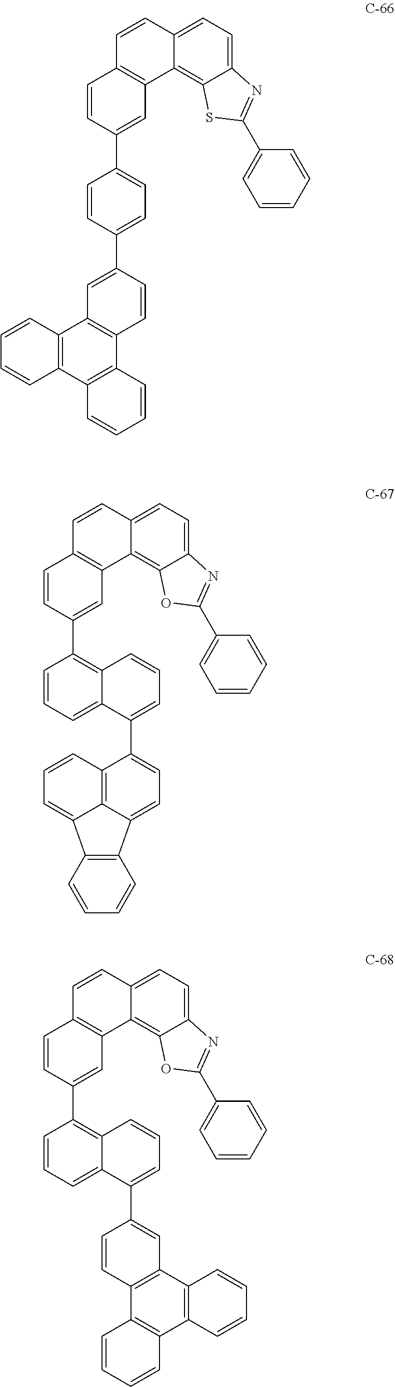 [SMILES: c1ccc(-c2nc3ccc4ccc5ccc(-c6ccc(-c7ccc8c9ccccc9c9ccccc9c8c7)cc6)cc5c4c3s2)cc1 ; c1ccc(-c2nc3ccc4ccc5ccc(-c6cccc7c(-c8ccc9c%10c(cccc8%10)-c8ccccc8-9)cccc67)cc5c4c3o2)cc1 ; c1ccc(-c2nc3ccc4ccc5ccc(-c6cccc7c(-c8ccc9c%10ccccc%10c%10ccccc%10c9c8)cccc67)cc5c4c3o2)cc1]

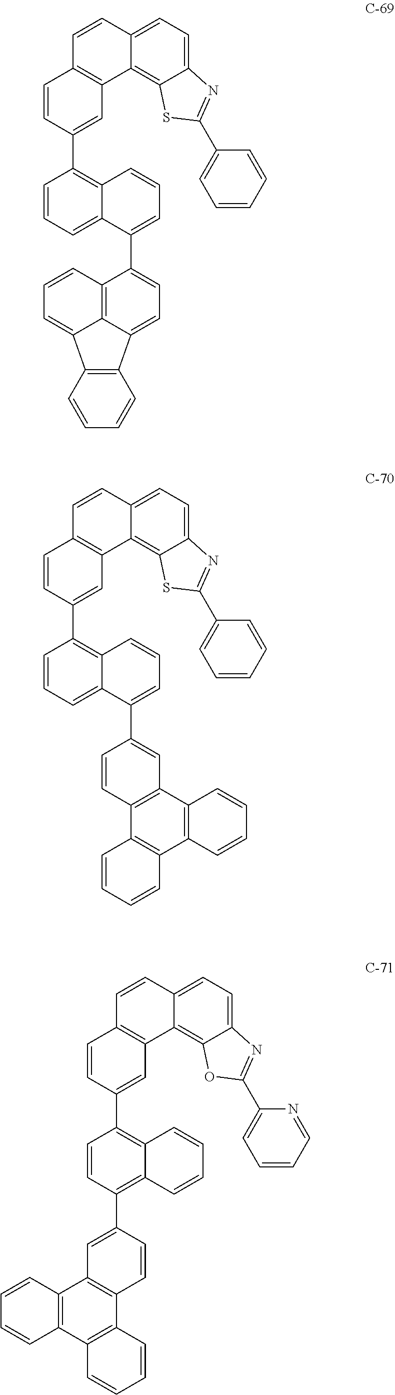 [SMILES: c1ccc(-c2nc3ccc4ccc5ccc(-c6cccc7c(-c8ccc9c%10c(cccc8%10)-c8ccccc8-9)cccc67)cc5c4c3s2)cc1 ; c1ccc(-c2nc3ccc4ccc5ccc(-c6cccc7c(-c8ccc9c%10ccccc%10c%10ccccc%10c9c8)cccc67)cc5c4c3s2)cc1 ; c1ccc(-c2nc3ccc4ccc5ccc(-c6ccc(-c7ccc8c9ccccc9c9ccccc9c8c7)c7ccccc67)cc5c4c3o2)nc1]

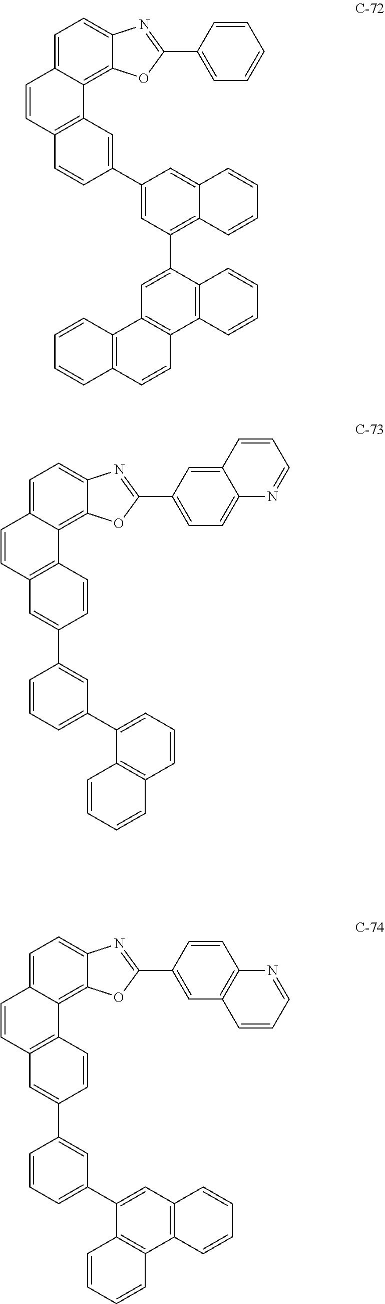 [SMILES: c1ccc(-c2nc3ccc4ccc5ccc(-c6cc(-c7cc8c9ccccc9ccc8c8ccccc78)c7ccccc7c6)cc5c4c3o2)cc1 ; c1cc(-c2ccc3c(ccc4ccc5nc(-c6ccc7ncccc7c6)oc5c43)c2)cc(-c2cccc3ccccc23)c1 ; c1cc(-c2ccc3c(ccc4ccc5nc(-c6ccc7ncccc7c6)oc5c43)c2)cc(-c2cc3ccccc3c3ccccc23)c1]

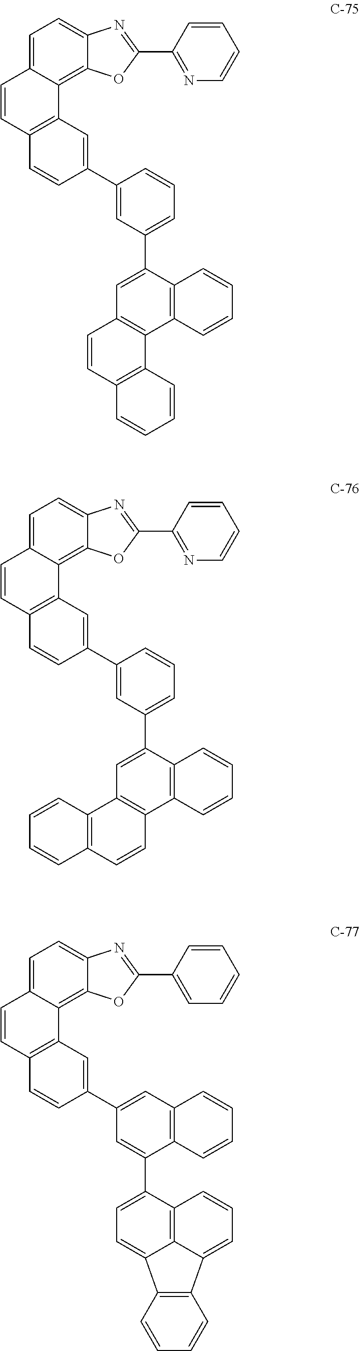 [SMILES: c1ccc(-c2nc3ccc4ccc5ccc(-c6cccc(-c7cc8ccc9ccccc9c8c8ccccc78)c6)cc5c4c3o2)nc1 ; c1ccc(-c2nc3ccc4ccc5ccc(-c6cccc(-c7cc8c9ccccc9ccc8c8ccccc78)c6)cc5c4c3o2)nc1 ; c1ccc(-c2nc3ccc4ccc5ccc(-c6cc(-c7ccc8c9c(cccc79)-c7ccccc7-8)c7ccccc7c6)cc5c4c3o2)cc1]

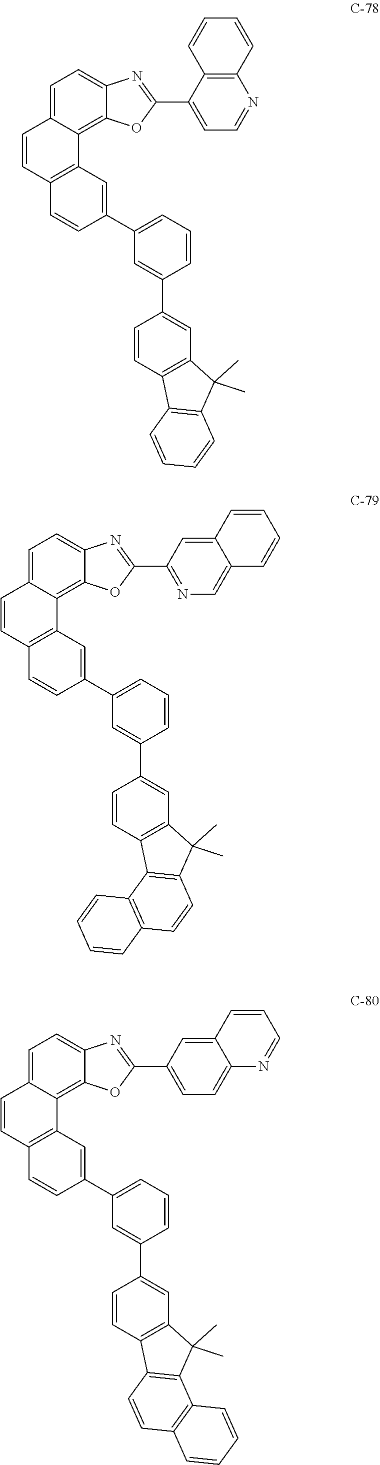 [SMILES: CC1(C)c2ccccc2-c2ccc(-c3cccc(-c4ccc5ccc6ccc7nc(-c8ccnc9ccccc89)oc7c6c5c4)c3)cc21 ; CC1(C)c2cc(-c3cccc(-c4ccc5ccc6ccc7nc(-c8cc9ccccc9cn8)oc7c6c5c4)c3)ccc2-c2c1ccc1ccccc21 ; CC1(C)c2cc(-c3cccc(-c4ccc5ccc6ccc7nc(-c8ccc9ncccc9c8)oc7c6c5c4)c3)ccc2-c2ccc3ccccc3c21]

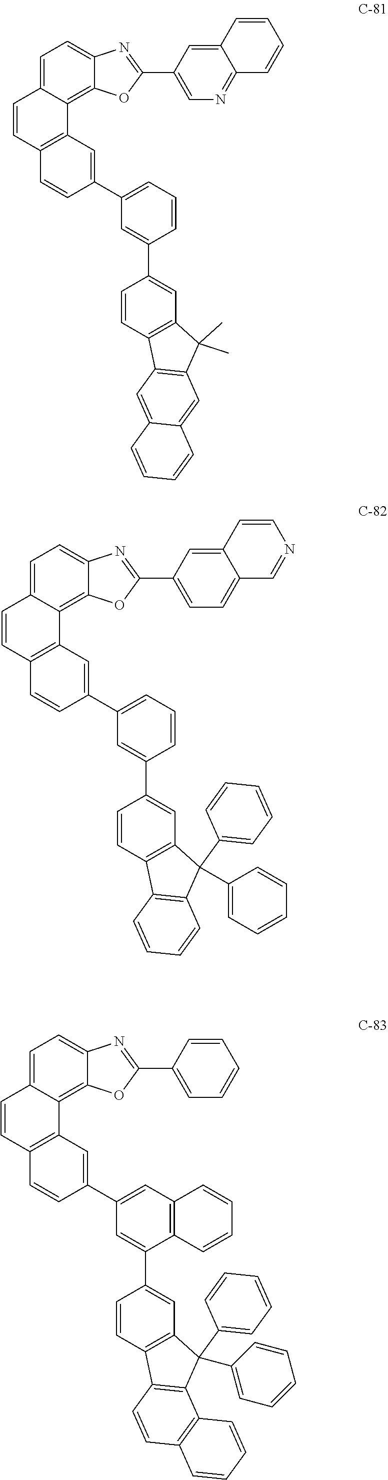 [SMILES: CC1(C)c2cc(-c3cccc(-c4ccc5ccc6ccc7nc(-c8cnc9ccccc9c8)oc7c6c5c4)c3)ccc2-c2cc3ccccc3cc21 ; c1ccc(C2(c3ccccc3)c3ccccc3-c3ccc(-c4cccc(-c5ccc6ccc7ccc8nc(-c9ccc%10cnccc%10c9)oc8c7c6c5)c4)cc32)cc1 ; c1ccc(-c2nc3ccc4ccc5ccc(-c6cc(-c7ccc8c(c7)C(c7ccccc7)(c7ccccc7)c7c-8ccc8ccccc78)c7ccccc7c6)cc5c4c3o2)cc1]

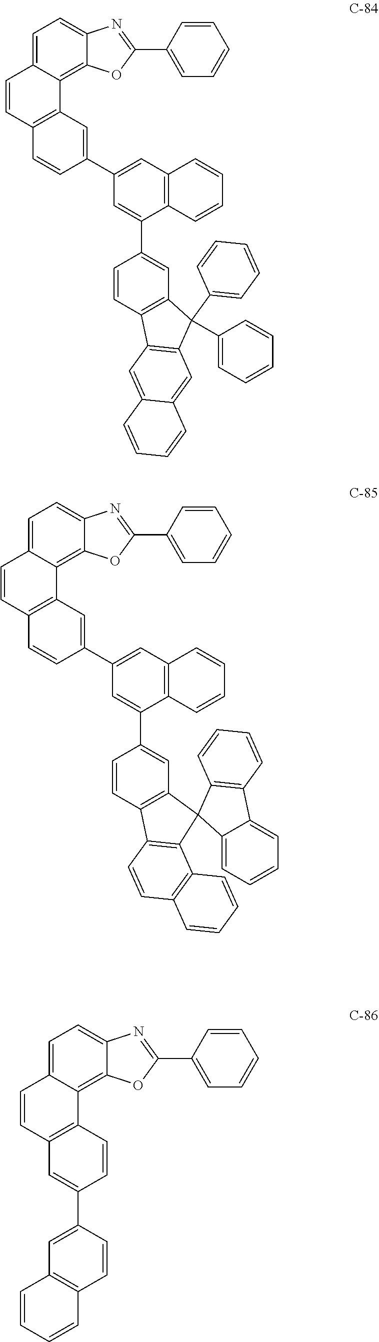 [SMILES: c1ccc(-c2nc3ccc4ccc5ccc(-c6cc(-c7ccc8c(c7)C(c7ccccc7)(c7ccccc7)c7cc9ccccc9cc7-8)c7ccccc7c6)cc5c4c3o2)cc1 ; c1ccc(-c2nc3ccc4ccc5ccc(-c6cc(-c7ccc8c(c7)C7(c9ccccc9-c9ccccc97)c7c-8ccc8ccccc78)c7ccccc7c6)cc5c4c3o2)cc1 ; c1ccc(-c2nc3ccc4ccc5cc(-c6ccc7ccccc7c6)ccc5c4c3o2)cc1]

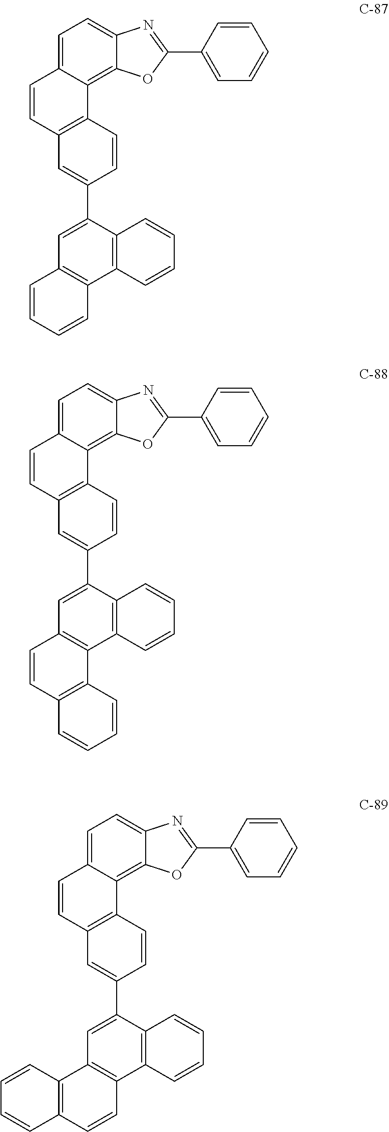 [SMILES: c1ccc(-c2nc3ccc4ccc5cc(-c6cc7ccccc7c7ccccc67)ccc5c4c3o2)cc1 ; c1ccc(-c2nc3ccc4ccc5cc(-c6cc7ccc8ccccc8c7c7ccccc67)ccc5c4c3o2)cc1 ; c1ccc(-c2nc3ccc4ccc5cc(-c6cc7c8ccccc8ccc7c7ccccc67)ccc5c4c3o2)cc1]

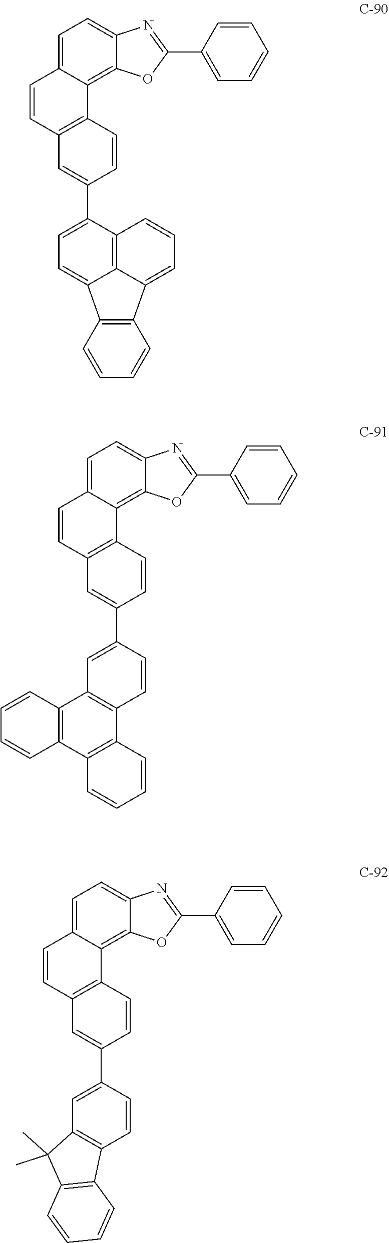 [SMILES: c1ccc(-c2nc3ccc4ccc5cc(-c6ccc7c8c(cccc68)-c6ccccc6-7)ccc5c4c3o2)cc1 ; c1ccc(-c2nc3ccc4ccc5cc(-c6ccc7c8ccccc8c8ccccc8c7c6)ccc5c4c3o2)cc1 ; CC1(C)c2ccccc2-c2ccc(-c3ccc4c(ccc5ccc6nc(-c7ccccc7)oc6c54)c3)cc21]

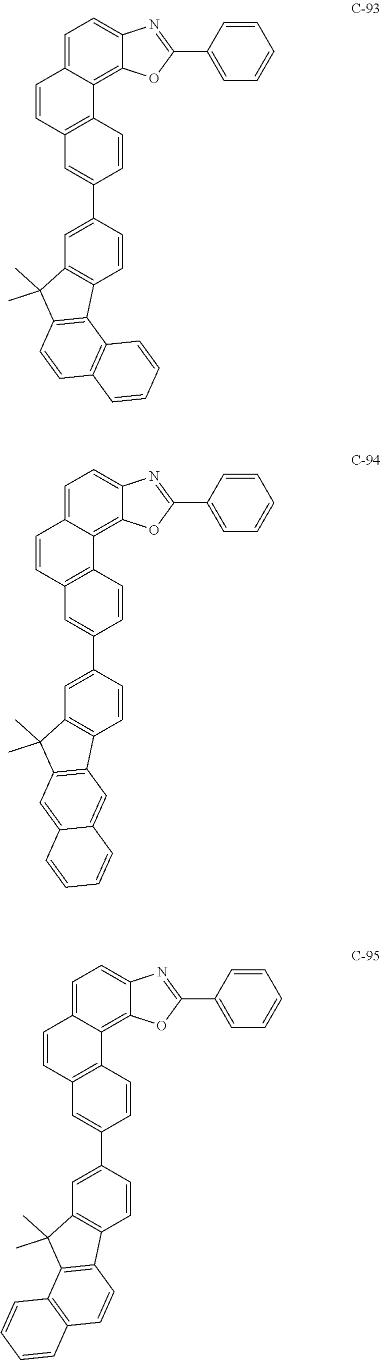 [SMILES: CC1(C)c2cc(-c3ccc4c(ccc5ccc6nc(-c7ccccc7)oc6c54)c3)ccc2-c2c1ccc1ccccc21 ; CC1(C)c2cc(-c3ccc4c(ccc5ccc6nc(-c7ccccc7)oc6c54)c3)ccc2-c2cc3ccccc3cc21 ; CC1(C)c2cc(-c3ccc4c(ccc5ccc6nc(-c7ccccc7)oc6c54)c3)ccc2-c2ccc3ccccc3c21]

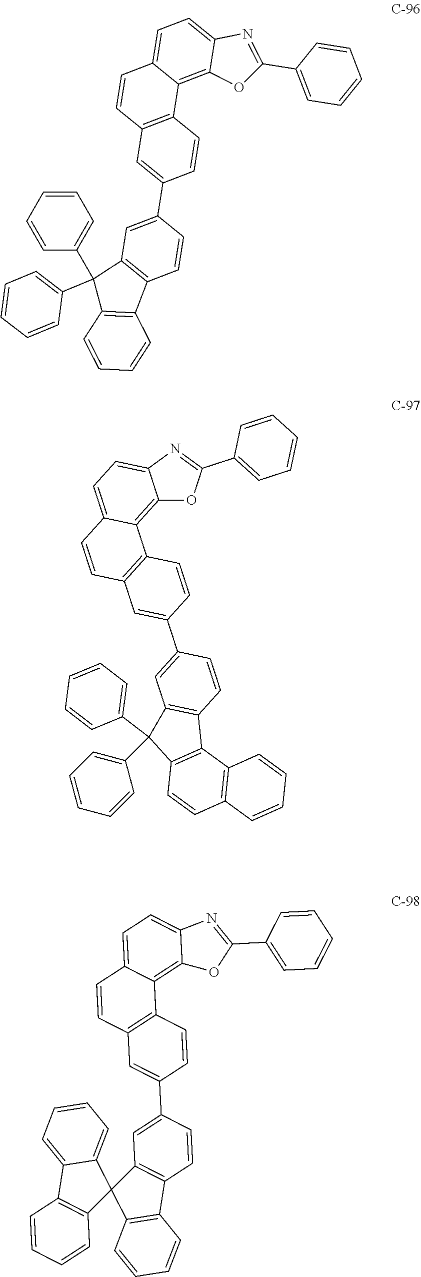 [SMILES: c1ccc(-c2nc3ccc4ccc5cc(-c6ccc7c(c6)C(c6ccccc6)(c6ccccc6)c6ccccc6-7)ccc5c4c3o2)cc1 ; c1ccc(-c2nc3ccc4ccc5cc(-c6ccc7c(c6)C(c6ccccc6)(c6ccccc6)c6ccc8ccccc8c6-7)ccc5c4c3o2)cc1 ; c1ccc(-c2nc3ccc4ccc5cc(-c6ccc7c(c6)C6(c8ccccc8-c8ccccc86)c6ccccc6-7)ccc5c4c3o2)cc1]

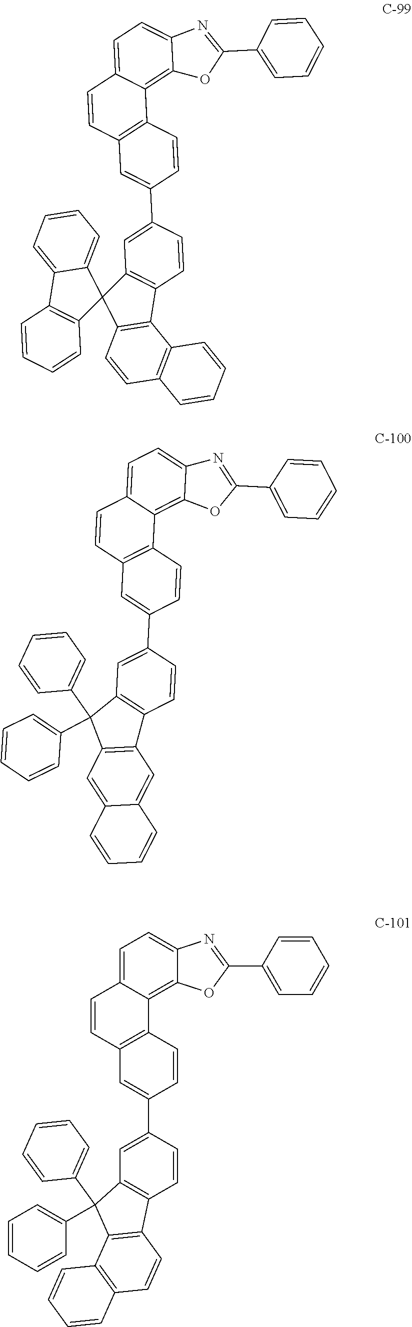 [SMILES: c1ccc(-c2nc3ccc4ccc5cc(-c6ccc7c(c6)C6(c8ccccc8-c8ccccc86)c6ccc8ccccc8c6-7)ccc5c4c3o2)cc1 ; c1ccc(-c2nc3ccc4ccc5cc(-c6ccc7c(c6)C(c6ccccc6)(c6ccccc6)c6cc8ccccc8cc6-7)ccc5c4c3o2)cc1 ; c1ccc(-c2nc3ccc4ccc5cc(-c6ccc7c(c6)C(c6ccccc6)(c6ccccc6)c6c-7ccc7ccccc67)ccc5c4c3o2)cc1]

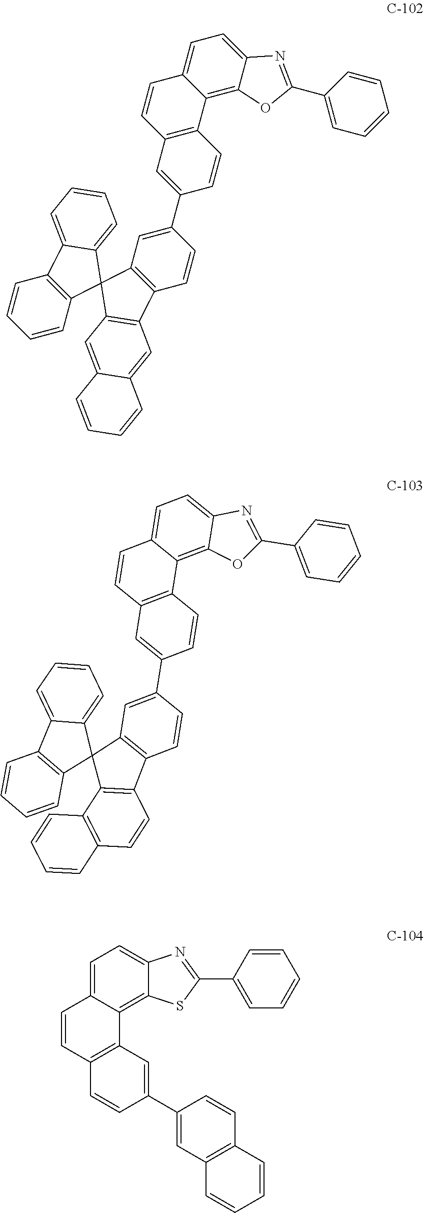 [SMILES: c1ccc(-c2nc3ccc4ccc5cc(-c6ccc7c(c6)C6(c8ccccc8-c8ccccc86)c6cc8ccccc8cc6-7)ccc5c4c3o2)cc1 ; c1ccc(-c2nc3ccc4ccc5cc(-c6ccc7c(c6)C6(c8ccccc8-c8ccccc86)c6c-7ccc7ccccc67)ccc5c4c3o2)cc1 ; c1ccc(-c2nc3ccc4ccc5ccc(-c6ccc7ccccc7c6)cc5c4c3s2)cc1]

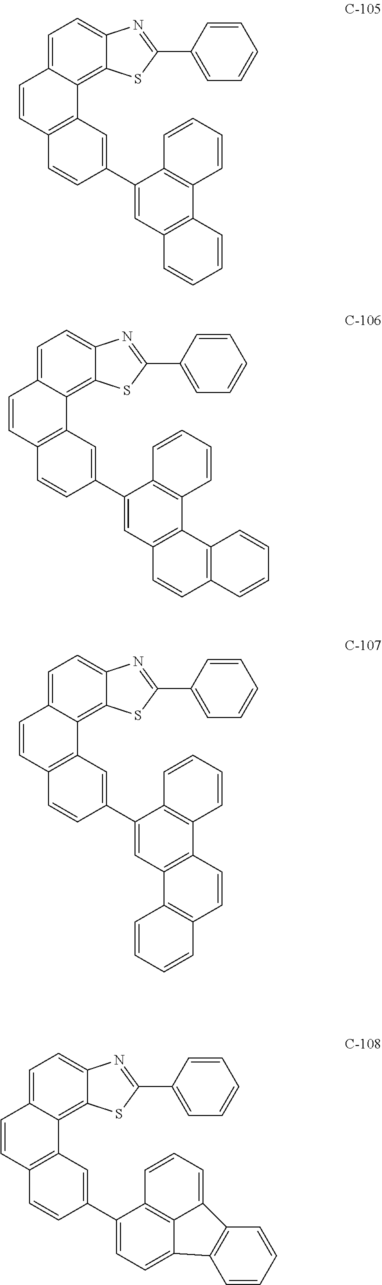 [SMILES: c1ccc(-c2nc3ccc4ccc5ccc(-c6cc7ccccc7c7ccccc67)cc5c4c3s2)cc1 ; c1ccc(-c2nc3ccc4ccc5ccc(-c6cc7ccc8ccccc8c7c7ccccc67)cc5c4c3s2)cc1 ; c1ccc(-c2nc3ccc4ccc5ccc(-c6cc7c8ccccc8ccc7c7ccccc67)cc5c4c3s2)cc1 ; c1ccc(-c2nc3ccc4ccc5ccc(-c6ccc7c8c(cccc68)-c6ccccc6-7)cc5c4c3s2)cc1]

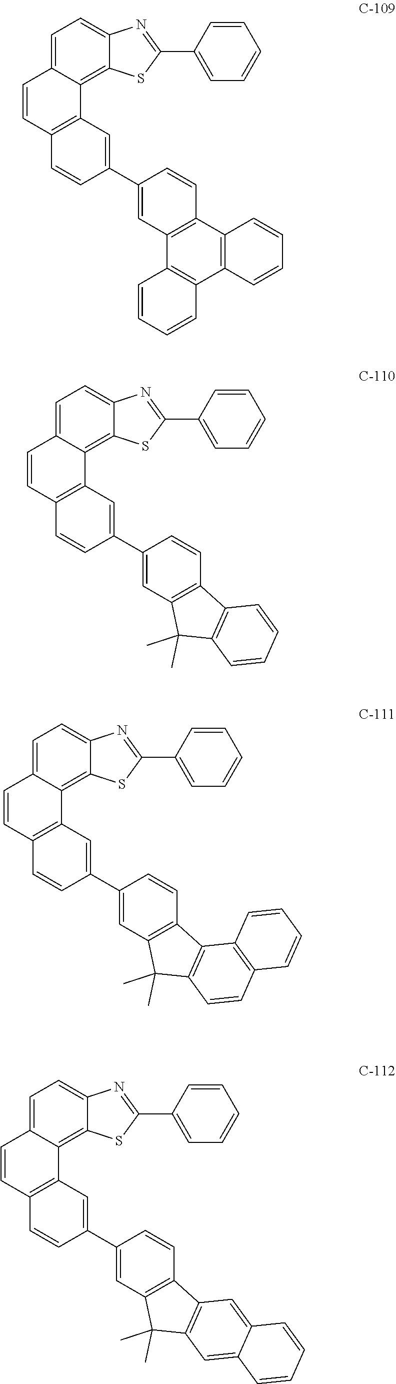 [SMILES: c1ccc(-c2nc3ccc4ccc5ccc(-c6ccc7c8ccccc8c8ccccc8c7c6)cc5c4c3s2)cc1 ; CC1(C)c2ccccc2-c2ccc(-c3ccc4ccc5ccc6nc(-c7ccccc7)sc6c5c4c3)cc21 ; CC1(C)c2cc(-c3ccc4ccc5ccc6nc(-c7ccccc7)sc6c5c4c3)ccc2-c2c1ccc1ccccc21 ; CC1(C)c2cc(-c3ccc4ccc5ccc6nc(-c7ccccc7)sc6c5c4c3)ccc2-c2cc3ccccc3cc21]

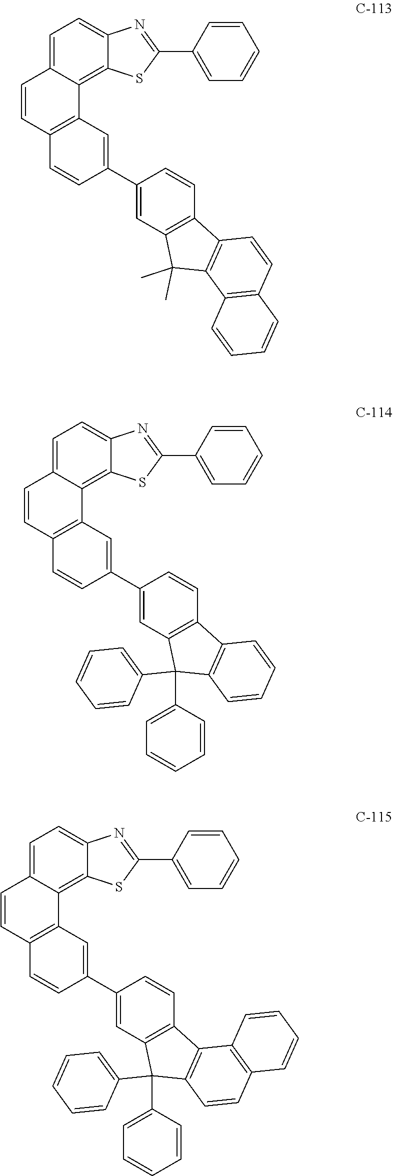 [SMILES: CC1(C)c2cc(-c3ccc4ccc5ccc6nc(-c7ccccc7)sc6c5c4c3)ccc2-c2ccc3ccccc3c21 ; c1ccc(-c2nc3ccc4ccc5ccc(-c6ccc7c(c6)C(c6ccccc6)(c6ccccc6)c6ccccc6-7)cc5c4c3s2)cc1 ; c1ccc(-c2nc3ccc4ccc5ccc(-c6ccc7c(c6)C(c6ccccc6)(c6ccccc6)c6ccc8ccccc8c6-7)cc5c4c3s2)cc1]

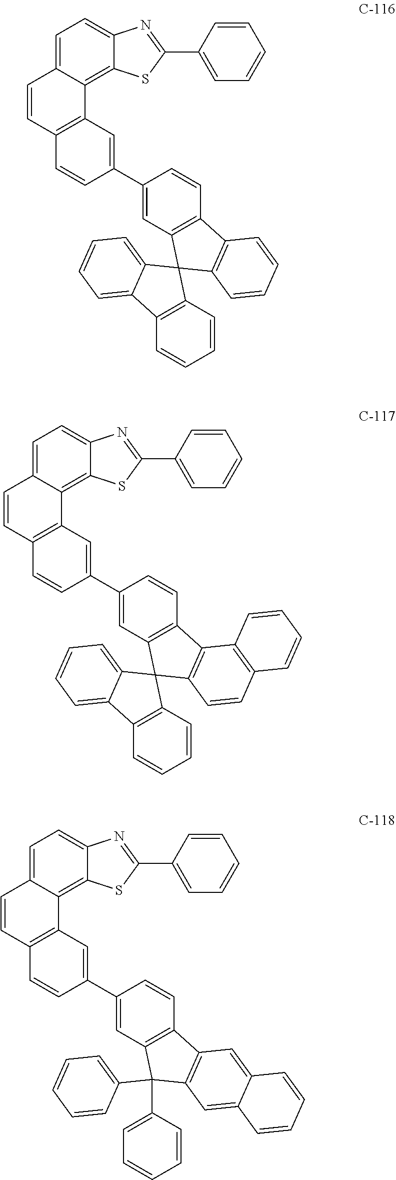 [SMILES: c1ccc(-c2nc3ccc4ccc5ccc(-c6ccc7c(c6)C6(c8ccccc8-c8ccccc86)c6ccccc6-7)cc5c4c3s2)cc1 ; c1ccc(-c2nc3ccc4ccc5ccc(-c6ccc7c(c6)C6(c8ccccc8-c8ccccc86)c6ccc8ccccc8c6-7)cc5c4c3s2)cc1 ; c1ccc(-c2nc3ccc4ccc5ccc(-c6ccc7c(c6)C(c6ccccc6)(c6ccccc6)c6cc8ccccc8cc6-7)cc5c4c3s2)cc1]

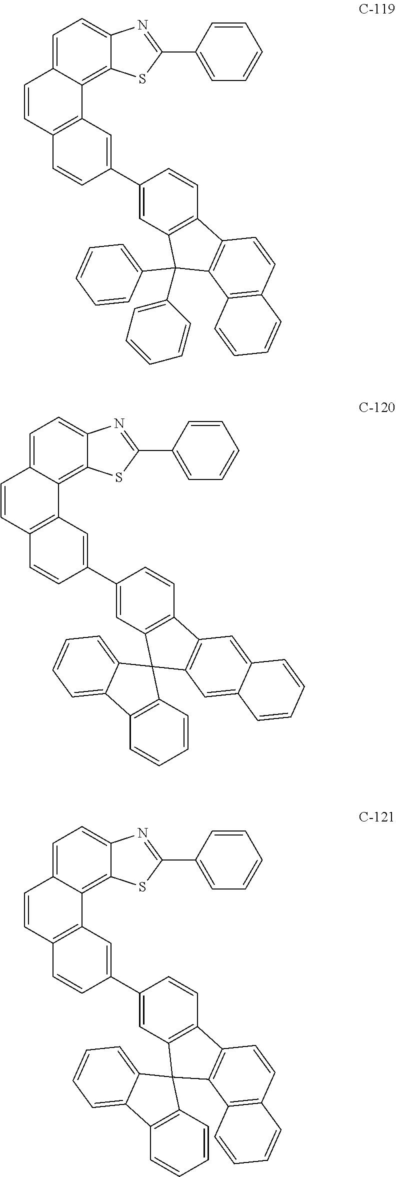 [SMILES: c1ccc(-c2nc3ccc4ccc5ccc(-c6ccc7c(c6)C(c6ccccc6)(c6ccccc6)c6c-7ccc7ccccc67)cc5c4c3s2)cc1 ; c1ccc(-c2nc3ccc4ccc5ccc(-c6ccc7c(c6)C6(c8ccccc8-c8ccccc86)c6cc8ccccc8cc6-7)cc5c4c3s2)cc1 ; c1ccc(-c2nc3ccc4ccc5ccc(-c6ccc7c(c6)C6(c8ccccc8-c8ccccc86)c6c-7ccc7ccccc67)cc5c4c3s2)cc1]

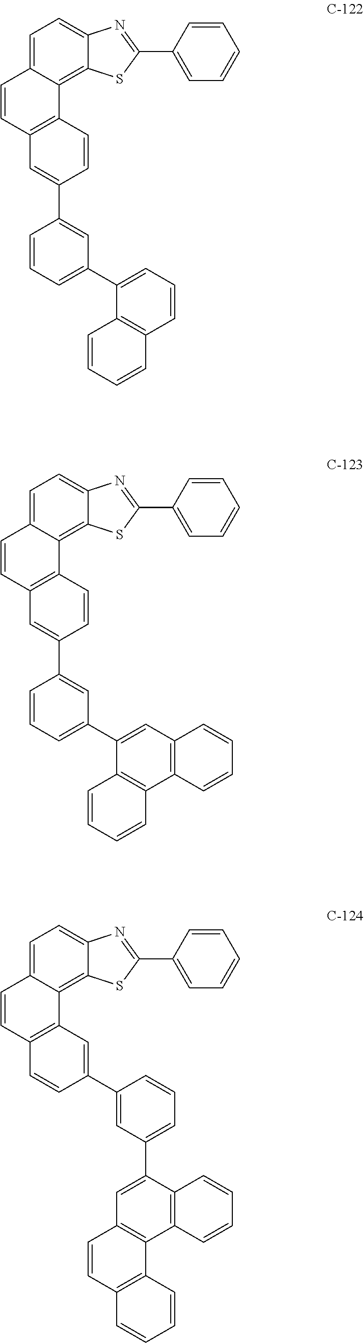 [SMILES: c1ccc(-c2nc3ccc4ccc5cc(-c6cccc(-c7cccc8ccccc78)c6)ccc5c4c3s2)cc1 ; c1ccc(-c2nc3ccc4ccc5cc(-c6cccc(-c7cc8ccccc8c8ccccc78)c6)ccc5c4c3s2)cc1 ; c1ccc(-c2nc3ccc4ccc5ccc(-c6cccc(-c7cc8ccc9ccccc9c8c8ccccc78)c6)cc5c4c3s2)cc1]

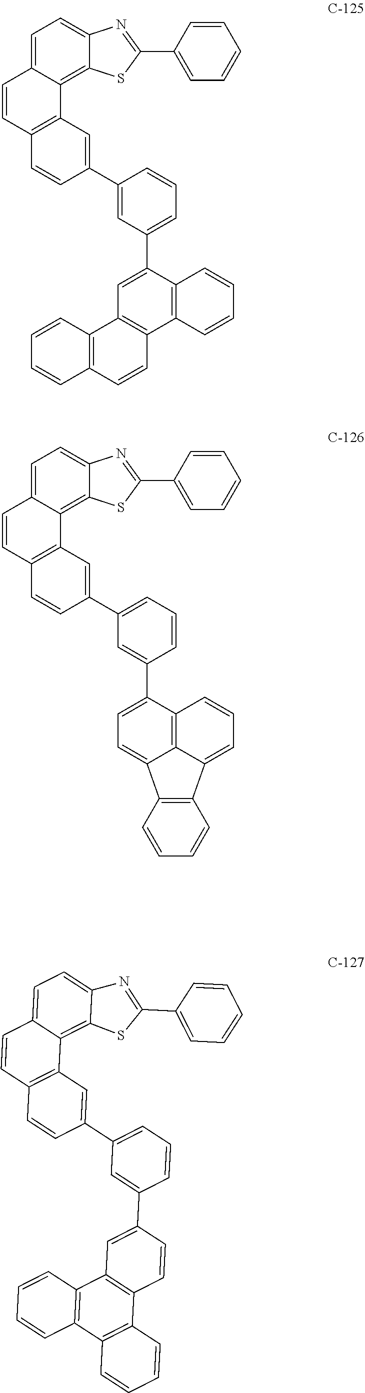 [SMILES: c1ccc(-c2nc3ccc4ccc5ccc(-c6cccc(-c7cc8c9ccccc9ccc8c8ccccc78)c6)cc5c4c3s2)cc1 ; c1ccc(-c2nc3ccc4ccc5ccc(-c6cccc(-c7ccc8c9c(cccc79)-c7ccccc7-8)c6)cc5c4c3s2)cc1 ; c1ccc(-c2nc3ccc4ccc5ccc(-c6cccc(-c7ccc8c9ccccc9c9ccccc9c8c7)c6)cc5c4c3s2)cc1]

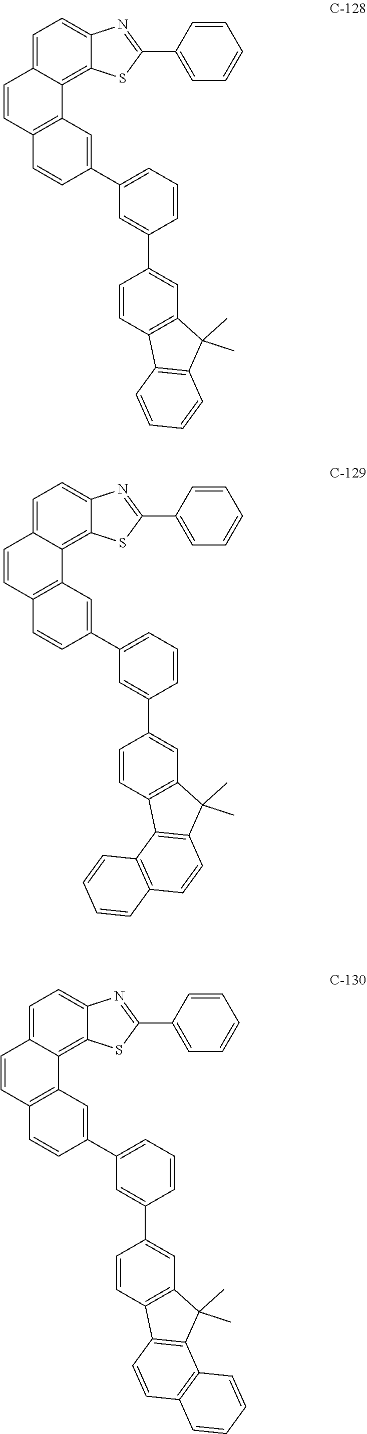 [SMILES: CC1(C)c2ccccc2-c2ccc(-c3cccc(-c4ccc5ccc6ccc7nc(-c8ccccc8)sc7c6c5c4)c3)cc21 ; CC1(C)c2cc(-c3cccc(-c4ccc5ccc6ccc7nc(-c8ccccc8)sc7c6c5c4)c3)ccc2-c2c1ccc1ccccc21 ; CC1(C)c2cc(-c3cccc(-c4ccc5ccc6ccc7nc(-c8ccccc8)sc7c6c5c4)c3)ccc2-c2ccc3ccccc3c21]

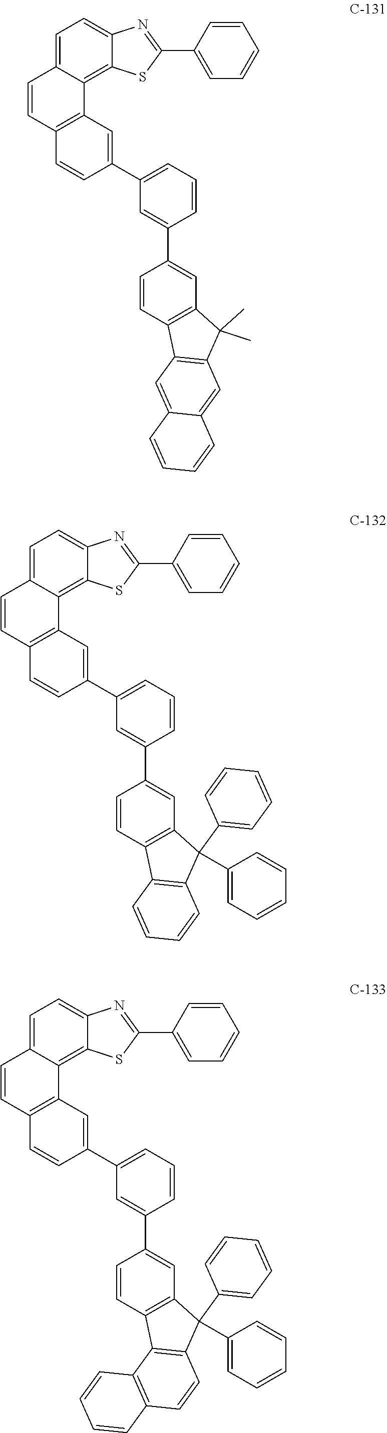 [SMILES: CC1(C)c2cc(-c3cccc(-c4ccc5ccc6ccc7nc(-c8ccccc8)sc7c6c5c4)c3)ccc2-c2cc3ccccc3cc21 ; c1ccc(-c2nc3ccc4ccc5ccc(-c6cccc(-c7ccc8c(c7)C(c7ccccc7)(c7ccccc7)c7ccccc7-8)c6)cc5c4c3s2)cc1 ; c1ccc(-c2nc3ccc4ccc5ccc(-c6cccc(-c7ccc8c(c7)C(c7ccccc7)(c7ccccc7)c7ccc9ccccc9c7-8)c6)cc5c4c3s2)cc1]

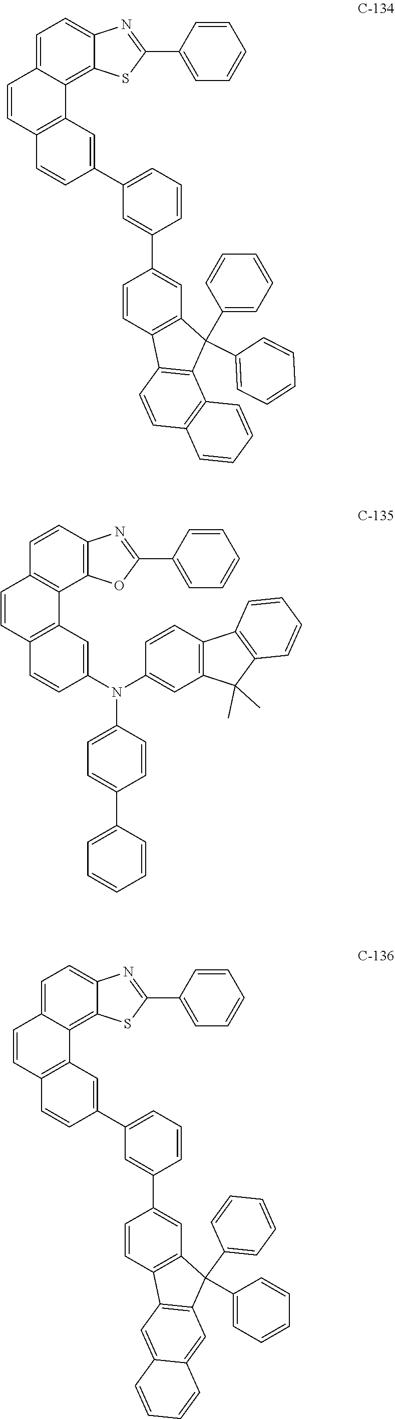 [SMILES: c1ccc(-c2nc3ccc4ccc5ccc(-c6cccc(-c7ccc8c(c7)C(c7ccccc7)(c7ccccc7)c7c-8ccc8ccccc78)c6)cc5c4c3s2)cc1 ; CC1(C)c2ccccc2-c2ccc(N(c3ccc(-c4ccccc4)cc3)c3ccc4ccc5ccc6nc(-c7ccccc7)oc6c5c4c3)cc21 ; c1ccc(-c2nc3ccc4ccc5ccc(-c6cccc(-c7ccc8c(c7)C(c7ccccc7)(c7ccccc7)c7cc9ccccc9cc7-8)c6)cc5c4c3s2)cc1]

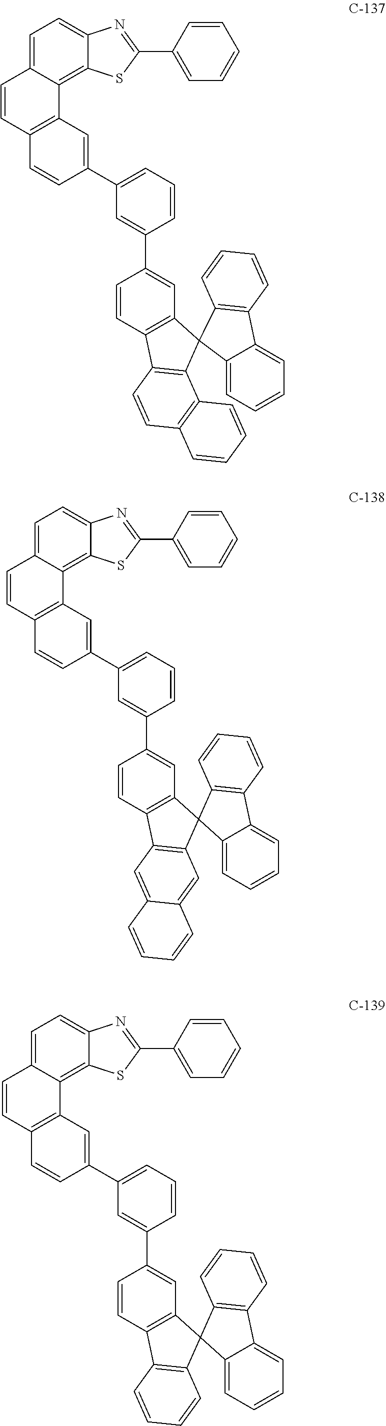 [SMILES: c1ccc(-c2nc3ccc4ccc5ccc(-c6cccc(-c7ccc8c(c7)C7(c9ccccc9-c9ccccc97)c7c-8ccc8ccccc78)c6)cc5c4c3s2)cc1 ; c1ccc(-c2nc3ccc4ccc5ccc(-c6cccc(-c7ccc8c(c7)C7(c9ccccc9-c9ccccc97)c7cc9ccccc9cc7-8)c6)cc5c4c3s2)cc1 ; c1ccc(-c2nc3ccc4ccc5ccc(-c6cccc(-c7ccc8c(c7)C7(c9ccccc9-c9ccccc97)c7ccccc7-8)c6)cc5c4c3s2)cc1]

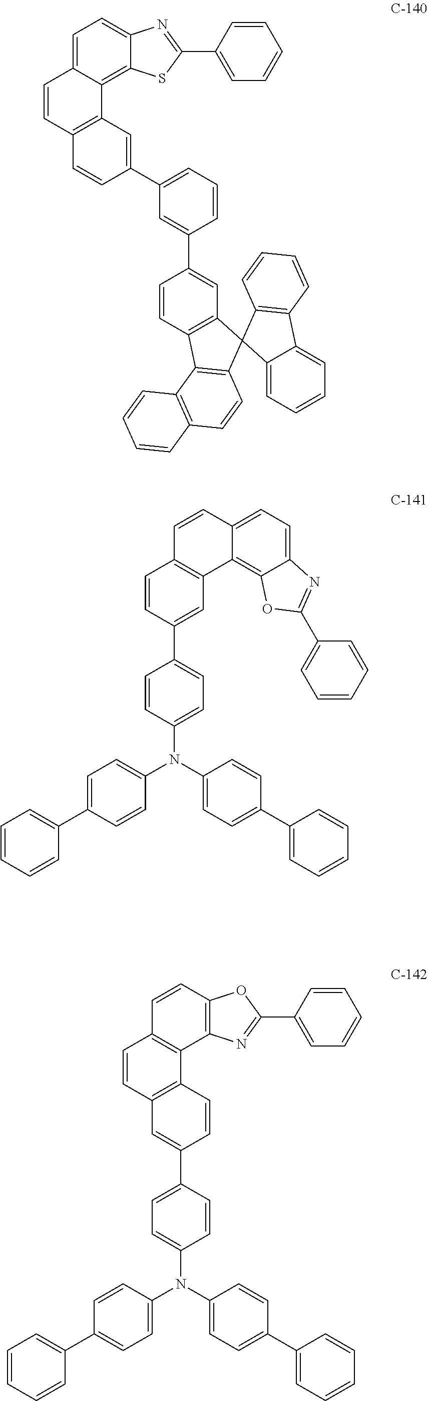 [SMILES: c1ccc(-c2nc3ccc4ccc5ccc(-c6cccc(-c7ccc8c(c7)C7(c9ccccc9-c9ccccc97)c7ccc9ccccc9c7-8)c6)cc5c4c3s2)cc1 ; c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2ccc(N(c3ccc(-c4ccccc4)cc3)c3ccc(-c4ccc5c(ccc6ccc7oc(-c8ccccc8)nc7c65)c4)cc3)cc2)cc1]

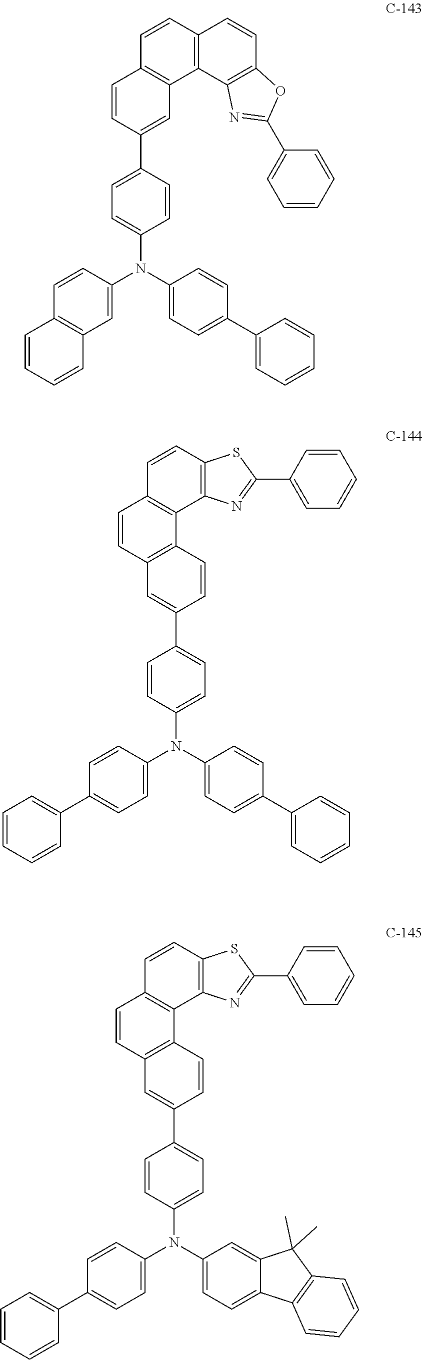 [SMILES: c1ccc(-c2ccc(N(c3ccc(-c4ccc5ccc6ccc7oc(-c8ccccc8)nc7c6c5c4)cc3)c3ccc4ccccc4c3)cc2)cc1 ; c1ccc(-c2ccc(N(c3ccc(-c4ccccc4)cc3)c3ccc(-c4ccc5c(ccc6ccc7sc(-c8ccccc8)nc7c65)c4)cc3)cc2)cc1 ; CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21]

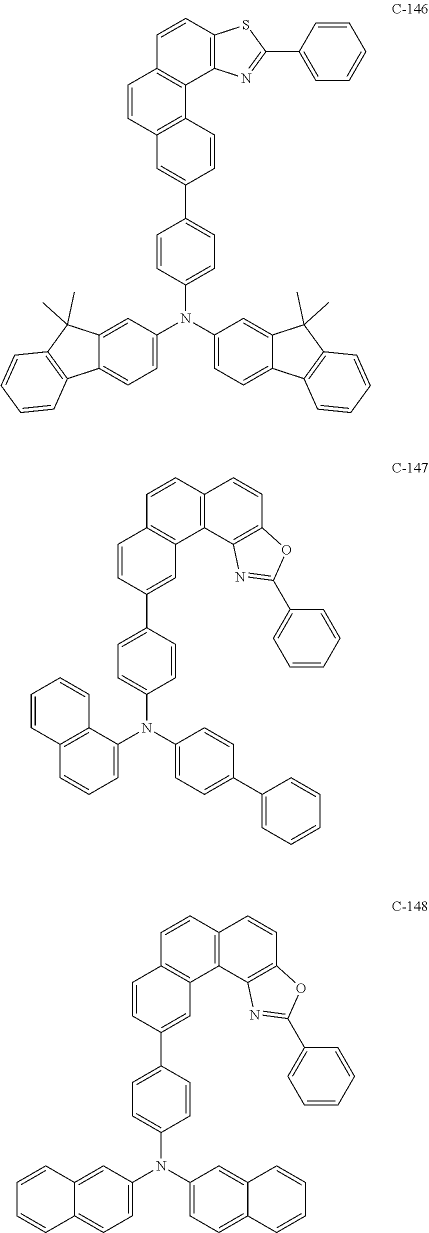 [SMILES: CC1(C)c2ccccc2-c2ccc(N(c3ccc(-c4ccc5c(ccc6ccc7sc(-c8ccccc8)nc7c65)c4)cc3)c3ccc4c(c3)C(C)(C)c3ccccc3-4)cc21 ; c1ccc(-c2ccc(N(c3ccc(-c4ccc5ccc6ccc7oc(-c8ccccc8)nc7c6c5c4)cc3)c3cccc4ccccc34)cc2)cc1 ; c1ccc(-c2nc3c(ccc4ccc5ccc(-c6ccc(N(c7ccc8ccccc8c7)c7ccc8ccccc8c7)cc6)cc5c43)o2)cc1]

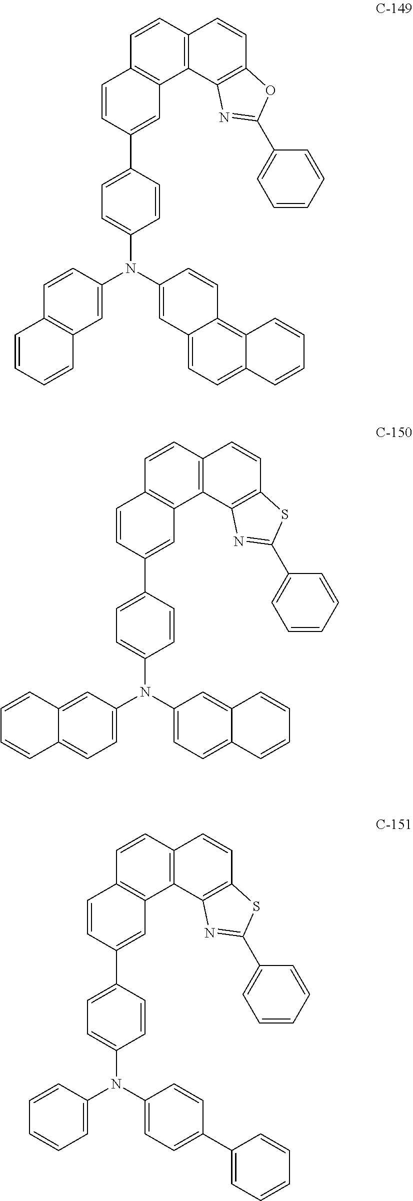 [SMILES: c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2nc3c(ccc4ccc5ccc(-c6ccc(N(c7ccc8ccccc8c7)c7ccc8ccccc8c7)cc6)cc5c43)s2)cc1 ; c1ccc(-c2ccc(N(c3ccccc3)c3ccc(-c4ccc5ccc6ccc7sc(-c8ccccc8)nc7c6c5c4)cc3)cc2)cc1]

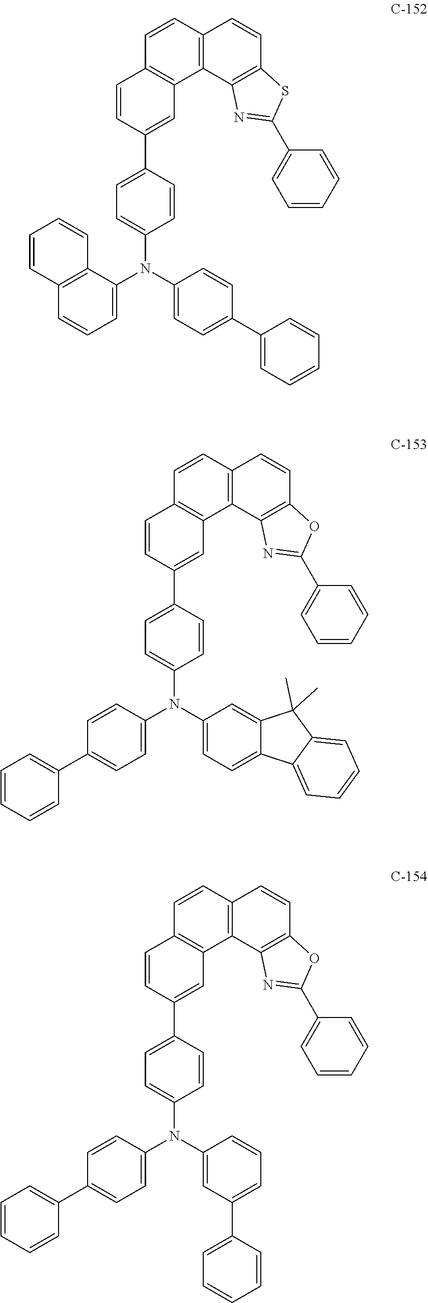 [SMILES: c1ccc(-c2ccc(N(c3ccc(-c4ccc5ccc6ccc7sc(-c8ccccc8)nc7c6c5c4)cc3)c3cccc4ccccc34)cc2)cc1 ; CC1(C)c2ccccc2-c2ccc(N(c3ccc(-c4ccccc4)cc3)c3ccc(-c4ccc5ccc6ccc7oc(-c8ccccc8)nc7c6c5c4)cc3)cc21 ; c1ccc(-c2ccc(N(c3ccc(-c4ccc5ccc6ccc7oc(-c8ccccc8)nc7c6c5c4)cc3)c3cccc(-c4ccccc4)c3)cc2)cc1]

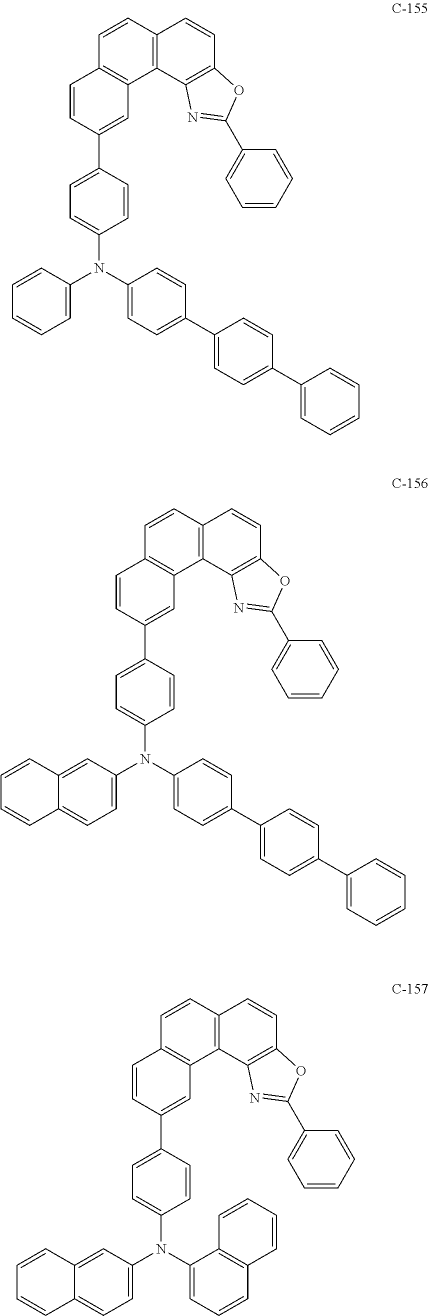 [SMILES: c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5ccc(-c6ccc(N(c7ccc8ccccc8c7)c7cccc8ccccc78)cc6)cc5c43)o2)cc1]

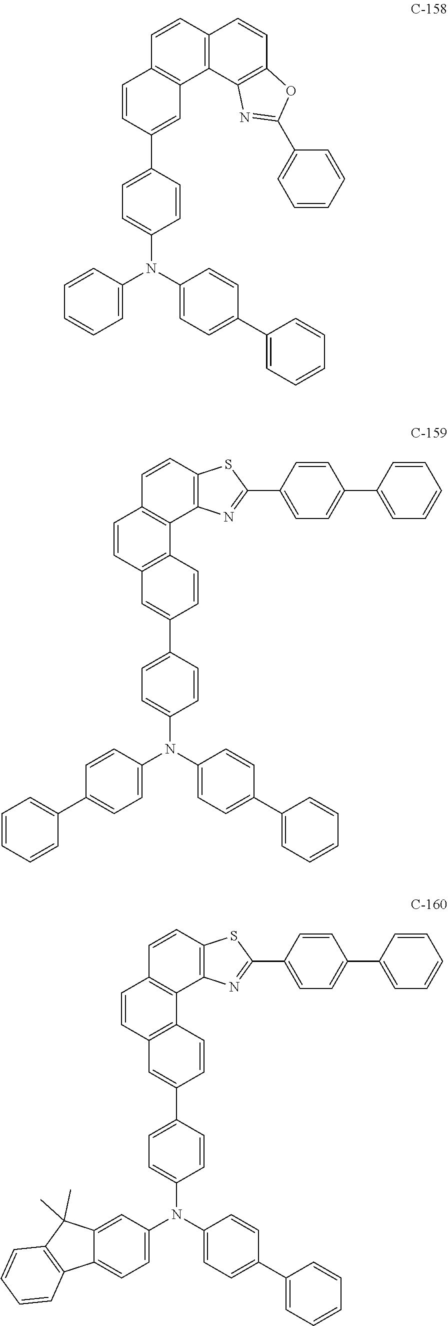 [SMILES: c1ccc(-c2ccc(N(c3ccccc3)c3ccc(-c4ccc5ccc6ccc7oc(-c8ccccc8)nc7c6c5c4)cc3)cc2)cc1 ; c1ccc(-c2ccc(-c3nc4c(ccc5ccc6cc(-c7ccc(N(c8ccc(-c9ccccc9)cc8)c8ccc(-c9ccccc9)cc8)cc7)ccc6c54)s3)cc2)cc1 ; CC1(C)c2ccccc2-c2ccc(N(c3ccc(-c4ccccc4)cc3)c3ccc(-c4ccc5c(ccc6ccc7sc(-c8ccc(-c9ccccc9)cc8)nc7c65)c4)cc3)cc21]

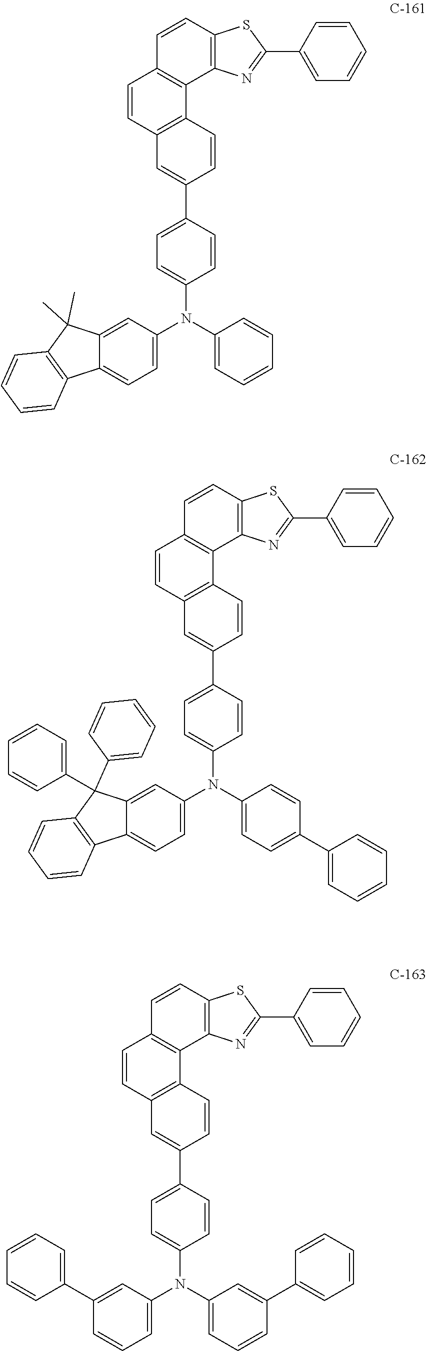 [SMILES: CC1(C)c2ccccc2-c2ccc(N(c3ccccc3)c3ccc(-c4ccc5c(ccc6ccc7sc(-c8ccccc8)nc7c65)c4)cc3)cc21 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1 ; c1ccc(-c2cccc(N(c3ccc(-c4ccc5c(ccc6ccc7sc(-c8ccccc8)nc7c65)c4)cc3)c3cccc(-c4ccccc4)c3)c2)cc1]

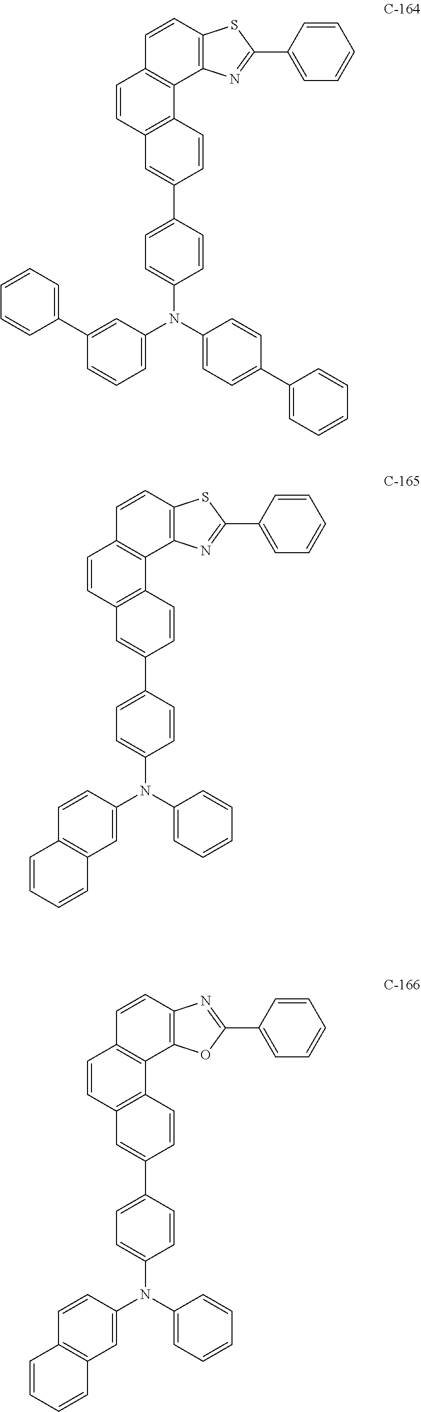 [SMILES: c1ccc(-c2ccc(N(c3ccc(-c4ccc5c(ccc6ccc7sc(-c8ccccc8)nc7c65)c4)cc3)c3cccc(-c4ccccc4)c3)cc2)cc1 ; c1ccc(-c2nc3c(ccc4ccc5cc(-c6ccc(N(c7ccccc7)c7ccc8ccccc8c7)cc6)ccc5c43)s2)cc1 ; c1ccc(-c2nc3ccc4ccc5cc(-c6ccc(N(c7ccccc7)c7ccc8ccccc8c7)cc6)ccc5c4c3o2)cc1]

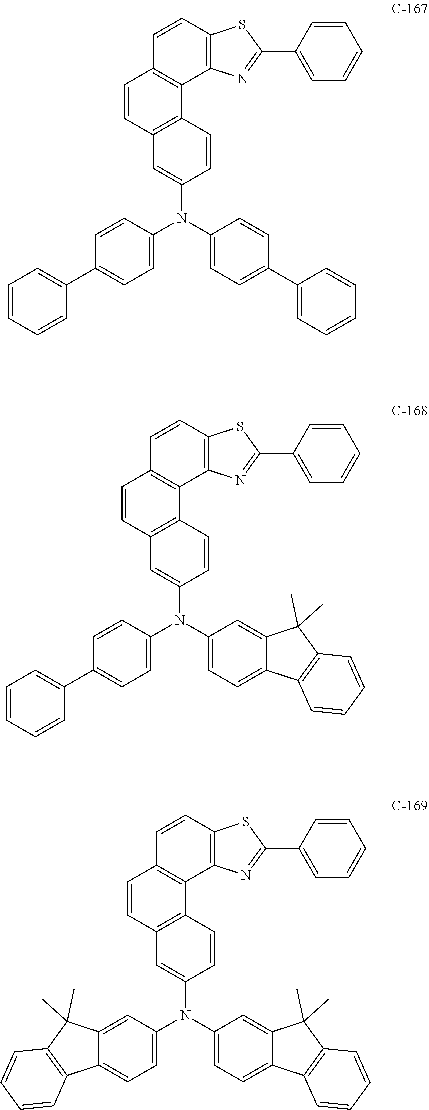 [SMILES: c1ccc(-c2ccc(N(c3ccc(-c4ccccc4)cc3)c3ccc4c(ccc5ccc6sc(-c7ccccc7)nc6c54)c3)cc2)cc1 ; CC1(C)c2ccccc2-c2ccc(N(c3ccc(-c4ccccc4)cc3)c3ccc4c(ccc5ccc6sc(-c7ccccc7)nc6c54)c3)cc21 ; CC1(C)c2ccccc2-c2ccc(N(c3ccc4c(c3)C(C)(C)c3ccccc3-4)c3ccc4c(ccc5ccc6sc(-c7ccccc7)nc6c54)c3)cc21]

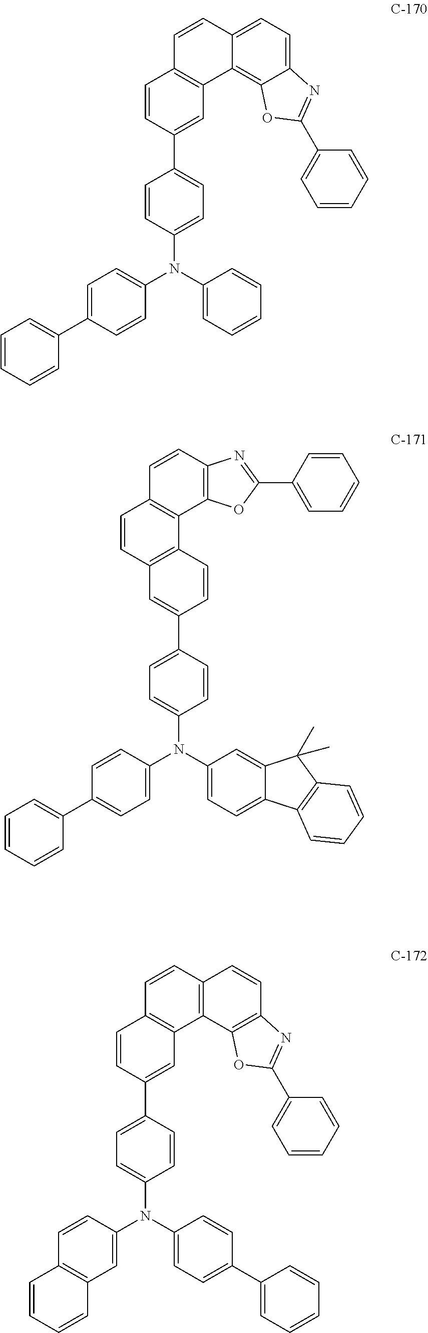 [SMILES: c1ccc(-c2ccc(N(c3ccccc3)c3ccc(-c4ccc5ccc6ccc7nc(-c8ccccc8)oc7c6c5c4)cc3)cc2)cc1 ; CC1(C)c2ccccc2-c2ccc(N(c3ccc(-c4ccccc4)cc3)c3ccc(-c4ccc5c(ccc6ccc7nc(-c8ccccc8)oc7c65)c4)cc3)cc21 ; c1ccc(-c2ccc(N(c3ccc(-c4ccc5ccc6ccc7nc(-c8ccccc8)oc7c6c5c4)cc3)c3ccc4ccccc4c3)cc2)cc1]

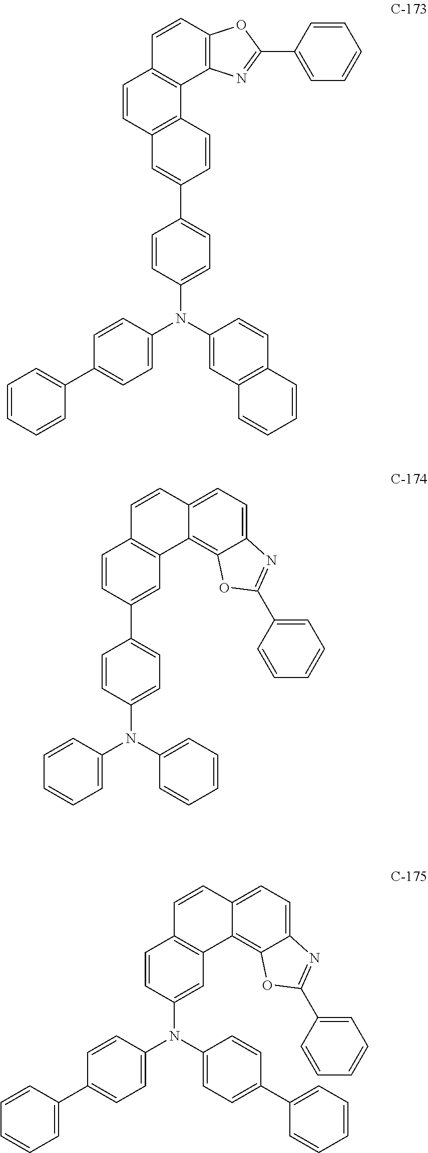 [SMILES: c1ccc(-c2ccc(N(c3ccc(-c4ccc5c(ccc6ccc7oc(-c8ccccc8)nc7c65)c4)cc3)c3ccc4ccccc4c3)cc2)cc1 ; c1ccc(-c2nc3ccc4ccc5ccc(-c6ccc(N(c7ccccc7)c7ccccc7)cc6)cc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1]

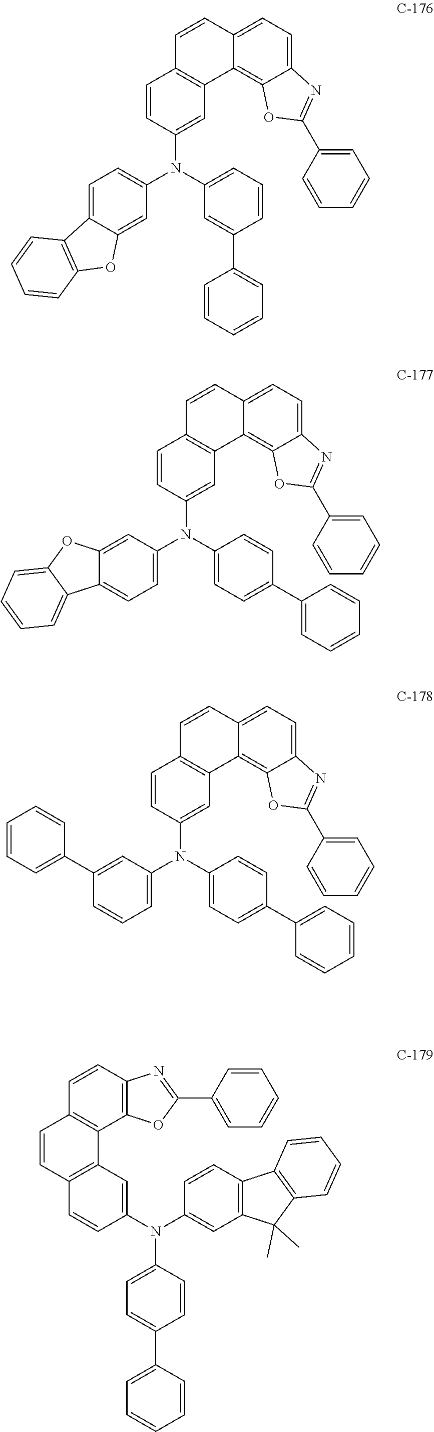 [SMILES: c1ccc(-c2cccc(N(c3ccc4c(c3)oc3ccccc34)c3ccc4ccc5ccc6nc(-c7ccccc7)oc6c5c4c3)c2)cc1 ; c1ccc(-c2ccc(N(c3ccc4c(c3)oc3ccccc34)c3ccc4ccc5ccc6nc(-c7ccccc7)oc6c5c4c3)cc2)cc1 ; c1ccc(-c2ccc(N(c3cccc(-c4ccccc4)c3)c3ccc4ccc5ccc6nc(-c7ccccc7)oc6c5c4c3)cc2)cc1 ; CC1(C)c2ccccc2-c2ccc(N(c3ccc(-c4ccccc4)cc3)c3ccc4ccc5ccc6nc(-c7ccccc7)oc6c5c4c3)cc21]

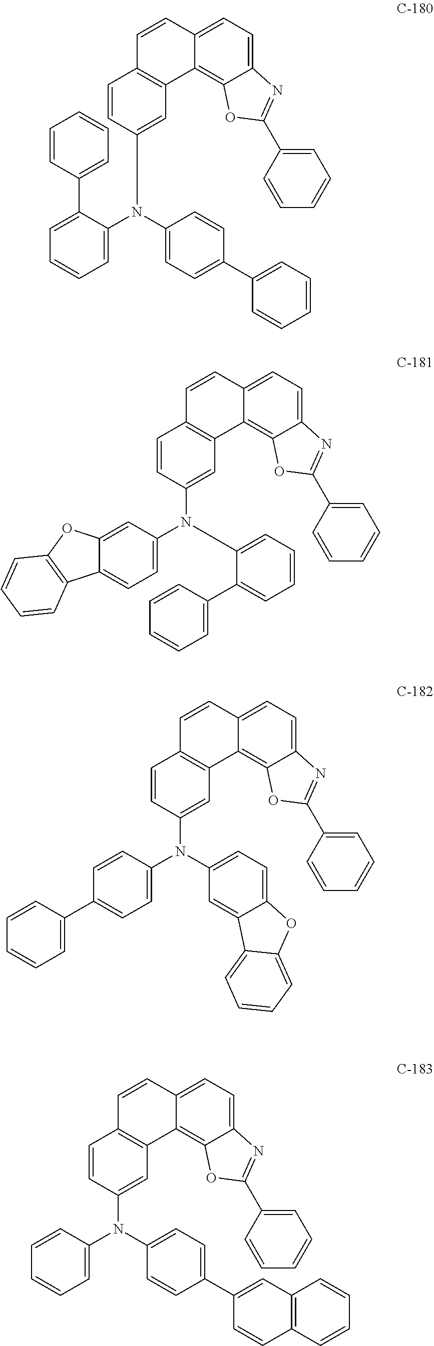

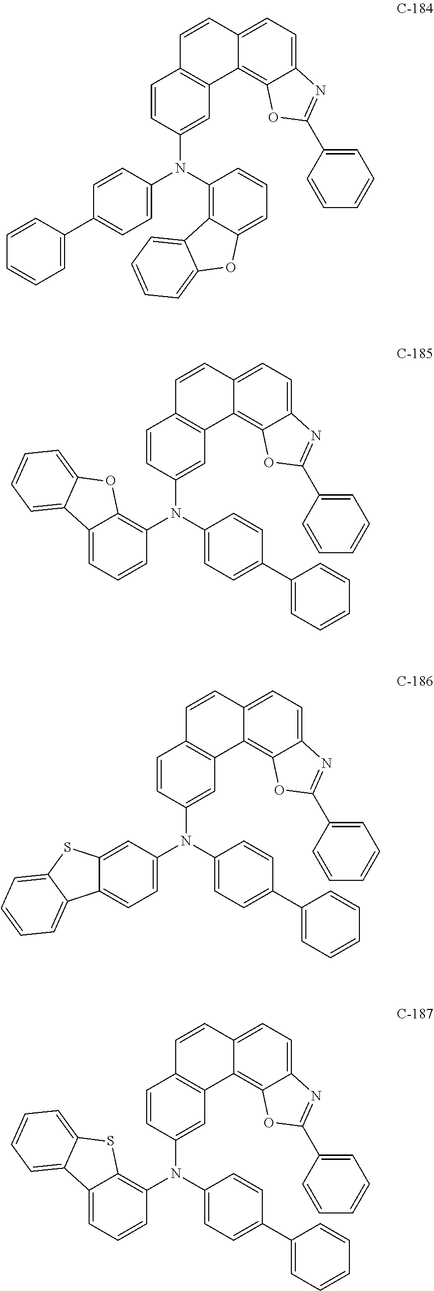 [SMILES: c1ccc(-c2ccc(N(c3ccc4ccc5ccc6nc(-c7ccccc7)oc6c5c4c3)c3cccc4oc5ccccc5c34)cc2)cc1 ; c1ccc(-c2ccc(N(c3ccc4ccc5ccc6nc(-c7ccccc7)oc6c5c4c3)c3cccc4c3oc3ccccc34)cc2)cc1 ; c1ccc(-c2ccc(N(c3ccc4c(c3)sc3ccccc34)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4c3sc3ccccc34)cc2)cc1]

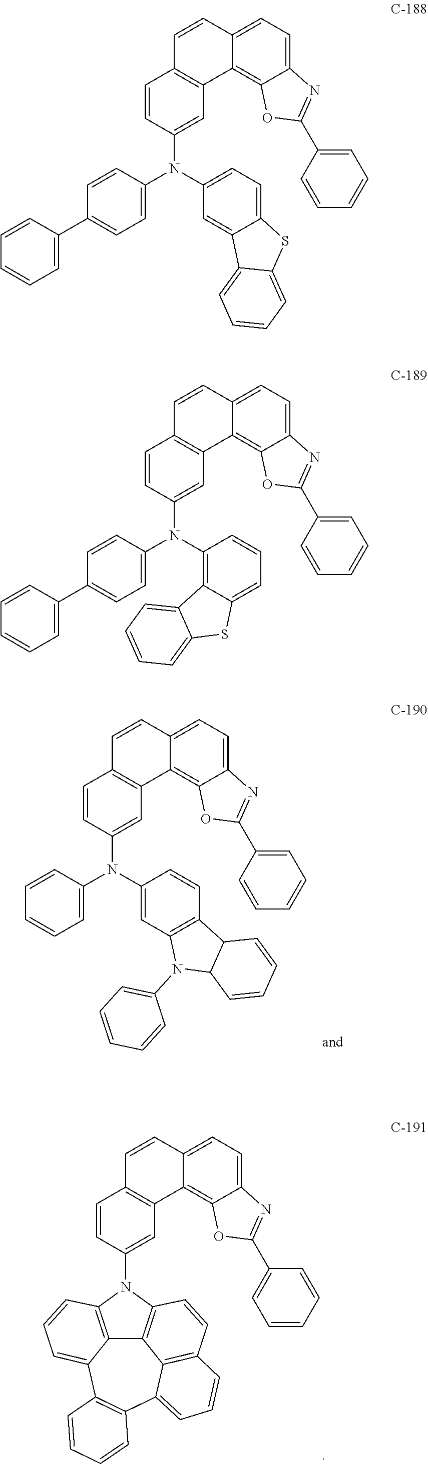 [SMILES: c1ccc(-c2ccc(N(c3ccc4sc5ccccc5c4c3)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4sc5ccccc5c34)cc2)cc1 ; C1=CC2c3ccc(N(c4ccccc4)c4ccc5ccc6ccc7nc(-c8ccccc8)oc7c6c5c4)cc3N(c3ccccc3)C2C=C1 ; c1ccc(-c2nc3ccc4ccc5ccc(-n6c7cccc8c7c7c9c(cccc9ccc76)-c6ccccc6-8)cc5c4c3o2)cc1]

9. The plurality of host materials according to claim 7, wherein the compound represented by formula 2 is at least one selected from the following compounds C2-1 to C2-259:

| Compound | Formula | L₂ | HAr | Compound | Formula | L₂ | HAr |
|---|---|---|---|---|---|---|---|
| C2-1 | 2-11 | 3-3 | 4-1 | C2-2 | 2-11 | 3-3 | 4-6 |
| C2-3 | 2-11 | 3-3 | 4-9 | C2-4 | 2-11 | 3-8 | 4-6 |
| C2-5 | 2-11 | 3-3 | 4-11 | C2-6 | 2-11 | 3-8 | 4-11 |
| C2-7 | 2-12 | 3-3 | 4-1 | C2-8 | 2-12 | 3-8 | 4-1 |
| C2-9 | 2-12 | 3-3 | 4-11 | C2-10 | 2-12 | 3-8 | 4-11 |
| C2-11 | 2-12 | 3-16 | 4-1 | C2-12 | 2-12 | 3-27 | 4-1 |
| C2-13 | 2-12 | 3-3 | 4-6 | C2-14 | 2-12 | 3-8 | 4-6 |
| C2-15 | 2-12 | 3-16 | 4-6 | C2-16 | 2-12 | 3-27 | 4-6 |
| C2-17 | 2-12 | 3-3 | 4-9 | C2-18 | 2-12 | 3-8 | 4-9 |
| C2-19 | 2-12 | 3-16 | 4-9 | C2-20 | 2-12 | 3-27 | 4-9 |
| C2-21 | 2-13 | 3-3 | 4-1 | C2-22 | 2-13 | 3-3 | 4-6 |
| C2-23 | 2-13 | 3-3 | 4-9 | C2-24 | 2-13 | 3-8 | 4-6 |
| C2-25 | 2-13 | 3-3 | 4-11 | C2-26 | 2-13 | 3-8 | 4-11 |
| C2-27 | 2-14 | 3-3 | 4-1 | C2-28 | 2-14 | 3-3 | 4-6 |
| C2-29 | 2-14 | 3-3 | 4-9 | C2-30 | 2-14 | 3-8 | 4-6 |
| C2-31 | 2-14 | 3-3 | 4-11 | C2-32 | 2-14 | 3-8 | 4-11 |
| C2-33 | 2-15 | 3-3 | 4-1 | C2-34 | 2-15 | 3-3 | 4-6 |
| C2-35 | 2-15 | 3-3 | 4-9 | C2-36 | 2-15 | 3-8 | 4-6 |
| C2-37 | 2-15 | 3-3 | 4-11 | C2-38 | 2-15 | 3-8 | 4-11 |
| C2-39 | 2-16 | 3-3 | 4-1 | C2-40 | 2-16 | 3-8 | 4-1 |
| C2-41 | 2-16 | 3-16 | 4-1 | C2-42 | 2-16 | 3-27 | 4-1 |
| C2-43 | 2-16 | 3-3 | 4-6 | C2-44 | 2-16 | 3-8 | 4-6 |
| C2-45 | 2-16 | 3-3 | 4-11 | C2-46 | 2-16 | 3-8 | 4-11 |
| C2-47 | 2-16 | 3-16 | 4-6 | C2-48 | 2-16 | 3-27 | 4-6 |
| C2-49 | 2-16 | 3-3 | 4-9 | C2-50 | 2-16 | 3-8 | 4-9 |
| C2-51 | 2-16 | 3-16 | 4-9 | C2-52 | 2-16 | 3-27 | 4-9 |
| C2-53 | 2-17 | 3-3 | 4-1 | C2-54 | 2-17 | 3-3 | 4-6 |
| C2-55 | 2-17 | 3-3 | 4-9 | C2-56 | 2-17 | 3-8 | 4-6 |
| C2-57 | 2-17 | 3-3 | 4-11 | C2-58 | 2-17 | 3-8 | 4-11 |
| C2-59 | 2-18 | 3-3 | 4-1 | C2-60 | 2-18 | 3-3 | 4-6 |
| C2-61 | 2-18 | 3-3 | 4-9 | C2-62 | 2-18 | 3-8 | 4-6 |
| C2-63 | 2-18 | 3-3 | 4-11 | C2-64 | 2-18 | 3-8 | 4-11 |
| C2-65 | 2-19 | 3-3 | 4-1 | C2-66 | 2-19 | 3-3 | 4-6 |
| C2-67 | 2-19 | 3-3 | 4-9 | C2-68 | 2-19 | 3-8 | 4-6 |
| C2-69 | 2-19 | 3-3 | 4-11 | C2-70 | 2-19 | 3-8 | 4-11 |
| C2-71 | 2-20 | 3-3 | 4-1 | C2-72 | 2-20 | 3-3 | 4-6 |
| C2-73 | 2-20 | 3-3 | 4-9 | C2-74 | 2-20 | 3-8 | 4-6 |
| C2-75 | 2-20 | 3-3 | 4-11 | C2-76 | 2-20 | 3-8 | 4-11 |
| C2-77 | 2-21 | 3-3 | 4-1 | C2-78 | 2-21 | 3-3 | 4-6 |
| C2-79 | 2-21 | 3-3 | 4-9 | C2-80 | 2-21 | 3-8 | 4-6 |
| C2-81 | 2-21 | 3-3 | 4-11 | C2-82 | 2-21 | 3-8 | 4-11 |
| C2-83 | 2-22 | 3-3 | 4-1 | C2-84 | 2-22 | 3-3 | 4-6 |
| C2-85 | 2-22 | 3-3 | 4-9 | C2-86 | 2-22 | 3-8 | 4-6 |
| C2-87 | 2-22 | 3-3 | 4-11 | C2-88 | 2-22 | 3-8 | 4-11 |
| C2-89 | 2-23 | 3-3 | 4-1 | C2-90 | 2-23 | 3-8 | 4-1 |
| C2-91 | 2-23 | 3-16 | 4-1 | C2-92 | 2-23 | 3-27 | 4-1 |
| C2-93 | 2-23 | 3-3 | 4-11 | C2-94 | 2-23 | 3-8 | 4-11 |
| C2-95 | 2-23 | 3-3 | 4-6 | C2-96 | 2-23 | 3-8 | 4-6 |
| C2-97 | 2-23 | 3-16 | 4-6 | C2-98 | 2-23 | 3-27 | 4-6 |
| C2-99 | 2-23 | 3-3 | 4-9 | C2-100 | 2-23 | 3-8 | 4-9 |
| C2-101 | 2-23 | 3-16 | 4-9 | C2-102 | 2-23 | 3-27 | 4-9 |
| C2-103 | 2-24 | 3-3 | 4-1 | C2-104 | 2-24 | 3-3 | 4-6 |
| C2-105 | 2-24 | 3-3 | 4-9 | C2-106 | 2-24 | 3-8 | 4-6 |
| C2-107 | 2-24 | 3-3 | 4-11 | C2-108 | 2-24 | 3-8 | 4-11 |
| C2-109 | 2-25 | 3-3 | 4-1 | C2-110 | 2-25 | 3-3 | 4-6 |
| C2-111 | 2-25 | 3-3 | 4-9 | C2-112 | 2-25 | 3-8 | 4-6 |
| C2-113 | 2-25 | 3-3 | 4-11 | C2-114 | 2-25 | 3-8 | 4-11 |
| C2-115 | 2-26 | 3-3 | 4-1 | C2-116 | 2-26 | 3-3 | 4-6 |
| C2-117 | 2-26 | 3-3 | 4-9 | C2-118 | 2-26 | 3-8 | 4-6 |
| C2-119 | 2-26 | 3-3 | 4-11 | C2-120 | 2-26 | 3-8 | 4-11 |
| C2-121 | 2-27 | 3-3 | 4-1 | C2-122 | 2-27 | 3-3 | 4-6 |
| C2-123 | 2-27 | 3-3 | 4-9 | C2-124 | 2-27 | 3-8 | 4-6 |
| C2-125 | 2-27 | 3-3 | 4-11 | C2-126 | 2-27 | 3-8 | 4-11 |
| C2-127 | 2-28 | 3-3 | 4-1 | C2-128 | 2-28 | 3-3 | 4-6 |
| C2-129 | 2-28 | 3-3 | 4-9 | C2-130 | 2-28 | 3-8 | 4-6 |
| C2-131 | 2-28 | 3-3 | 4-11 | C2-132 | 2-28 | 3-8 | 4-11 |
| C2-133 | 2-29 | 3-3 | 4-1 | C2-134 | 2-29 | 3-3 | 4-6 |
| C2-135 | 2-29 | 3-3 | 4-9 | C2-136 | 2-29 | 3-8 | 4-6 |
| C2-137 | 2-29 | 3-3 | 4-11 | C2-138 | 2-29 | 3-8 | 4-11 |
| C2-139 | 2-30 | 3-3 | 4-1 | C2-140 | 2-30 | 3-8 | 4-1 |
| C2-141 | 2-30 | 3-16 | 4-1 | C2-142 | 2-30 | 3-27 | 4-1 |
| C2-143 | 2-30 | 3-3 | 4-11 | C2-144 | 2-30 | 3-8 | 4-11 |
| C2-145 | 2-30 | 3-3 | 4-6 | C2-146 | 2-30 | 3-8 | 4-6 |
| C2-147 | 2-30 | 3-16 | 4-6 | C2-148 | 2-30 | 3-27 | 4-6 |
| C2-149 | 2-30 | 3-3 | 4-9 | C2-150 | 2-30 | 3-8 | 4-9 |
| C2-151 | 2-30 | 3-16 | 4-9 | C2-152 | 2-30 | 3-27 | 4-9 |
| C2-153 | 2-31 | 3-3 | 4-1 | C2-154 | 2-31 | 3-3 | 4-6 |
| C2-155 | 2-31 | 3-3 | 4-9 | C2-156 | 2-31 | 3-8 | 4-6 |
| C2-157 | 2-31 | 3-3 | 4-11 | C2-158 | 2-31 | 3-8 | 4-11 |
| C2-159 | 2-32 | 3-3 | 4-1 | C2-160 | 2-32 | 3-3 | 4-6 |
| C2-161 | 2-32 | 3-3 | 4-9 | C2-162 | 2-32 | 3-8 | 4-6 |
| C2-163 | 2-32 | 3-3 | 4-11 | C2-164 | 2-32 | 3-8 | 4-11 |
| C2-165 | 2-33 | 3-3 | 4-1 | C2-166 | 2-33 | 3-3 | 4-6 |
| C2-167 | 2-33 | 3-3 | 4-9 | C2-168 | 2-33 | 3-8 | 4-6 |
| C2-169 | 2-33 | 3-3 | 4-11 | C2-170 | 2-33 | 3-8 | 4-11 |
| C2-171 | 2-34 | 3-3 | 4-1 | C2-172 | 2-34 | 3-3 | 4-6 |
| C2-173 | 2-34 | 3-3 | 4-9 | C2-174 | 2-34 | 3-8 | 4-6 |
| C2-175 | 2-34 | 3-3 | 4-11 | C2-176 | 2-34 | 3-8 | 4-11 |
| C2-177 | 2-35 | 3-3 | 4-1 | C2-178 | 2-35 | 3-3 | 4-6 |
| C2-179 | 2-35 | 3-3 | 4-9 | C2-180 | 2-35 | 3-8 | 4-6 |
| C2-181 | 2-35 | 3-3 | 4-11 | C2-182 | 2-35 | 3-8 | 4-11 |
| C2-183 | 2-36 | 3-3 | 4-1 | C2-184 | 2-36 | 3-3 | 4-6 |
| C2-185 | 2-36 | 3-3 | 4-9 | C2-186 | 2-36 | 3-8 | 4-6 |
| C2-187 | 2-36 | 3-3 | 4-11 | C2-188 | 2-36 | 3-8 | 4-11 |
| C2-189 | 2-37 | 3-3 | 4-1 | C2-190 | 2-37 | 3-3 | 4-6 |
| C2-191 | 2-37 | 3-3 | 4-9 | C2-192 | 2-37 | 3-8 | 4-6 |
| C2-193 | 2-37 | 3-3 | 4-11 | C2-194 | 2-37 | 3-8 | 4-11 |
| C2-195 | 2-38 | 3-3 | 4-1 | C2-196 | 2-38 | 3-3 | 4-6 |
| C2-197 | 2-38 | 3-3 | 4-9 | C2-198 | 2-38 | 3-8 | 4-6 |
| C2-199 | 2-38 | 3-3 | 4-11 | C2-200 | 2-38 | 3-8 | 4-11 |
| C2-201 | 2-12 | Single | 4-9 | C2-202 | 2-16 | Single | 4-9 |
| | | Bond | | | | Bond | |
| C2-203 | 2-23 | Single | 4-9 | C2-204 | 2-26 | Single | 4-9 |
| | | Bond | | | | Bond | |
| C2-205 | 2-30 | Single | 4-9 | C2-206 | 2-37 | Single | 4-9 |
| | | Bond | | | | Bond | |
| C2-207 | 2-11 | Single | 4-5 | C2-208 | 2-12 | Single | 4-6 |
| | | Bond | | | | Bond | |
| C2-209 | 2-16 | Single | 4-8 | C2-210 | 2-23 | Single | 4-1 |
| | | Bond | | | | Bond | |
| C2-211 | 2-30 | Single | 4-1 | C2-212 | 2-37 | Single | 4-1 |
| | | Bond | | | | Bond | |
| C2-213 | 2-12 | 3-8 | 4-20 | C2-214 | 2-12 | 3-8 | 4-21 |
| C2-215 | 2-12 | 3-8 | 4-22 | C2-216 | 2-12 | 3-8 | 4-23 |
| C2-217 | 2-12 | 3-8 | 4-24 | C2-218 | 2-12 | 3-8 | 4-25 |
| C2-219 | 2-12 | 3-8 | 4-26 | C2-220 | 2-12 | 3-8 | 4-27 |
| C2-221 | 2-12 | 3-8 | 4-28 | C2-222 | 2-12 | 3-1 | 4-1 |
| C2-223 | 2-12 | 3-2 | 4-1 | C2-224 | 2-12 | 3-4 | 4-1 |
| C2-225 | 2-12 | 3-5 | 4-1 | C2-226 | 2-12 | 3-6 | 4-1 |
| C2-227 | 2-12 | 3-7 | 4-1 | C2-228 | 2-12 | 3-9 | 4-1 |
| C2-229 | 2-12 | 3-10 | 4-1 | C2-230 | 2-12 | 3-11 | 4-1 |
| C2-231 | 2-12 | 3-12 | 4-1 | C2-232 | 2-12 | 3-13 | 4-1 |
| C2-233 | 2-12 | 3-14 | 4-1 | C2-234 | 2-12 | 3-15 | 4-1 |
| C2-235 | 2-12 | 3-40 | 4-1 | C2-236 | 2-12 | 3-17 | 4-1 |
| C2-237 | 2-12 | 3-18 | 4-1 | C2-238 | 2-12 | 3-19 | 4-1 |
| C2-239 | 2-12 | 3-20 | 4-1 | C2-240 | 2-12 | 3-21 | 4-1 |
| C2-241 | 2-12 | 3-22 | 4-1 | C2-242 | 2-12 | 3-23 | 4-1 |
| C2-243 | 2-12 | 3-24 | 4-1 | C2-244 | 2-12 | 3-25 | 4-1 |
| C2-245 | 2-12 | 3-26 | 4-1 | C2-246 | 2-12 | 3-29 | 4-1 |
| C2-247 | 2-12 | 3-28 | 4-1 | C2-248 | 2-12 | 3-31 | 4-1 |
| C2-249 | 2-12 | 3-30 | 4-1 | C2-250 | 2-12 | 3-33 | 4-1 |
| C2-251 | 2-12 | 3-32 | 4-1 | C2-252 | 2-12 | 3-35 | 4-1 |
| C2-253 | 2-12 | 3-34 | 4-1 | C2-254 | 2-12 | 3-37 | 4-1 |
| C2-255 | 2-12 | 3-36 | 4-1 | C2-256 | 2-12 | 3-39 | 4-1 |
| C2-257 | 2-12 | 3-38 | 4-1 | C2-258 | 2-12 | 3-9 | 4-11 |
| C2-259 | 2-12 | 3-8 | 4-5 | | | | |

wherein, the compounds C2-1 to C2-259, each independently, are represented by any one of formulas 2-11 to 2-38, L₂ represents a single bond, or any one of the structures 3-1 to 3-40, and HAr represents any one of the structures 4-1 to 4-28.

10. An organic electroluminescent device comprising an anode, a cathode, and at least one light-emitting layer between the anode and the cathode, wherein the at least one layer of the light-emitting layers comprises the plurality of host materials according to claim 1.
